(19) United States
(12) Patent Application Publication
(10) Pub. No.: US 2026/0190609 A1
(43) Pub. Date: Jul. 2, 2026

(54) ORGANIC ELECTRONIC DEVICE COMPRISING A PLURALITY OF LIGHT-EMITTING AUXILIARY LAYERS AND ELECTRONIC APPARATUS THEREOF

(71) Applicant: DUK SAN NEOLUX CO., LTD., Chungcheongnam-do (KR)

(72) Inventors: MOON SUNG KANG, Chungcheongnam-do (KR); HYUNG DONG LEE, Chungcheongnam-do (KR); SUN HEE LEE, Chungcheongnam-do (KR); YUN SUK LEE, Chungcheongnam-do (KR); YOUNG CHANG YU, Chungcheongnam-do (KR); JUNG HWAN PARK, Chungcheongnam-do (KR)

(21) Appl. No.: 19/127,278

(22) PCT Filed: Oct. 18, 2023
(86) PCT No.: PCT/KR2023/016125

§ 371 Date: May 5, 2025

(30) Foreign Application Priority Data
Nov. 4, 2022 (KR) 10-2022-0146061

(51) Int. Cl. H10K 50/15; C09K 11/06; H10K 50/16; H10K 50/19; H10K 59/12; H10K 85/40; H10K 85/60

(52) U.S. Cl. CPC H10K 50/15; C09K 11/06; H10K 50/16; H10K 50/19; H10K 85/40; H10K 85/622; H10K 85/626; H10K 85/633; H10K 85/636; H10K 85/6572; H10K 85/6574; H10K 85/6576; C09K 2211/1096; H10K 59/12

(57) ABSTRACT

An organic electronic device includes a first electrode, a second electrode, a hole transport layer, a light-emitting layer disposed between the first electrode and the second electrode, and a plurality of light-emitting auxiliary layers positioned between the light-emitting layer and the hole transport layer. The plurality of light-emitting auxiliary layers includes a first light-emitting auxiliary layer adjacent to the hole transport layer and a second light-emitting auxiliary layer adjacent to the light-emitting layer. The first light-emitting auxiliary layer includes a compound represented by Formula 1, and the second light-emitting auxiliary layer includes a compound represented by Formula 2, thereby improving the driving voltage, efficiency, and lifetime of the organic electronic device.

### BACKGROUND

### 1. Technical Field

The present invention relates to an organic electronic device including a plurality of light-emitting auxiliary layers and an electronic apparatus thereof.

### 2. Background Art

In general, organic electroluminescence refers to a phenomenon in which electrical energy is converted into light energy by an organic material. An organic electronic device utilizing organic electroluminescence typically includes an anode, a cathode, and an organic layer interposed therebetween. In many cases, the organic layer has a multi-layered structure including different materials, respectively, in order to improve the efficiency and stability of an organic electronic device. For example, the organic layer may include a hole-injecting layer, a hole-transporting layer, a light-emitting layer, an electron-transporting layer, and an electron-injecting layer.

The biggest issues with an organic electroluminescent device are their lifespan and efficiency, and these efficiency and lifespan issues must be resolved as displays become larger in size.

Efficiency, lifespan, driving voltage, and the like are interrelated. An increase in efficiency may lead to a decrease in driving voltage, which in turn may reduce the crystallization of organic materials caused by Joule heating generated during device operation. As a result, the lifespan of the device may be increased.

However, efficiency cannot be maximized solely by improving the organic layer. This is because both long lifespan and high efficiency can be simultaneously achieved only when an optimal combination is established among the energy levels, T₁ values, and intrinsic material properties (e.g., charge mobility, interfacial characteristics, etc.) of the respective layers constituting the organic layer.

Therefore, it is necessary to develop materials that consist of an organic layer of a device, especially materials for the light-emitting auxiliary layer, in order to fully exhibit the excellent characteristics of an organic electronic device.

### SUMMARY

An object of the present invention is to provide an organic electronic device including a plurality of light-emitting auxiliary layers, each containing a specific compound, in order to lower the driving voltage, and improve the luminous efficiency and lifespan of a device, and an electronic apparatus thereof.

The present invention provides an organic electronic device and an electronic apparatus thereof, which include a plurality of light-emitting auxiliary layers and employ a combination of a light-emitting auxiliary layer containing a compound represented by the Formula 1 and a light-emitting auxiliary layer containing a compound represented by the Formula 2.

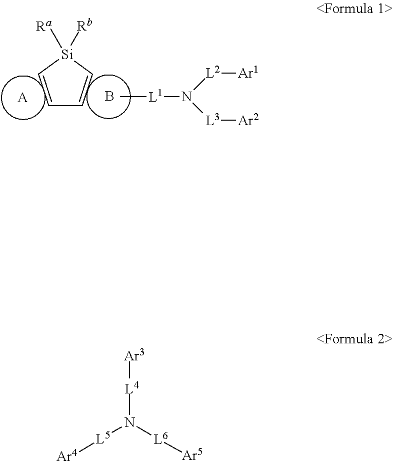

By combining and employing light-emitting auxiliary layers each containing a compound according to an embodiment of the present invention, it is possible to lower the driving voltage and improve the light-emitting efficiency and lifespan of a device.

### BRIEF DESCRIPTION OF THE DRAWINGS

FIGS. 1 and 2 are each schematic figures illustrating the stacked structure of an organic electroluminescent device according to an embodiment of the present invention.

### DETAILED DESCRIPTION

Unless otherwise stated, the term “aryl group” or “arylene group” as used herein refers to a group having 6 to 60 carbon atoms, but is not limited thereto. The aryl group or arylene group in the present invention may include a monocyclic ring, ring assemblies, a fused polycyclic system, a spiro compound, and the like.

As used herein, the term “fluorenyl group” refers to a fluorenyl moiety that may be substituted or unsubstituted, and the term “fluorenylene group” refers to a fluorenylene moiety that may be substituted or unsubstituted. The fluorenyl group or fluorenylene group employed in the present invention may include a spiro compound in which R and R′ are bonded to each other in the structure shown below, and may also include compounds in which adjacent R″ groups are linked together. The terms “substituted fluorenyl group” and “substituted fluorenylene group” mean that at least one of R, R′, or R″ in the following structure is a substituent other than hydrogen. In the following structure, the number of R″ groups may range from 1 to 8. Throughout this specification, the fluorenyl group and fluorenylene group may collectively be referred to as a “fluorene group” or “fluorene,” regardless of their valence.

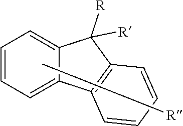

As used herein, the term “spiro compound” refers to a compound having a spiro linkage, which is a structure in which two rings are connected through a single common atom. The atom shared by the two rings is referred to as a “spiro atom,” and the compound may be classified as a monospiro, dispiro, or trispiro compound depending on the number of spiro atoms present in the molecule.

As used herein, the term “heterocyclic group” includes both aromatic rings, such as a “heteroaryl group” or a “heteroarylene group,” and non-aromatic rings. Unless otherwise specified, the “heterocyclic group” refers to a ring structure containing one or more heteroatoms and having from 2 to 60 carbon atoms, but is not limited thereto. The term “heteroatom,” as used herein, refers to atoms such as nitrogen (N), oxygen (O), sulfur (S), phosphorus (P), or silicon (Si), and may also include heteroatomic groups such as SO₂, P═O, and the like, which can replace a carbon atom in the ring structure as shown in the following compound. The “heterocyclic group” may include monocyclic ring, ring assemblies, fused polycyclic system, a spiro compound, and the like.

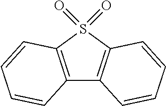 [SMILES: O=S1(=O)c2ccccc2-c2ccccc21]

As used herein, the term “aliphatic ring group” refers to a cyclic hydrocarbon excluding aromatic hydrocarbons, and includes, but is not limited to, monocyclic rings, ring assemblies, fused polycyclic systems, spiro compounds, and the like. Unless otherwise specified, the aliphatic ring group may include a ring having from 3 to 60 carbon atoms. For example, a fused ring system composed of benzene, which is an aromatic ring, and cyclohexane, which is a non-aromatic ring, corresponds to an aliphatic ring group.

In this specification, the “group name” corresponding to an aryl group, an arylene group, a heterocyclic group, and the like, exemplified for each symbol and its substituent, may be expressed either as a functional group name reflecting the valence or as the name of the parent compound. For example, in the case of phenanthrene, which is a type of aryl group, it may be described as “phenanthryl (group)” when referring to a monovalent group, and as “phenanthrylene (group)” when referring to a divalent group. Alternatively, it may also be described by its parent compound name “phenanthrene,” regardless of valence. Similarly, in the case of pyrimidine, it may be referred to as “pyrimidine” regardless of its valence. Alternatively, it may be described by the name of the corresponding functional group, such as “pyrimidinyl (group)” for a monovalent group and “pyrimidylene (group)” for a divalent group.

In addition, in the present specification, numerical and alphabetical indicators of positions may be omitted when describing the name of a compound or a substituent. For example, compounds such as pyrido[4,3-d]pyrimidine, benzofuro[2,3-d]pyrimidine, and 9,9-dimethyl-9H-fluorene may be described in a simplified manner as pyridopyrimidine, benzofuropyrimidine, and dimethylfluorene, respectively. Accordingly, both benzo[g]quinoxaline and benzo[f]quinoxaline may be generally referred to as benzoquinoxaline.

In addition, unless otherwise specified, when any compound according to the present invention is represented by the following formula, each substituent corresponding to the respective index is defined as described below.

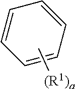

In the above formula, when a is zero, the substituent R¹ is absent, meaning that hydrogen atoms are bonded to all carbon atoms constituting the benzene ring. Here, chemical structures or compounds may be represented without explicitly indicating hydrogen atoms bonded to carbon atoms. In addition, when a is an integer of 1, one substituent R¹ is bonded to one of the carbon atoms constituting the benzene ring. When a is 2 or 3, the substituents may be bonded as exemplified below. In the case where a is an integer from 4 to 6, the substituents are similarly bonded to the carbon atoms of the benzene ring. Further, when a is greater than or equal to 2, the substituents R¹ may be identical or different from each other.

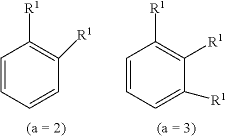

In addition, unless otherwise specified in the specification, the term ‘ring’ refers to an aryl ring, heteroaryl ring, fluorene ring, aliphatic ring, etc., and a number-membered (atom) ring may refer to the shape of a ring. For example, naphthalene corresponds to a two-fused (condensed) ring, anthracene to a three-fused (condensed) ring, thiophene or furan corresponds to a five-membered ring, and benzene or pyridine corresponds to a six-membered ring.

In addition, unless otherwise specified in the present specification, when adjacent groups are linked to each other to form a ring, the ring may be selected from the group consisting of a C₆-C₆₀ aromatic ring group, a fluorenyl group, a C₂-C₆₀ heterocyclic group containing at least one heteroatom selected from O, N, S, Si, and P, and a C₃-C₆₀ aliphatic ring group. Here, the aromatic ring group may include an aryl ring, and the heterocyclic group may include a heteroaryl ring.

Unless otherwise specified, the term “(between) adjacent groups,” as used herein, includes not only the relationships such as “(between) R₁ and R₂,” “(between) R₂ and R₃” “(between) R₃ and R₄,” and “(between) R₅ and R₆” but also “(between) R₇ and R₈” sharing a common carbon atom. It may further include cases “(between) substituents” attached to different ring-forming atoms (e.g., carbon or nitrogen), such as “(between) R₁ and R₇,” “(between) R₁ and R₈,” or “(between) R₄ and R₅.” That is, even when substituents are not directly adjacent on the same atom, one substituent may be considered adjacent to another substituent attached to a neighboring ring-forming atom. Additionally, substituents bonded to the same carbon atom forming the ring may also be regarded as adjacent groups. In the following Formula, when substituents such as R₇ and R₈, which are bonded to the same carbon atom, are connected to form a ring, a compound containing a spiro moiety may be formed.

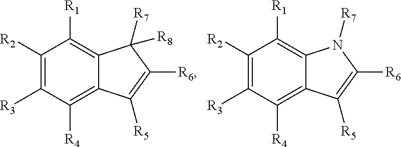

In addition, in the present specification, the expression “adjacent groups may be linked to each other to form a ring” is used in the same sense as “adjacent groups are selectively linked to each other to form a ring,” and refers to a case where at least one pair of adjacent groups may be bonded to form a ring structure.

In addition, unless otherwise specified in the present specification, substituents such as an aryl group, an arylene group, a fluorenyl group, a fluorenylene group, a heterocyclic group, an aliphatic ring group, an alkyl group, an alkenyl group, an alkynyl group, an alkoxyl group, an aryloxyl group, alkylthio group, arylthio group, etc., and a ring formed by adjacent groups may be each optionally substituted with one or more substituents selected from the group consisting of deuterium, halogen, a cyano group, a nitro group, siloxane group, a C₆-C₃₀ aryl group, a fluorenyl group, a C₂-C₃₀ heterocyclic group containing at least one heteroatom of O, N, S, Si and P, a C₃-C₃₀ aliphatic ring group, a C₁-C₂₀ alkyl group, a C₂-C₂₀ alkenyl group, a C₂-C₂₀ alkynyl group, a C₁-C₂₀ alkoxyl group, a C₆-C₂₀ aryloxy group, a C₁-C₂₀ alkylthio group, a C₆-C₂₀ arylthio group, a silane group unsubstituted or substituted with a C₁-C₂₀ alkyl group or a C₆-C₂₀ aryl group, and a phosphine oxide group unsubstituted or substituted with a C₁-C₂₀ alkyl group or a C₆-C₂₀ aryl group.

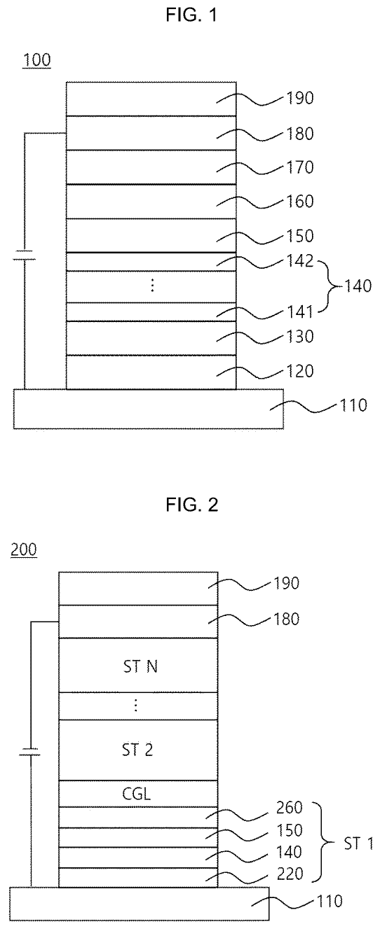

Hereinafter, with reference to FIGS. 1 and 2, the stacked structure of an organic electronic device including the compound according to the present invention will be described.

In the designation of reference numerals for components in the respective drawings, it should be understood that the same elements are denoted by the same reference numerals, even if they appear in different drawings. Furthermore, in the following description of the present invention, detailed explanations of well-known functions and configurations will be omitted where they may unnecessarily obscure the essence of the invention.

Terms such as “first,” “second,” “A,” “B,” “(a),” “(b),” and the like may be used to describe various components of the present invention. These terms are merely intended to distinguish one component from another and do not imply any particular order, importance, or essential characteristics. Furthermore, it should be understood that when a component is described as being “connected,” “coupled,” or “joined” to another component, this may include both direct connections as well as indirect connections through one or more intervening components.

Additionally, it is to be understood that when an element such as a layer, film, region, or substrate is described as being “on” or “over” another element, it may be positioned directly on the other element or with one or more intervening layers therebetween. In contrast, the expression “directly on” indicates that no intervening elements are present between the two elements.

Referring to FIG. 1, an organic electronic device 100 according to an embodiment of the present invention includes a first electrode 110, a second electrode 180, and an organic layer disposed between the first electrode 110 and the second electrode 180 on a substrate (not shown), an organic layer may include an inorganic material, and an inorganic layer may be formed between a first electrode 110 and a second electrode 180.

For example, the first electrode 110 may function as an anode (positive electrode), and the second electrode 170 may function as a cathode (negative electrode). In an inverted organic electronic device, however, the first electrode may serve as a cathode, while the second electrode may serve as an anode.

The organic layer refers to a layer containing at least one organic material. For example, the organic layer may include a hole-injecting layer 120, a hole-transporting layer 130, a light-emitting auxiliary layer 140, a light-emitting layer 150, an electron-transporting layer 160, and an electron-injecting layer 170 sequentially formed on the first electrode 110. However, the electron-injecting layer 170 may be an inorganic layer that does not contain organic material. Although not shown in FIG. 1, an electron-transporting auxiliary layer may be further formed between the light-emitting layer 150 and the electron-transporting layer 160.

Additionally, a layer for improving the luminous efficiency 190 may be formed on one side of the first electrode 110 or the second electrode 180 that is not in contact with the organic layer or inorganic layer. FIG. 1 shows an example in which a layer for improving the luminous efficiency 190 is formed on a second electrode 180. When the layer for improving the luminous efficiency 190 is formed, the luminous efficiency of the organic electronic device can be enhanced.

For example, the layer for improving the luminous efficiency 190 may be formed on the second electrode 180. As a result, in the case of a top-emission organic light emitting device, optical energy loss due to surface plasmon polaritons (SPPs) at the second electrode 180 may be reduced. In the case of a bottom-emission organic light emitting device, the layer for improving the luminous efficiency 190 may function as a buffer layer for the second electrode 180.

When the energy levels T₁ values, and intrinsic properties of the material (mobility, interfacial properties, etc.) between organic layers are optimally combined, the driving voltage, efficiency, and lifespan of a device can be improved.

Accordingly, the present invention provides light-emitting auxiliary layers 140 formed from a plurality of layers, with materials selected for each light-emitting auxiliary layer so that the energy levels, T1 values, and intrinsic properties of the material (such as mobility, interface properties, etc.) are optimally combined, and these light-emitting auxiliary layers are combined.

That is, when the light-emitting auxiliary layers 140 are formed of a plurality of layers, the driving voltage, efficiency, lifespan, etc. of the device may vary depending on the type of compound forming each layer and the combination or arrangement of the multiple light-emitting auxiliary layers. Therefore, the present invention proposes a combination of multiple light-emitting auxiliary layers formed of specific compounds that can improve the characteristics of the device.

According to the present invention, the light-emitting auxiliary layers 140 include a first light-emitting auxiliary layer 141 including a compound of Formula 1 adjacent to the hole-transporting layer 120, and a second light-emitting auxiliary layer 142 including a compound of Formula 2 adjacent to a light-emitting layer 150.

The first and second light-emitting auxiliary layers 141, 142 may include the same or different materials, and when these layers are adjacent to each other, they may be formed from different materials.

The first light-emitting auxiliary layer 141 functions to inject and transport holes from a hole-transporting layer to a light-emitting auxiliary layer, and the second light-emitting auxiliary layer 142 functions to inject and transport holes from a light-emitting auxiliary layer to host material.

When a plurality of light-emitting auxiliary layers are formed in this manner, the hole injection characteristics of the first and second light-emitting auxiliary layers 141, 142 can be adjusted to appropriately control the charge balance of the device, thereby improving the efficiency and lifetime of a device.

In the case of the first light-emitting auxiliary layer 141, the hole transport capability changes depending on the hole mobility, thereby influencing the driving voltage characteristics of the device. For the second light-emitting auxiliary layer 142, the electron-blocking ability toward the host varies depending on the high LUMO and T₁ values, which can affect the degree of damage to a hole-transporting layer and ultimately impact the lifetime.

The thickness of the light-emitting auxiliary layers varies depending on the color. In the case of a top emission device, light generated in a light-emitting layer passes through the hole transport region, is reflected at the anode, and the reflected light again passes through the hole transport region and combines with the light from a light-emitting layer to be emitted externally via an electron transport layer. The front-emission device must be designed to utilize the constructive interference phenomenon of microcavity effects.

In this way, the front-emission device improves optical efficiency, color purity, and lifespan. In other words, since the wavelengths differ by color, the thickness of the hole transport region between an anode and a light-emitting layer must be adjusted according to the color to utilize the microcavity effect, and in order to do this, the thickness of a hole transport region will vary.

For example, when the total thickness of the hole transport region excluding the light-emitting auxiliary layers is 1000 to 1500 Å, the thickness of the light-emitting auxiliary layer is preferably 600 to 900 Å for red OLEDs, 300 to 500 Å for green OLEDs, and 50 to 100 Å for blue OLEDs.

Preferably, the second light-emitting auxiliary layer 142 may be formed as thin as possible to maintain electron-blocking capability while not deteriorating the hole transport ability of the first light-emitting auxiliary layer 141.

For example, the thickness of the first light-emitting auxiliary layer 141 may be 25 to 900 Å, and the thickness of the second light-emitting auxiliary layer 142 may be 10 to 300 Å.

Specifically, the thickness of the first light-emitting auxiliary layer 141 may be 25 to 900 Å; for blue OLEDs, preferably 25 to 75 Å, more preferably 25 to 50 Å; for green OLEDs, 100 to 450 Å, more preferably 250 to 450 Å; for red OLEDs, 500 to 900 Å, more preferably 650 to 850 Å. The thickness of the second light-emitting auxiliary layer 142 may be 10 to 300 Å, preferably 20 to 100 Å, and more preferably 25 to 75 Å.

Also important is the HOMO energy level relationship between the first and second light-emitting auxiliary layers 141, 142. It is preferable for the HOMO energy level of the first light-emitting auxiliary layer 141 to be higher than that of the second 142.

When formed as such, the first and second light-emitting auxiliary layers 141, 142 form a cascade structure that facilitates hole injection and transport from a hole-transporting layer to the host material. In particular, hole injection from the light-emitting auxiliary layer to the host material becomes smooth, which can improve the efficiency of a device.

The T1 energy levels of the first and second light-emitting auxiliary layers 141, 142 may also influence the efficiency and lifetime of a device.

The T1 energy level of the second light-emitting auxiliary layer 142, represented by Formula 2, is preferably 2.3 to 3.0; for red OLEDs, preferably 2.3 to 2.9, more preferably 2.5 to 2.8; for green OLEDs, preferably 2.6 to 2.9, more preferably 2.7 to 2.9.

When the T1 energy level of the second light-emitting auxiliary layer 142 is within this range, it can effectively block triplet electrons from the dopant from moving to the hole-transporting layer (130), thereby enhancing the efficiency and lifetime of a device.

According to another embodiment of the present invention, the stacked structure of the OLED may include a plurality of stacks. This is illustrated referring to FIG. 2.

Referring to FIG. 2, an organic electronic device 200 according to another embodiment of the present invention may include two or more sets of stacks ST 1, ST 2, ST N of organic layers formed between a first electrode 110 and a second electrode 180, and a charge generation layer (CGL) may be formed between the stacks.

Specifically, the OLED may include a first electrode 110, a first stack ST 1, a charge generation layer (CGL), a second stack ST 2, a second electrode 180, and a layer for improving light efficiency 190.

The first stack ST 1 is an organic layer formed on the first electrode 110, and may include a hole transport region 220, a light-emitting auxiliary layer 140, a light-emitting layer 150, and an electron transport region 260.

The hole transport region 220 may consist of one or more layers, for example, includes a hole injection layer and a hole transport layer, and a hole injection layer may also be formed of one or more layers.

The light-emitting auxiliary layer 140 is formed a plurality of layers as described in FIG. 1. For example, it may include a first light-emitting auxiliary layer adjacent to a hole transport region 220 and a second light-emitting auxiliary layer adjacent to a light-emitting layer 150.

The electron transport region 260 is formed on the light-emitting layer 150 and may consist of one or more layers. For example it may include an electron transport layer and an electron injection layer.

A second stack ST 2 may be formed on the first stack ST 1, and one or more additional stacks (ST N) may be further formed on the second stack. Each stack may include the same or different organic layers.

A charge generation layer (CGL) may be formed between each stack, which enhances the current efficiency of each light-emitting layer and facilitates smooth charge distribution.

When a plurality of light-emitting layers are formed via a multilayer stack structure as shown in FIG. 2, a white OLED can be manufactured through the mixed emission of light from each light-emitting layer, and an OLED that emits light in various colors can also be produced.

At least one of the stacks—first stack ST 1, second stack ST 2, or N-th stack (ST N)—includes a multilayered light-emitting auxiliary layer. Among the plurality of light-emitting auxiliary layers, the one adjacent to the hole transport region includes a compound of Formula 1, and the one adjacent to the light-emitting layer 150 includes a compound of Formula 2.

For example, the light-emitting auxiliary layer 140 of the first stack ST 1 may include a first light-emitting auxiliary layer adjacent to the hole transport region 220 and a second light-emitting auxiliary layer 142 adjacent to the light-emitting layer 150. The second stack ST 2 may include no light-emitting auxiliary layer or may be formed of a light-emitting auxiliary layer of one or more layers.

The organic electronic device according to an embodiment of the present invention may be fabricated using various deposition methods, including physical vapor deposition (PVD) or chemical vapor deposition (CVD). For example, the organic electronic device may be manufactured by forming the anode 110 on the substrate by depositing a metal, a conductive metal oxide, or a mixture thereof, then forming an organic layer including a hole-injecting layer 120, a hole-transporting layer 130, a light-emitting auxiliary layer 140, a light-emitting layer 150, an electron-transporting layer 160, and an electron-injecting layer 170 thereon, and finally depositing a material that can be used as the cathode 180. In addition, an electron transport auxiliary layer (not shown) may additionally be formed between a light-emitting layer 150 and the electron-transporting layer 160. As described above, these layers may constitute a stacked structure.

In addition, the organic layer may be manufactured with fewer layers by using various polymer materials through a solution process or solvent-based process, such as spin coating, nozzle printing, inkjet printing, slot coating, dip coating, roll-to-roll, doctor blading, screen printing, or thermal transfer, instead of deposition. Since the organic layer according to the present invention may be formed in various ways, the scope of protection of the present invention is not limited by the method of forming the organic layer.

The organic electronic device according to an embodiment of the present invention may be a top-emission type, a bottom-emission type, or a dual-emission type, depending on the materials used.

In addition, the organic electronic device according to an embodiment of the present invention may be selected from the group consisting of an organic electroluminescent device, an organic solar cell, an organic photoconductor, an organic transistor, a monochromatic illumination device, and a quantum dot display device.

Another embodiment of the present invention provides an electronic apparatus including a display device including the above-described organic electronic device and a control unit for controlling the display device. The electronic apparatus may be a wired or wireless communication terminal currently in use or to be developed in the future, and includes all types of electronic devices, such as mobile communication terminals (e.g., cellular phones), navigation units, game players, various types of TVs, and computers.

Hereinafter, an electronic device according to one aspect of the present invention will be described.

An electronic device according to one aspect of the present invention includes a first electrode, a second electrode, a light-emitting layer disposed between the first electrode and the second electrode, and a plurality of light-emitting auxiliary layers positioned between the light-emitting layer and a hole transport layer, wherein, among the plurality of light-emitting auxiliary layers, a first light-emitting auxiliary layer adjacent to the hole transport layer includes a compound represented by Formula 1, and a second light-emitting auxiliary layer adjacent to the light-emitting layer includes a compound represented by Formula 2. The compound of Formula 1 and the compound of Formula 2 may be different from each other.

Hereinafter, Formulae 1 and 2 will be described in detail.

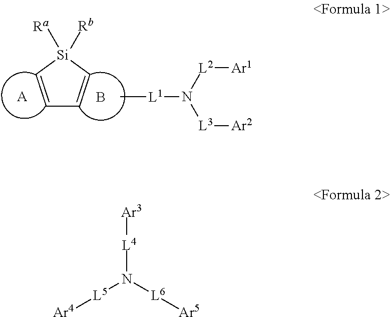

In Formula 1 and Formula 2, each symbol may be defined as follows.

A ring and B ring are each independently a C₆-C₆₀ aryl ring, wherein the A ring may be substituted with one or more R¹, which may be the same or different, and the B ring may be substituted with one or more R², which may be the same or different.

For example, the A ring and the B ring are each a C₆-C₃₀, a C₆-C₂₅, a C₆-C₂₀, a C₆-C₁₈, a C₆-C₁₆, a C₆-C₁₄, a C₆-C₁₀, a C₆, a C₁₀, a C₁₂, a C₁₄, a C₁₆, a C₁₈ aryl ring, specifically, and may be phenylene, naphthylene, phenanthrene, triphenylene, etc.

R^{a}, R^{b}, R¹ and R² are each independently selected from the group consisting of hydrogen, deuterium, halogen, a cyano group, a nitro group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₂₀ alkoxyl group, a C₆-C₆₀ aryloxy group, and -L′-N(Rₐ)(R_{b}), and adjacent R^{a} and R^{b} may be bonded to each other to form a ring. When R^{a} and R^{b} are bonded to each other to form a ring, a spiro compound may be formed.

L¹ to L⁶ are each independently selected from the group consisting of a single bond, a C₆-C₆₀ arylene group, a fluorenylene group, a C₃-C₆₀ aliphatic ring group, and a C₂-C₆₀ heterocyclic group containing at least one heteroatom of O, N, S, Si and P.

Ar¹ to Ar⁵ are each independently selected from the group consisting of a C₆-C₆₀ aryl group, a fluorenyl group, a C₃-C₆₀ aliphatic ring group, a C₂-C₆₀ heterocyclic group containing at least one heteroatom of O, N, S, Si and P, a C₁-C₂₀ alkyl group, and -L′-N(Rₐ)(R_{b}).

L′ is selected from the group consisting of a single bond, a C₆-C₃₀ arylene group, a fluorenylene group, a C₂-C₃₀ heterocyclic group containing at least one heteroatom of O, N, S, Si and P, and a C₃-C₃₀ aliphatic ring group.

Rₐ and R_{b} are each independently selected from the group consisting of a C₆-C₃₀ aryl group, a fluorenyl group, a C₂-C₃₀ heterocyclic group containing at least one heteroatom of O, N, S, Si and P, and a C₃-C₃₀ aliphatic ring group.

When at least one of Ar¹ to Ar⁵, R^{a}, R^{b}, Rₐ, R_{b}, R¹, R² is an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, or a C₁₈ aryl group, specifically, phenyl, biphenyl, naphthyl, terphenyl, phenanthrene, triphenylene, or the like.

When at least one of L¹ to L⁶, L′ is an arylene group, the arylene group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, or a C₁₈ arylene group, specifically, phenylene, biphenyl, naphthylene, terphenyl, phenanthrene, triphenylene, or the like.

When at least one of Ar¹ to Ar⁵, R^{a}, R^{b}, Rₐ, R_{b}, R¹, R², L¹ to L⁶, L′ is a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₈, a C₂-C₇, a C₂-C₆, a C₂-C₅, a C₂-C₄, a C₂-C₃, a C₂, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, or a C₂₉ heterocyclic group, specifically, pyridine, pyrimidine, pyrazine, pyridazine, triazine, furan, pyrrole, indene, indole, phenyl-indole, benzoindole, phenyl-benzoindole, pyrazinoindol, quinoline, isoquinoline, benzoquinoline, pyridoquinoline, quinazoline, benzoquinazoline, dibenzoquinazoline, phenanthroquinazoline, quinoxaline, benzoquinoxaline, dibenzoquinoxaline, benzofuran, naphthobenzofuran, dibenzofuran, dinaphthofuran, thiophene, benzothiophene, dibenzothiophene, naphthobenzothiophene, dinaphthothiophene, carbazole, phenyl-carbazole, benzocarbazole, phenyl-benzocarbazole, naphthyl-benzocarbazole, dibenzocarbazole, indolocarbazole, benzofuropyridine, benzothienopyridine, benzofuropyridine, benzothienopyrimidine, benzofuropyrimidine, benzothienopyrazine, benzofuropyrazine, benzoimidazole, benzothiazole, benzooxazole, benzosilole, phenanthroline, dihydro-phenylphenazine, 10-phenyl-10H-phenoxazine, phenoxazine, phenothiazine, dibenzodioxin, benzodibenzodioxin, thianthrene, 9,9-dimethyl-9H-xanthene, 9,9-dimethyl-9H-thioxanthene, dihydrodimethylphenylacridine, spiro[fluorene-9,9′-xanthene] and the like.

When at least one of Ar¹ to Ar⁵, R^{a}, R^{b}, Rₐ, R_{b}, R¹, R² is a fluorenyl group, or when at least one of L¹ to L⁶, L′ is a fluorenylene group, the fluorenyl group or the fluorenylene group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, or 9-(naphthalen-2-yl)-9-phenyl-9H-fluorene.

When at least one of Ar¹ to Ar⁵, R^{a}, R^{b}, Rₐ, R_{b}, R¹, R², L¹ to L⁶, L′ is an aliphatic ring group, the aliphatic ring group may be, for example, a C₃-C₃₀, a C₃-C₂₉, a C₃-C₂₈, a C₃-C₂₇, a C₃-C₂₆, a C₃-C₂₅, a C₃-C₂₄, a C₃-C₂₃, a C₃-C₂₂, a C₃-C₂₁, a C₃-C₂₀, a C₃-C₁₉, a C₃-C₁₈, a C₃-C₁₇, a C₃-C₁₆, a C₃-C₁₅, a C₃-C₁₄, a C₃-C₁₃, a C₃-C₁₂, a C₃-C₁₁, a C₃-C₁₀, a C₃-C₈, a C₃-C₆, a C₆, a C₁₀, a C₁₁, a C₁₂, a C₁₃, a C₁₄, a C₁₅, a C₁₆, a C₁₇ or a C₁₈ aliphatic ring group, specifically, a cyclopentanyl group, a cyclohexanyl group, a norbornyl group, an adamantyl group, etc.

The aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} may be each substituted with one or more substituents selected from the group consisting of deuterium, halogen, a silane group unsubstituted or substituted with a C₁-C₂₀ alkyl group or a C₆-C₂₀ aryl group, a phosphine oxide substituted or unsubstituted with a C₁-C₂₀ alkyl group or a C₆-C₂₀ aryl group, siloxane group, a cyano group, a nitro group, C₁-C₂₀ alkylthio group, C₁-C₂₀ alkoxy group, C₆-C₃₀ aryloxy group, C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group including at least one heteroatom selected from the group consisting of O, N, S, Si and P, a C₃-C₃₀ aliphatic ring group, and -L′-N(Rₐ)(R_{b}). Here, L′, Rₐ, and R_{b} are as defined above.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} is substituted with an aryl group, the aryl group may be, for example, a C₆-C₃₀, a C₆-C₂₉, a C₆-C₂₈, a C₆-C₂₇, a C₆-C₂₆, a C₆-C₂₅, a C₆-C₂₄, a C₆-C₂₃, a C₆-C₂₂, a C₆-C₂₁, a C₆-C₂₀, a C₆-C₁₉, a C₆-C₁₈, a C₆-C₁₇, a C₆-C₁₆, a C₆-C₁₅, a C₆-C₁₄, a C₆-C₁₃, a C₆-C₁₂, a C₆-C₁₁, a C₆-C₁₀, a C₆, a C₁₀, a C₁₂, a C₁₃, a C₁₄, a C₁₅, a C₁₆, a C₁₇, or a C₁₈ aryl group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} is substituted with a heterocyclic group, the heterocyclic group may be, for example, a C₂-C₃₀, a C₂-C₂₉, a C₂-C₂₈, a C₂-C₂₇, a C₂-C₂₆, a C₂-C₂₅, a C₂-C₂₄, a C₂-C₂₃, a C₂-C₂₂, a C₂-C₂₁, a C₂-C₂₀, a C₂-C₁₉, a C₂-C₁₈, a C₂-C₁₇, a C₂-C₁₆, a C₂-C₁₅, a C₂-C₁₄, a C₂-C₁₃, a C₂-C₁₂, a C₂-C₁₁, a C₂-C₁₀, a C₂-C₉, a C₂-C₈, a C₂-C₇, a C₂-C₆, a C₂-C₅, a C₂-C₄, a C₂-C₃, a C₂, a C₃, a C₄, a C₅, a C₆, a C₇, a C₈, a C₉, a C₁₀, a C₁₁, a C₁₂, a C₁₃, a C₁₄, a C₁₅, a C₁₆, a C₁₇, a C₁₈, a C₁₉, a C₂₀, a C₂₁, a C₂₂, a C₂₃, a C₂₄, a C₂₅, a C₂₆, a C₂₇, a C₂₈, or a C₂₉ heterocyclic group.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} is substituted with a fluorenyl group, the fluorenyl group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, or 9-(naphthalen-2-yl)-9-phenyl-9H-fluorene.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} is substituted with an alkyl group, the alkyl group may be, for example, a C₁-C₂₀, a C₁-C₁₀, a C₁-C₄, a C₁, a C₂, a C₃, or a C₄ alkyl group, for example, methyl, ethyl, t-butyl, etc.

When at least one of the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by R^{a} and R^{b} is substituted with an aliphatic ring group, the aliphatic ring group may be, for example, a C₃-C₃₀, a C₃-C₂₉, a C₃-C₂₈, a C₃-C₂₇, a C₃-C₂₆, a C₃-C₂₅, a C₃-C₂₄, a C₃-C₂₃, a C₃-C₂₂, a C₃-C₂₁, a C₃-C₂₀, a C₃-C₁₉, a C₃-C₁₈, a C₃-C₁₇, a C₃-C₁₆, a C₃-C₁₅, a C₃-C₁₄, a C₃-C₁₃, a C₃-C₁₂, a C₃-C₁₁, a C₃-C₁₀, a C₃-C₈, a C₃-C₆, a C₆, a C₁₀, a C₁₁, a C₁₂, a C₁₃, a C₁₄, a C₁₅, a C₁₆, a C₁₇ or a C₁₈ aliphatic ring group, specifically, a cyclopentanyl group, a cyclohexanyl group, a norbornyl group, an adamantyl group, etc.

Formula 1 may be represented by Formula 1-1.

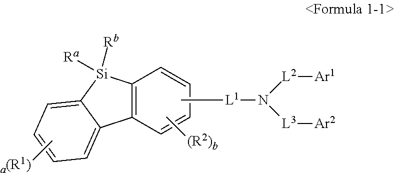

In Formula 1-1, R¹, R², R^{a}, R^{b}, L¹ to L³, Ar¹, Ar² are the same as defined for Formula 1, a is an integer from 0 to 4, and b is an integer from 0 to 3, and when a or b is 2 or more, each of the plurality of R¹ groups and each of the plurality of R² groups may be the same or different.

Formula 1 may be represented by one of Formula 1-2 to Formula 1-4.

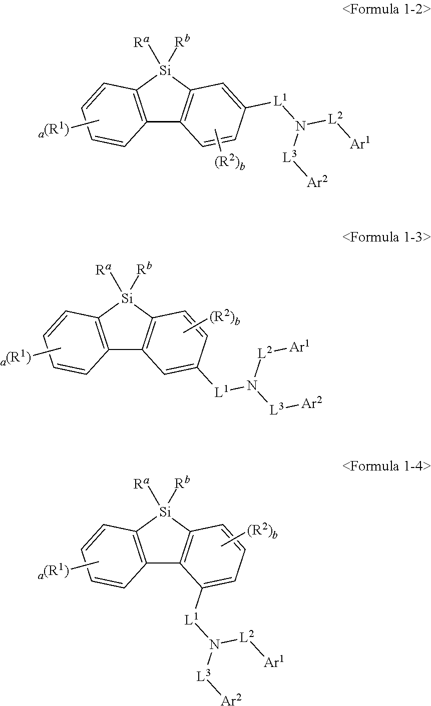

In Formula 1-2 to Formula 1-4, R¹, R², R^{a}, R^{b}, L¹ to L³, Ar¹, Ar², a, b are the same as defined for Formula 1-1.

At least one of Ar¹ and Ar² in Formula 1 may be selected from the group consisting of Formulae A-1 to A-9.

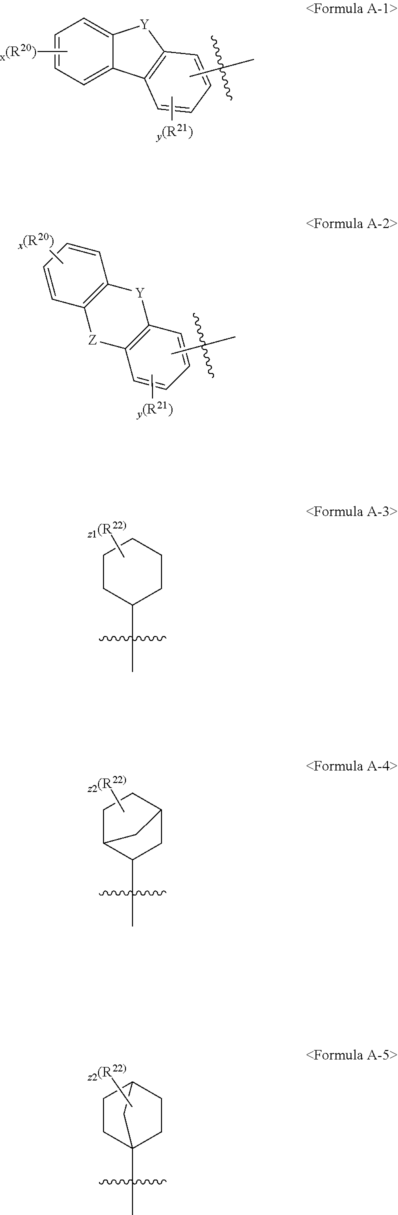

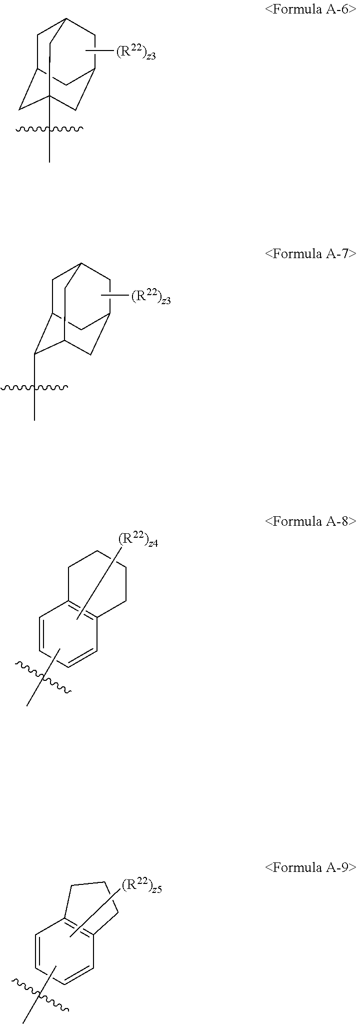

In Formula A-1 to Formula A-9, each symbol may be defined as follows.

Y and Z are each independently O, S, C(R₁)(R₂) or Si(R₃)(R₄).

R²⁰ to R²², R₁ to R₄ are each independently selected from the group consisting of hydrogen, deuterium, halogen, a silane group unsubstituted or substituted with a C₁-C₂₀ alkyl group or a C₆-C₂₀ aryl group, a phosphine oxide substituted or unsubstituted with a C₁-C₂₀ alkyl group or a C₆-C₂₀ aryl group, siloxane group, a cyano group, a nitro group, C₁-C₂₀ alkylthio group, C₁-C₂₀ alkoxy group, C₆-C₃₀ aryloxy group, C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group including at least one heteroatom selected from the group consisting of O, N, S, Si and P, a C₃-C₃₀ aliphatic ring group, and -L′-N(Rₐ)(R_{b}), and adjacent groups may be bonded to each other to form a ring. In addition,

R₁ and R₂ or R₃ and R₄ may be bonded to each other to form a ring, and when the ring is formed, a spiro compound may be formed.

Even if the same symbol is used in the above formulae, it may be defined differently depending on the formula. For example, when Ar¹ is Formula A-1 and Ar² is Formula A-2, a substituent R²⁰ indicated by the same symbol may be the same or different in the two formulae.

x is an integer from 0 to 4, y is an integer from 0 to 3, z1, z2, and z4 are each integers from 0 to 11, z3 is an integer from 0 to 15, and z5 is an integer from 0 to 9. When any of these integers is 2 or more, each of the plurality of R²⁰, R²¹, and R²² may be the same or different.

Formula A-1 may be selected from the group consisting of Formula A-1-1 to Formula A-1-4.

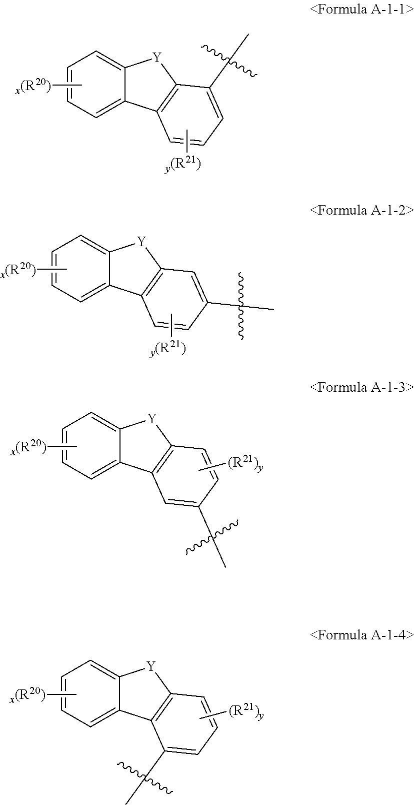

In Formula A-1-1 to Formula A-1-4, Y, R²⁰, R²¹, x, y are the same as defined for Formula A-1.

Ar³ in Formula 2 may be selected from the group consisting of Formula Ar-1 to Formula Ar-3.

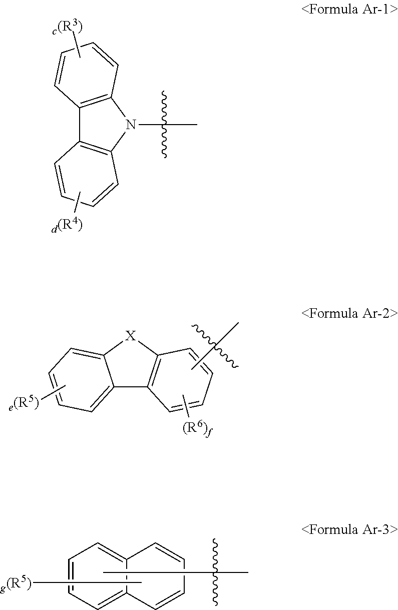

In Formula Ar-1 to Formula Ar-3, each symbol may be defined as follows.

X is O or S.

R³ to R⁷ are each independently selected from the group consisting of hydrogen, deuterium, halogen, a silane group unsubstituted or substituted with a C₁-C₂₀ alkyl group or a C₆-C₂₀ aryl group, a phosphine oxide substituted or unsubstituted with a C₁-C₂₀ alkyl group or a C₆-C₂₀ aryl group, siloxane group, a cyano group, a nitro group, C₁-C₂₀ alkylthio group, C₁-C₂₀ alkoxy group, C₆-C₃₀ aryloxy group, C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group including at least one heteroatom selected from the group consisting of O, N, S, Si and P, a C₃-C₃₀ aliphatic ring group, and -L′-N(Rₐ)(R_{b}), and adjacent groups may be bonded to each other to form a ring.

c, d, and e are each integers from 0 to 4, f is an integer from 0 to 3, and g is an integer from 0 to 7. When any of these integers is 2 or more, each of the plurality of R³ to each of the plurality of R⁷ may be the same or different.

Formula Ar-2 may be selected from the group consisting of Formula Ar-2-1 to Formula Ar-2-4.

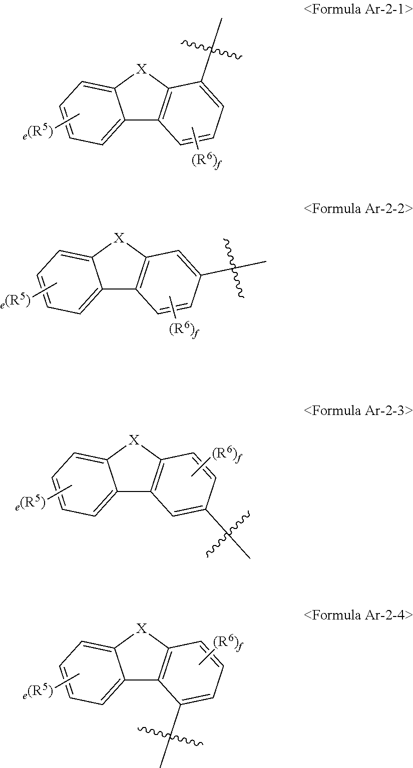

In Formula Ar-2-1 to Formula Ar-2-4, X, R⁵, R⁶, e, f are the same as defined for Formula Ar-2.

Formula 2 may be represented by Formula 2-1 when Ar³ in Formula Ar-2 is the same as Formula Ar-1, and may be represented by Formula 2-2 when Ar³ is Formula Ar-2 and one of the R⁵ groups is A″.

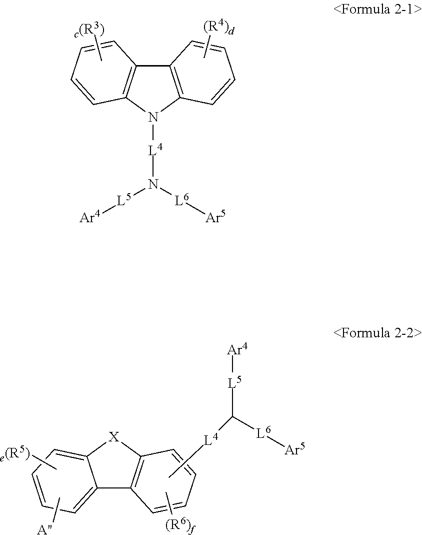

In Formula 2-1 and Formula 2-2, Ar⁴, Ar⁵, L⁴ to L⁶ are the same as defined for Formula 2; R³, R⁴, c, d are the same as defined for Formula Ar-1; X, R⁵, R⁶, f are the same as defined Formula Ar-2; and e′ is an integer from 0 to 3.

A″ may be selected from the group consisting of a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group including at least one heteroatom selected from the group consisting of O, N, S, Si and P, a C₃-C₃₀ aliphatic ring group, and -L′-N(Rₐ)(R_{b}).

Formula 2-2 may be selected from the group consisting of Formula 2-3 to Formula 2-5.

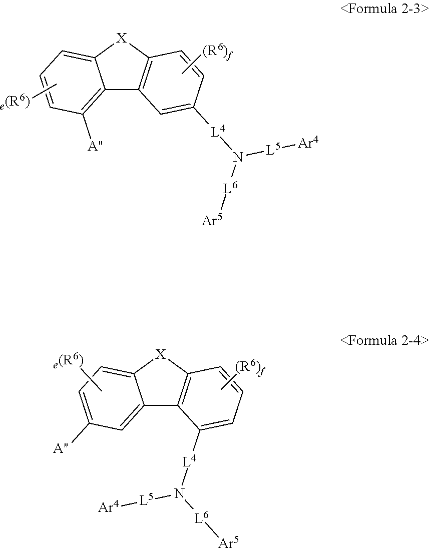

In Formula 2-3 and Formula 2-4, Ar⁴, Ar⁵, L⁴ to L⁶, X, R⁵, R⁶, A″, e′, f are the same as defined for Formula 2-2.

Formula 2-2 may be represented by Formula 2-5 when A″ is -L′-N(Rₐ)(R_{b}).

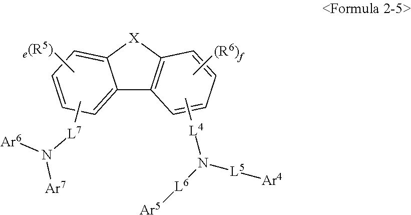

In Formula 2-5, L⁷ is defined in the same manner as L′, and Ar⁶ and Ar⁷ are defined in the same manner as Rₐ and R_{b}, respectively.

In Formula 1 and Formula 2, at least one of L¹ to L⁶ may be selected from the group consisting of Formulae L-1 to L-12.

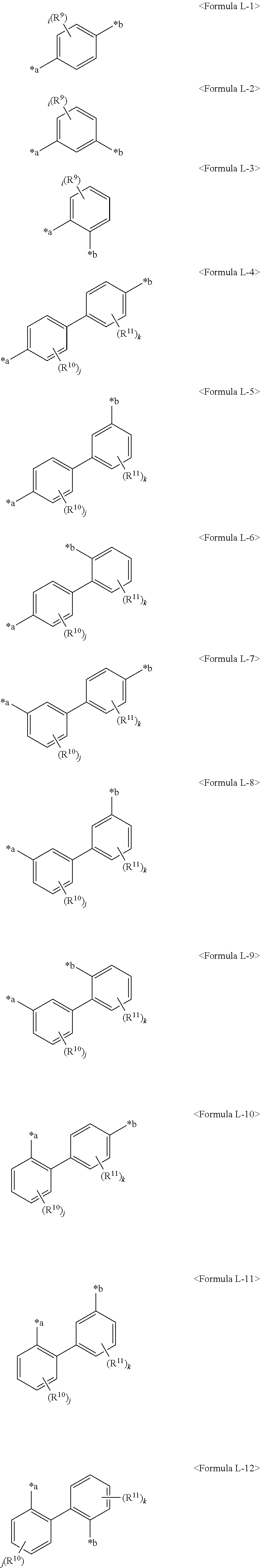

In Formula L-1 to Formula L-12, each symbol may be defined as follows.

The position indicated by *a is bonded to the nitrogen of the amine group in Formula 1 and Formula 2, and the position indicated by *b is bonded to the B ring in Formula 1 or to Ar¹ to Ar⁵ in Formula 2. For example, when L¹ is Formula L-1, *a is bonded to the nitrogen of the amine group and *b is bonded to the B ring; when L² is Formula L-1, *a is bonded to the nitrogen of the amine group and *b is bonded to Ar¹.

R⁹ to R¹¹ are each independently selected from the group consisting of hydrogen, deuterium, halogen, a silane group unsubstituted or substituted with a C₁-C₂₀ alkyl group or a C₆-C₂₀ aryl group, a phosphine oxide substituted or unsubstituted with a C₁-C₂₀ alkyl group or a C₆-C₂₀ aryl group, siloxane group, a cyano group, a nitro group, C₁-C₂₀ alkylthio group, C₁-C₂₀ alkoxy group, C₆-C₃₀ aryloxy group, C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group including at least one heteroatom selected from the group consisting of O, N, S, Si and P, a C₃-C₃₀ aliphatic ring group, and -L′-N(Rₐ)(R_{b}), and adjacent groups may be bonded to each other to form a ring.

i, j, k are each integers from 0 to 4. When any of these integers is 2 or more, each of the plurality of R⁹ groups, R¹⁰ groups, R¹¹ groups may be the same or different.

Even if the same symbol is used in Formulae L-1 to L-12, it may be defined differently depending on the specific formula. For example, when L¹ is Formula L-1 and L² is Formula L-2, a substituent R⁹ indicated by the same symbol may be the same or different in the two formulae.

Specifically, the compound represented by Formula 1 may be one of the following compounds, but there is no limitation thereto.

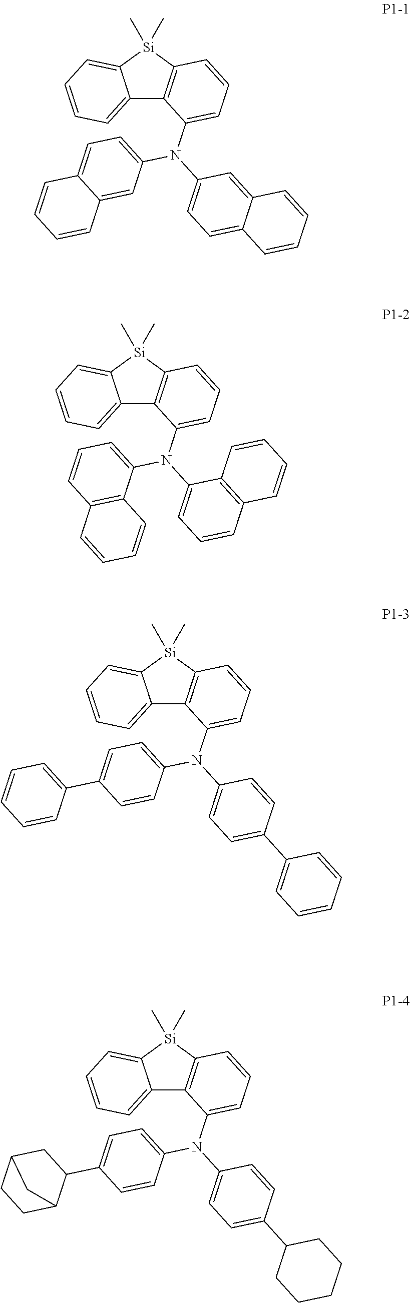 [SMILES: C[Si]1(C)c2ccccc2-c2c(N(c3ccc4ccccc4c3)c3ccc4ccccc4c3)cccc21 ; C[Si]1(C)c2ccccc2-c2c(N(c3cccc4ccccc34)c3cccc4ccccc34)cccc21 ; C[Si]1(C)c2ccccc2-c2c(N(c3ccc(-c4ccccc4)cc3)c3ccc(-c4ccccc4)cc3)cccc21 ; C[Si]1(C)c2ccccc2-c2c(N(c3ccc(C4CCCCC4)cc3)c3ccc(C4CC5CCC4C5)cc3)cccc21]

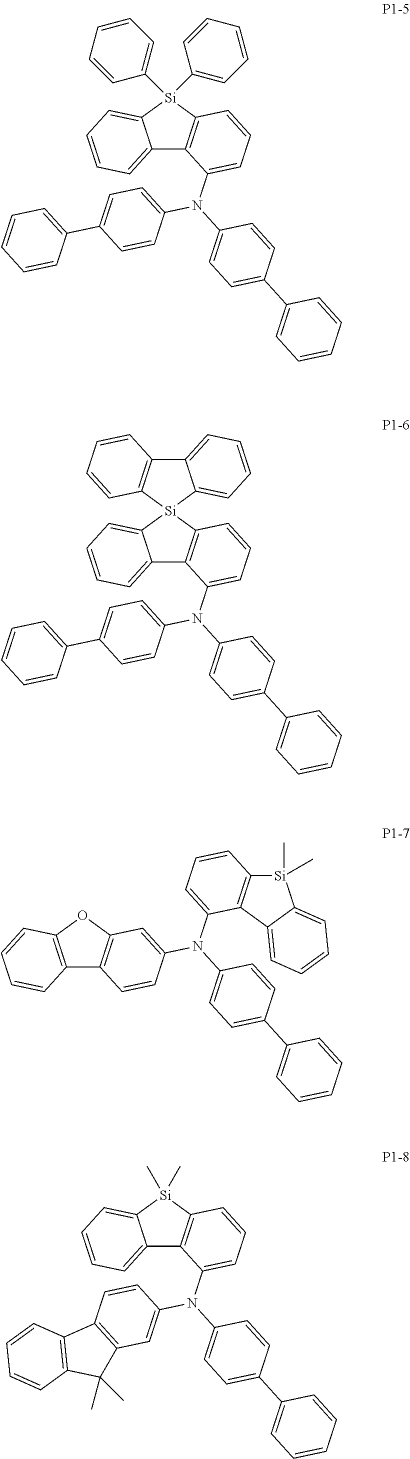 [SMILES: c1ccc(-c2ccc(N(c3ccc(-c4ccccc4)cc3)c3cccc4c3-c3ccccc3[Si]4(c3ccccc3)c3ccccc3)cc2)cc1 ; c1ccc(-c2ccc(N(c3ccc(-c4ccccc4)cc3)c3cccc4c3-c3ccccc3[Si]43c4ccccc4-c4ccccc43)cc2)cc1 ; C[Si]1(C)c2ccccc2-c2c(N(c3ccc(-c4ccccc4)cc3)c3ccc4c(c3)oc3ccccc34)cccc21 ; CC1(C)c2ccccc2-c2ccc(N(c3ccc(-c4ccccc4)cc3)c3cccc4c3-c3ccccc3[Si]4(C)C)cc21]

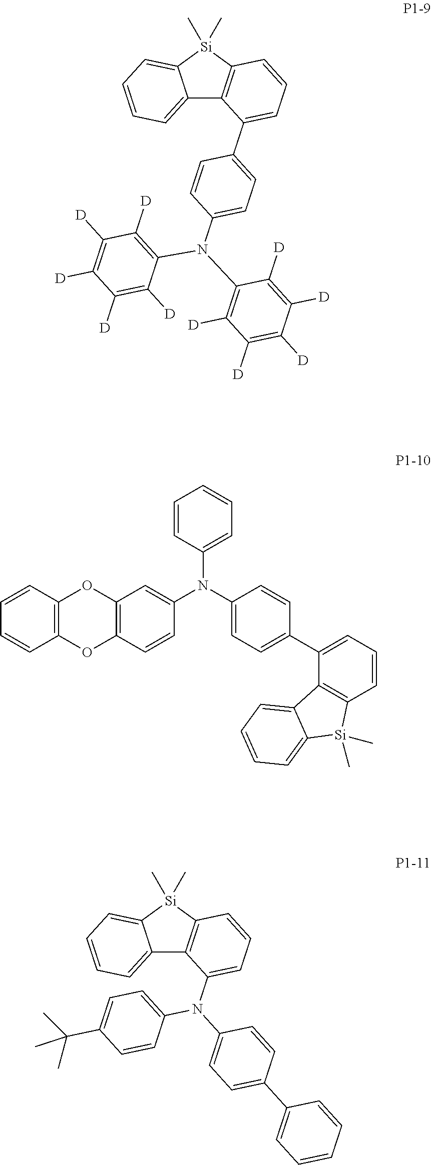 [SMILES: [2H]c1c([2H])c([2H])c(N(c2ccc(-c3cccc4c3-c3ccccc3[Si]4(C)C)cc2)c2c([2H])c([2H])c([2H])c([2H])c2[2H])c([2H])c1[2H] ; C[Si]1(C)c2ccccc2-c2c(-c3ccc(N(c4ccccc4)c4ccc5c(c4)Oc4ccccc4O5)cc3)cccc21 ; CC(C)(C)c1ccc(N(c2ccc(-c3ccccc3)cc2)c2cccc3c2-c2ccccc2[Si]3(C)C)cc1]

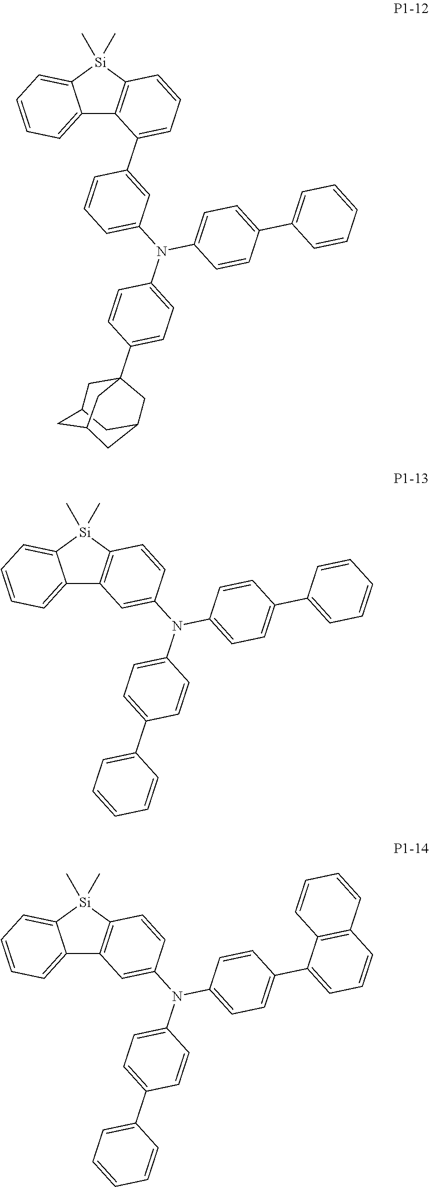 [SMILES: C[Si]1(C)c2ccccc2-c2c(-c3cccc(N(c4ccc(-c5ccccc5)cc4)c4ccc(C56CC7CC(CC(C7)C5)C6)cc4)c3)cccc21 ; C[Si]1(C)c2ccccc2-c2cc(N(c3ccc(-c4ccccc4)cc3)c3ccc(-c4ccccc4)cc3)ccc21 ; C[Si]1(C)c2ccccc2-c2cc(N(c3ccc(-c4ccccc4)cc3)c3ccc(-c4cccc5ccccc45)cc3)ccc21]

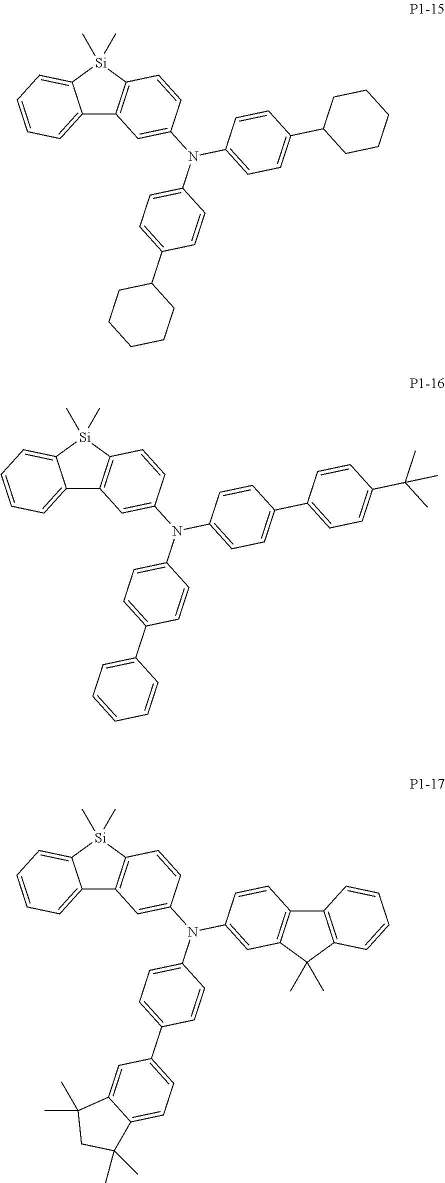 [SMILES: C[Si]1(C)c2ccccc2-c2cc(N(c3ccc(C4CCCCC4)cc3)c3ccc(C4CCCCC4)cc3)ccc21 ; CC(C)(C)c1ccc(-c2ccc(N(c3ccc(-c4ccccc4)cc3)c3ccc4c(c3)-c3ccccc3[Si]4(C)C)cc2)cc1 ; CC1(C)CC(C)(C)c2cc(-c3ccc(N(c4ccc5c(c4)-c4ccccc4[Si]5(C)C)c4ccc5c(c4)C(C)(C)c4ccccc4-5)cc3)ccc21]

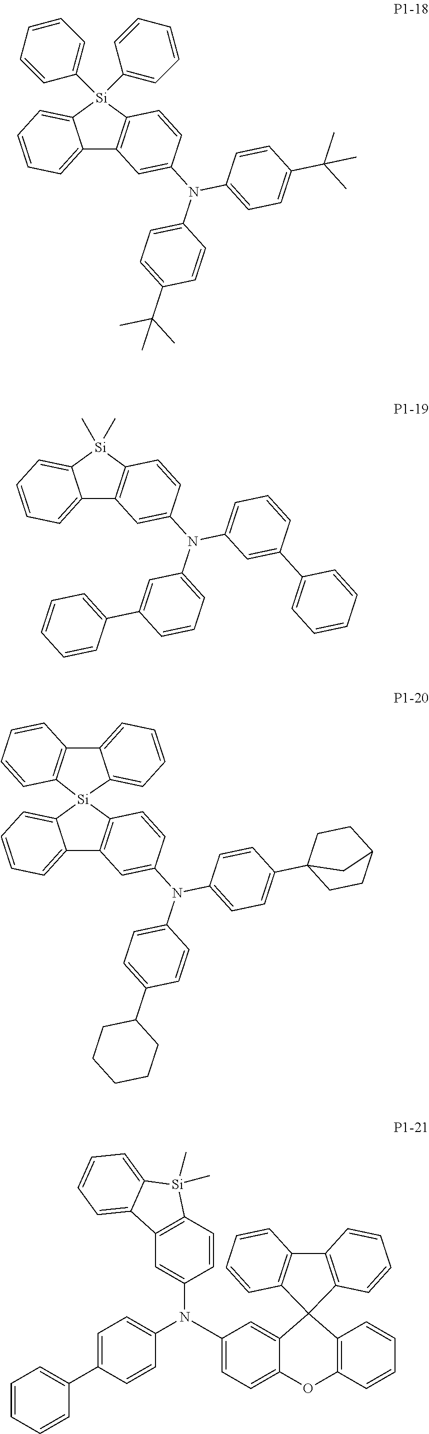 [SMILES: CC(C)(C)c1ccc(N(c2ccc(C(C)(C)C)cc2)c2ccc3c(c2)-c2ccccc2[Si]3(c2ccccc2)c2ccccc2)cc1 ; C[Si]1(C)c2ccccc2-c2cc(N(c3cccc(-c4ccccc4)c3)c3cccc(-c4ccccc4)c3)ccc21 ; c1ccc2c(c1)-c1ccccc1[Si]21c2ccccc2-c2cc(N(c3ccc(C4CCCCC4)cc3)c3ccc(C45CCC(CC4)C5)cc3)ccc21 ; C[Si]1(C)c2ccccc2-c2cc(N(c3ccc(-c4ccccc4)cc3)c3ccc4c(c3)C3(c5ccccc5O4)c4ccccc4-c4ccccc43)ccc21]

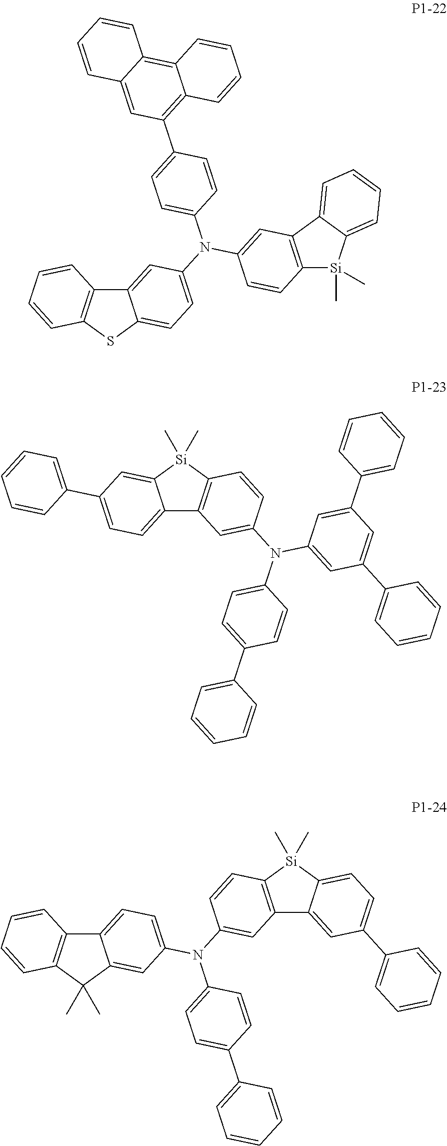 [SMILES: C[Si]1(C)c2ccccc2-c2cc(N(c3ccc(-c4cc5ccccc5c5ccccc45)cc3)c3ccc4sc5ccccc5c4c3)ccc21 ; C[Si]1(C)c2ccc(N(c3ccc(-c4ccccc4)cc3)c3cc(-c4ccccc4)cc(-c4ccccc4)c3)cc2-c2ccc(-c3ccccc3)cc21 ; CC1(C)c2ccccc2-c2ccc(N(c3ccc(-c4ccccc4)cc3)c3ccc4c(c3)-c3cc(-c5ccccc5)ccc3[Si]4(C)C)cc21]

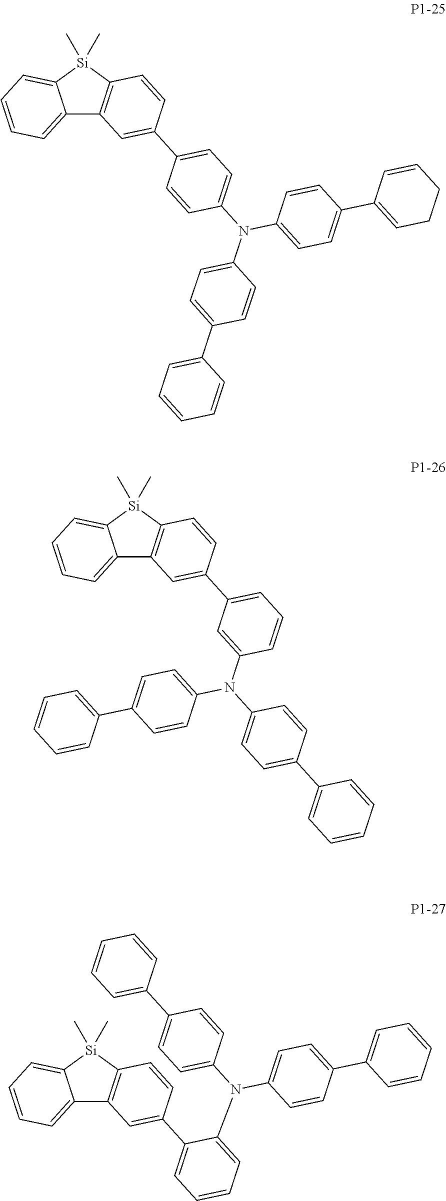 [SMILES: C[Si]1(C)c2ccccc2-c2cc(-c3ccc(N(c4ccc(C5=CCCC=C5)cc4)c4ccc(-c5ccccc5)cc4)cc3)ccc21 ; C[Si]1(C)c2ccccc2-c2cc(-c3cccc(N(c4ccc(-c5ccccc5)cc4)c4ccc(-c5ccccc5)cc4)c3)ccc21 ; C[Si]1(C)c2ccccc2-c2cc(-c3ccccc3N(c3ccc(-c4ccccc4)cc3)c3ccc(-c4ccccc4)cc3)ccc21]

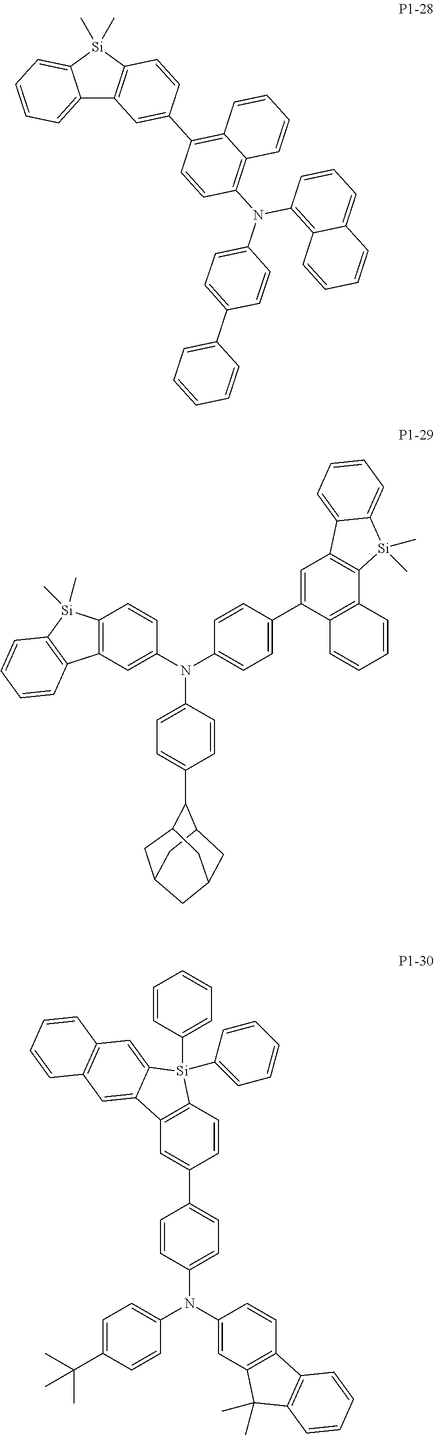 [SMILES: C[Si]1(C)c2ccccc2-c2cc(-c3ccc(N(c4ccc(-c5ccccc5)cc4)c4cccc5ccccc45)c4ccccc34)ccc21 ; C[Si]1(C)c2ccccc2-c2cc(N(c3ccc(-c4cc5c(c6ccccc46)[Si](C)(C)c4ccccc4-5)cc3)c3ccc(C4C5CC6CC(C5)CC4C6)cc3)ccc21 ; CC(C)(C)c1ccc(N(c2ccc(-c3ccc4c(c3)-c3cc5ccccc5cc3[Si]4(c3ccccc3)c3ccccc3)cc2)c2ccc3c(c2)C(C)(C)c2ccccc2-3)cc1]

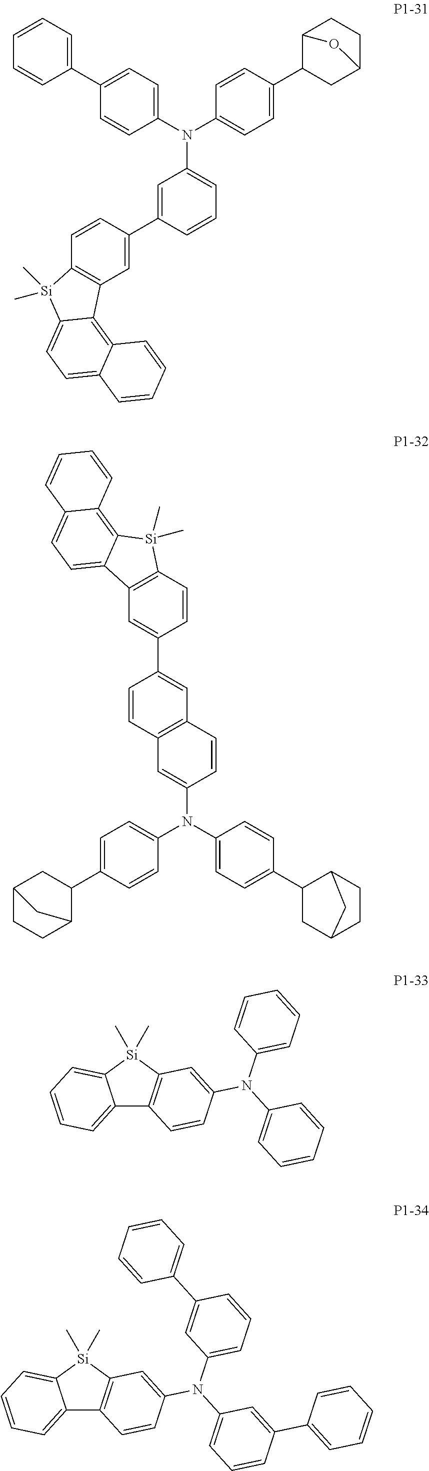 [SMILES: C[Si]1(C)c2ccc(-c3cccc(N(c4ccc(-c5ccccc5)cc4)c4ccc(C5CC6CCC5O6)cc4)c3)cc2-c2c1ccc1ccccc21 ; C[Si]1(C)c2ccc(-c3ccc4cc(N(c5ccc(C6CC7CCC6C7)cc5)c5ccc(C6CC7CCC6C7)cc5)ccc4c3)cc2-c2ccc3ccccc3c21 ; C[Si]1(C)c2ccccc2-c2ccc(N(c3ccccc3)c3ccccc3)cc21 ; C[Si]1(C)c2ccccc2-c2ccc(N(c3cccc(-c4ccccc4)c3)c3cccc(-c4ccccc4)c3)cc21]

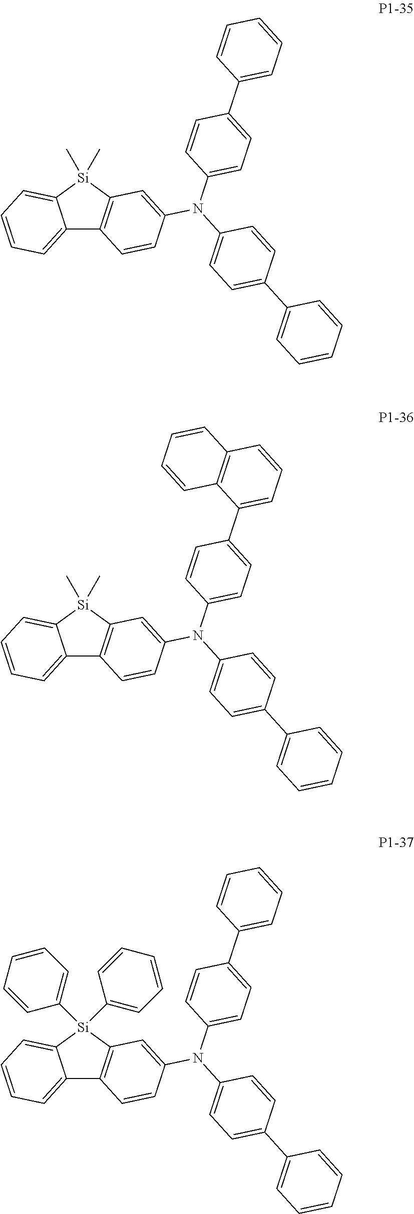 [SMILES: C[Si]1(C)c2ccccc2-c2ccc(N(c3ccc(-c4ccccc4)cc3)c3ccc(-c4ccccc4)cc3)cc21 ; C[Si]1(C)c2ccccc2-c2ccc(N(c3ccc(-c4ccccc4)cc3)c3ccc(-c4cccc5ccccc45)cc3)cc21 ; c1ccc(-c2ccc(N(c3ccc(-c4ccccc4)cc3)c3ccc4c(c3)[Si](c3ccccc3)(c3ccccc3)c3ccccc3-4)cc2)cc1]

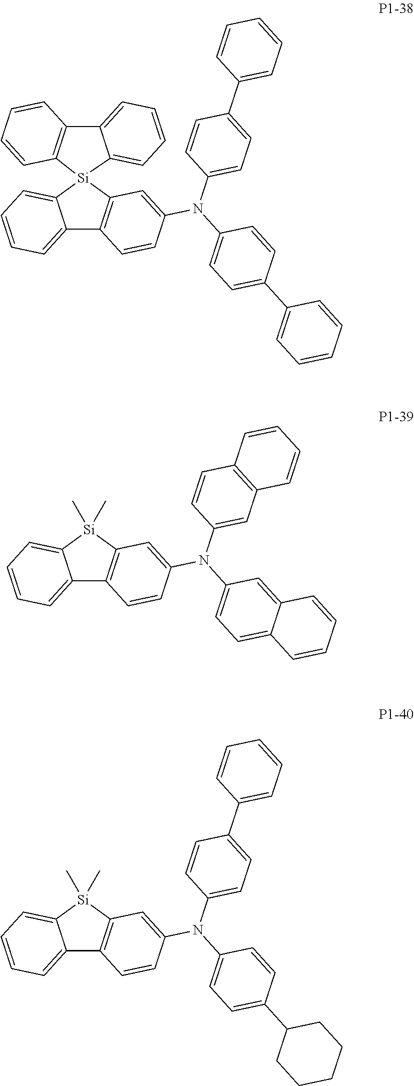 [SMILES: c1ccc(-c2ccc(N(c3ccc(-c4ccccc4)cc3)c3ccc4c(c3)[Si]3(c5ccccc5-c5ccccc53)c3ccccc3-4)cc2)cc1 ; C[Si]1(C)c2ccccc2-c2ccc(N(c3ccc4ccccc4c3)c3ccc4ccccc4c3)cc21 ; C[Si]1(C)c2ccccc2-c2ccc(N(c3ccc(-c4ccccc4)cc3)c3ccc(C4CCCCC4)cc3)cc21]

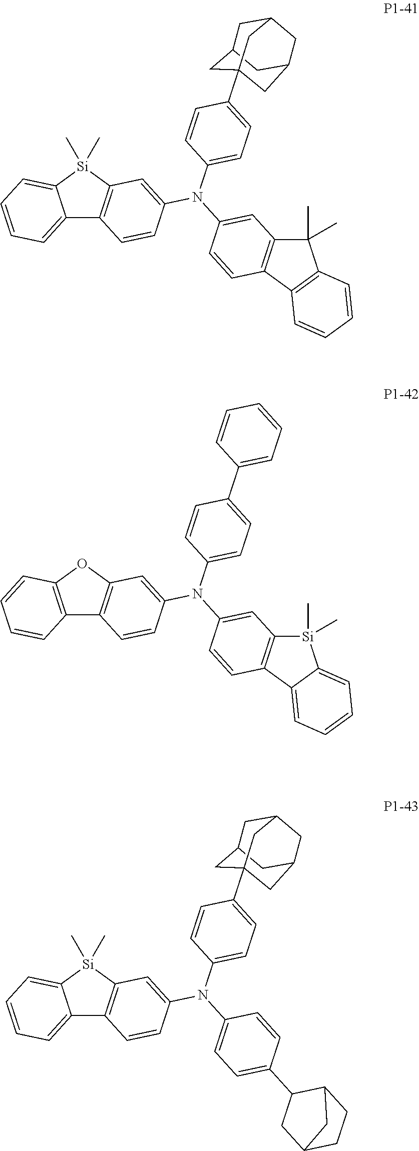 [SMILES: CC1(C)c2ccccc2-c2ccc(N(c3ccc(C45CC6CC(CC(C6)C4)C5)cc3)c3ccc4c(c3)[Si](C)(C)c3ccccc3-4)cc21 ; C[Si]1(C)c2ccccc2-c2ccc(N(c3ccc(-c4ccccc4)cc3)c3ccc4c(c3)oc3ccccc34)cc21 ; C[Si]1(C)c2ccccc2-c2ccc(N(c3ccc(C4CC5CCC4C5)cc3)c3ccc(C45CC6CC(CC(C6)C4)C5)cc3)cc21]

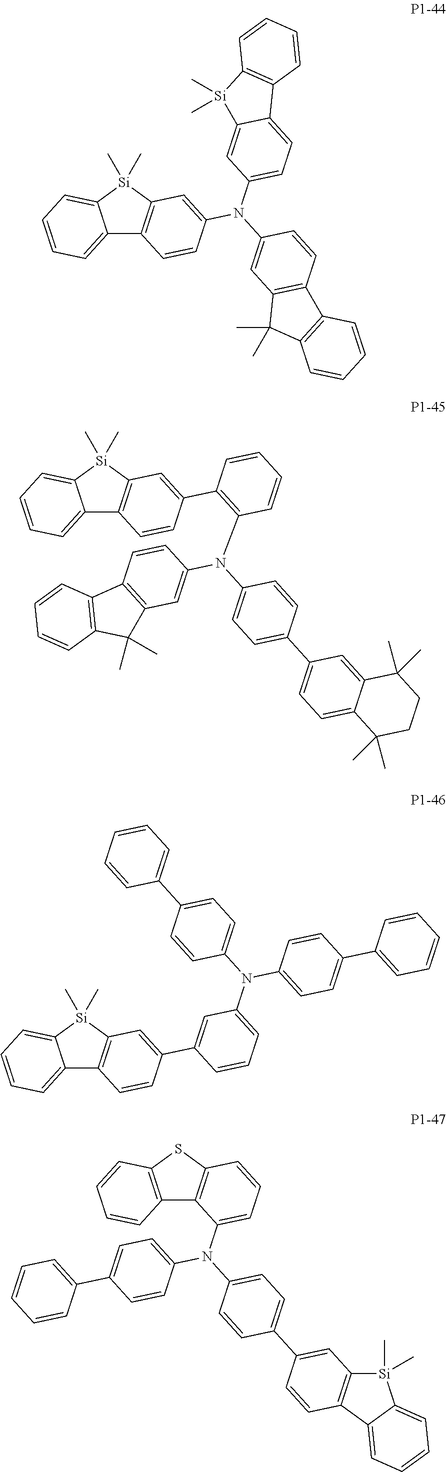 [SMILES: CC1(C)c2ccccc2-c2ccc(N(c3ccc4c(c3)[Si](C)(C)c3ccccc3-4)c3ccc4c(c3)[Si](C)(C)c3ccccc3-4)cc21 ; CC1(C)CCC(C)(C)c2cc(-c3ccc(N(c4ccc5c(c4)C(C)(C)c4ccccc4-5)c4ccccc4-c4ccc5c(c4)[Si](C)(C)c4ccccc4-5)cc3)ccc21 ; C[Si]1(C)c2ccccc2-c2ccc(-c3cccc(N(c4ccc(-c5ccccc5)cc4)c4ccc(-c5ccccc5)cc4)c3)cc21 ; C[Si]1(C)c2ccccc2-c2ccc(-c3ccc(N(c4ccc(-c5ccccc5)cc4)c4cccc5sc6ccccc6c45)cc3)cc21]

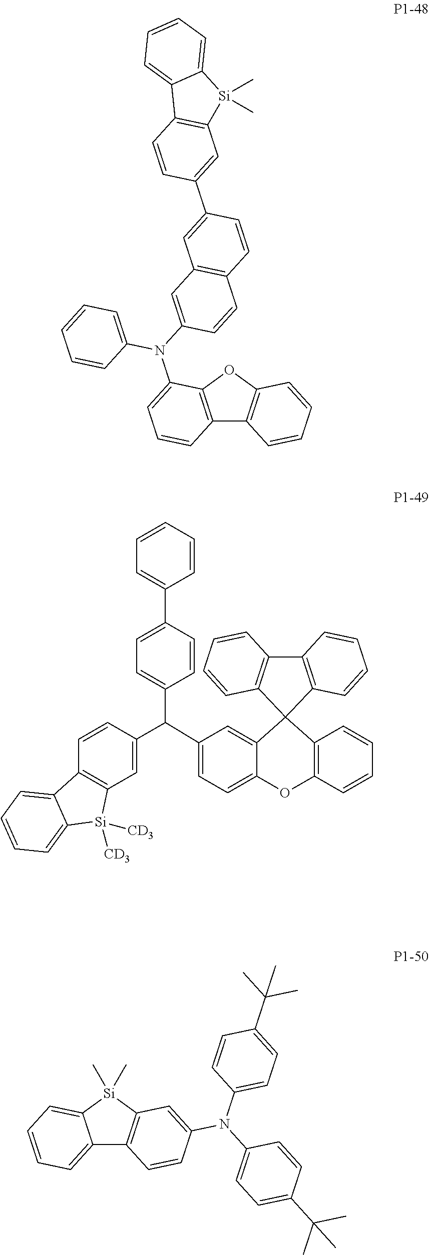 [SMILES: C[Si]1(C)c2ccccc2-c2ccc(-c3ccc4ccc(N(c5ccccc5)c5cccc6c5oc5ccccc56)cc4c3)cc21 ; [2H]C([2H])([2H])[Si]1(C([2H])([2H])[2H])c2ccccc2-c2ccc(C(c3ccc(-c4ccccc4)cc3)c3ccc4c(c3)C3(c5ccccc5O4)c4ccccc4-c4ccccc43)cc21 ; CC(C)(C)c1ccc(N(c2ccc(C(C)(C)C)cc2)c2ccc3c(c2)[Si](C)(C)c2ccccc2-3)cc1]

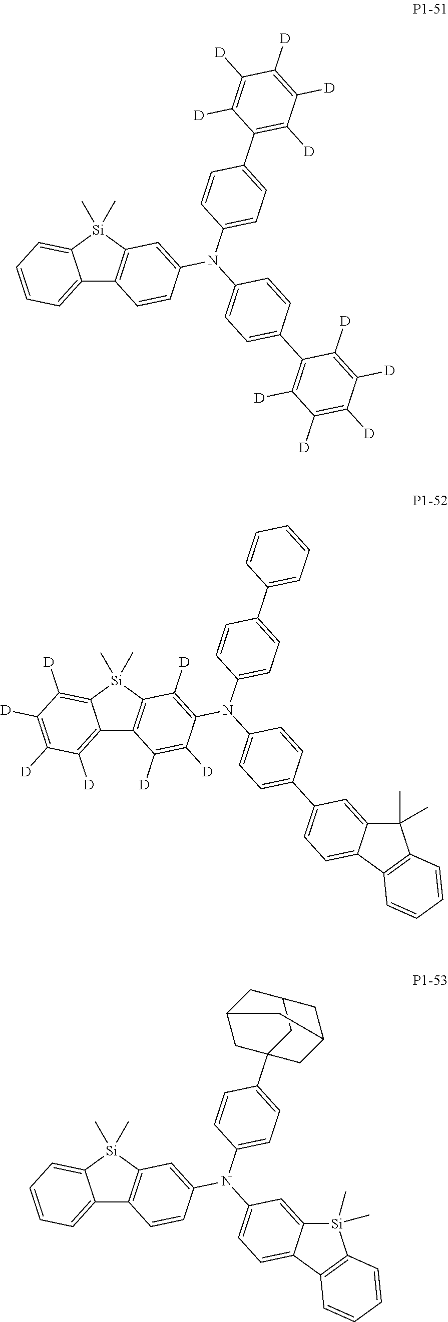 [SMILES: [2H]c1c([2H])c([2H])c(-c2ccc(N(c3ccc(-c4c([2H])c([2H])c([2H])c([2H])c4[2H])cc3)c3ccc4c(c3)[Si](C)(C)c3ccccc3-4)cc2)c([2H])c1[2H] ; [2H]c1c([2H])c([2H])c2c(c1[2H])-c1c([2H])c([2H])c(N(c3ccc(-c4ccccc4)cc3)c3ccc(-c4ccc5c(c4)C(C)(C)c4ccccc4-5)cc3)c([2H])c1[Si]2(C)C ; C[Si]1(C)c2ccccc2-c2ccc(N(c3ccc(C45CC6CC(CC(C6)C4)C5)cc3)c3ccc4c(c3)[Si](C)(C)c3ccccc3-4)cc21]

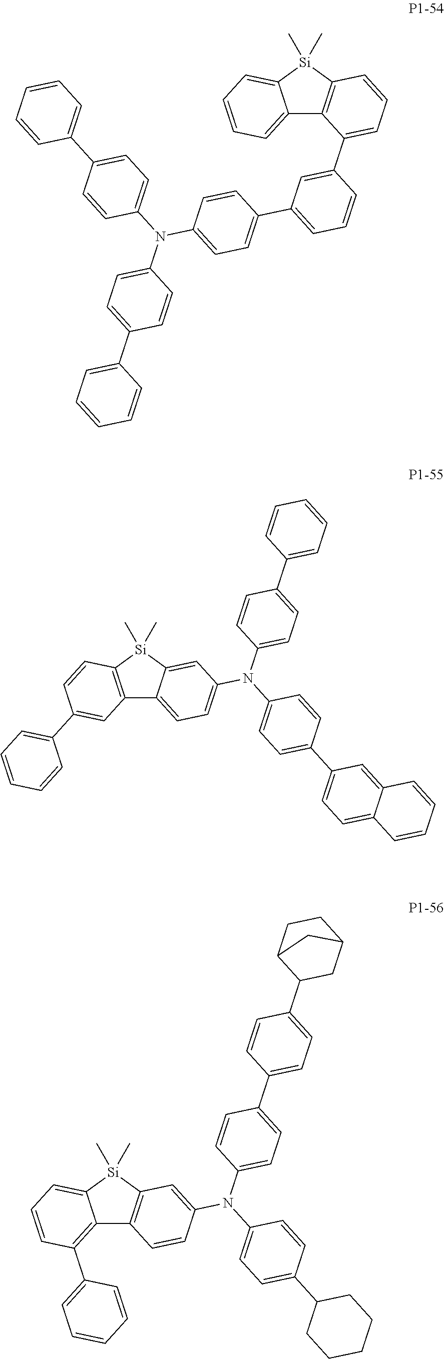 [SMILES: C[Si]1(C)c2ccccc2-c2c(-c3cccc(-c4ccc(N(c5ccc(-c6ccccc6)cc5)c5ccc(-c6ccccc6)cc5)cc4)c3)cccc21 ; C[Si]1(C)c2ccc(-c3ccccc3)cc2-c2ccc(N(c3ccc(-c4ccccc4)cc3)c3ccc(-c4ccc5ccccc5c4)cc3)cc21 ; C[Si]1(C)c2cc(N(c3ccc(-c4ccc(C5CC6CCC5C6)cc4)cc3)c3ccc(C4CCCCC4)cc3)ccc2-c2c(-c3ccccc3)cccc21]

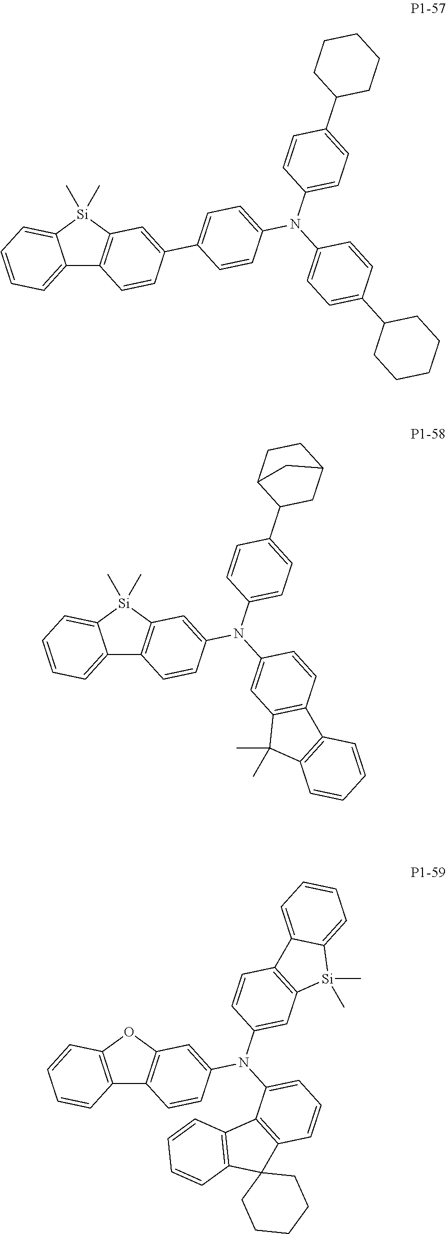 [SMILES: C[Si]1(C)c2ccccc2-c2ccc(-c3ccc(N(c4ccc(C5CCCCC5)cc4)c4ccc(C5CCCCC5)cc4)cc3)cc21 ; CC1(C)c2ccccc2-c2ccc(N(c3ccc(C4CC5CCC4C5)cc3)c3ccc4c(c3)[Si](C)(C)c3ccccc3-4)cc21 ; C[Si]1(C)c2ccccc2-c2ccc(N(c3ccc4c(c3)oc3ccccc34)c3cccc4c3-c3ccccc3C43CCCCC3)cc21]

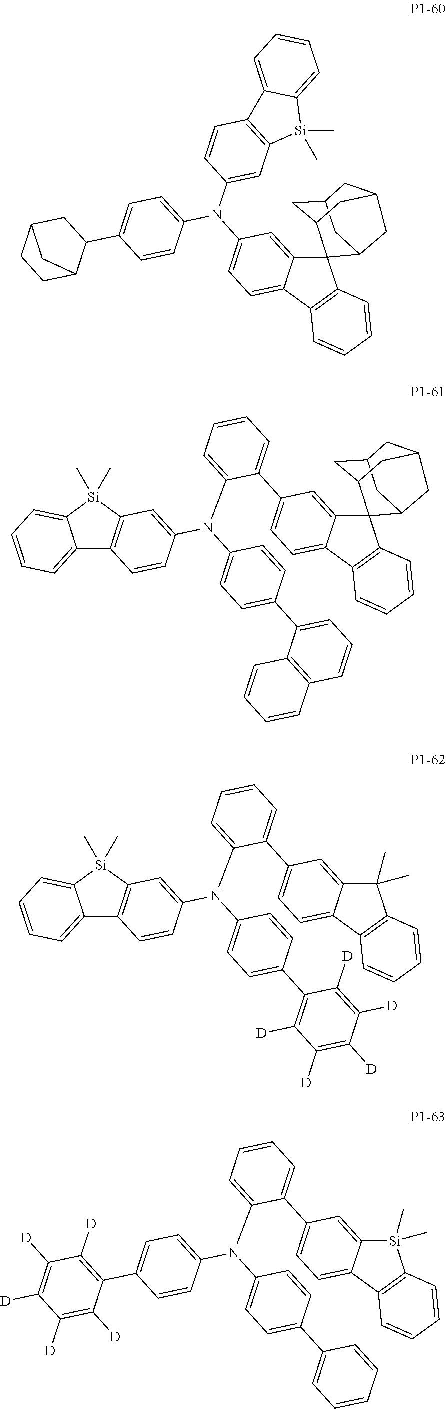 [SMILES: C[Si]1(C)c2ccccc2-c2ccc(N(c3ccc(C4CC5CCC4C5)cc3)c3ccc4c(c3)C3(c5ccccc5-4)C4CC5CC(C4)CC3C5)cc21 ; C[Si]1(C)c2ccccc2-c2ccc(N(c3ccc(-c4cccc5ccccc45)cc3)c3ccccc3-c3ccc4c(c3)C3(c5ccccc5-4)C4CC5CC(C4)CC3C5)cc21 ; [2H]c1c([2H])c([2H])c(-c2ccc(N(c3ccc4c(c3)[Si](C)(C)c3ccccc3-4)c3ccccc3-c3ccc4c(c3)C(C)(C)c3ccccc3-4)cc2)c([2H])c1[2H] ; [2H]c1c([2H])c([2H])c(-c2ccc(N(c3ccc(-c4ccccc4)cc3)c3ccccc3-c3ccc4c(c3)[Si](C)(C)c3ccccc3-4)cc2)c([2H])c1[2H]]

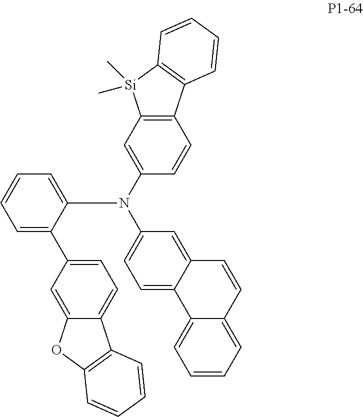 [SMILES: C[Si]1(C)c2ccccc2-c2ccc(N(c3ccc4c(ccc5ccccc54)c3)c3ccccc3-c3ccc4c(c3)oc3ccccc34)cc21]

Specifically, the compound represented by Formula 2 may be one of the following compounds, but there is no limitation thereto.

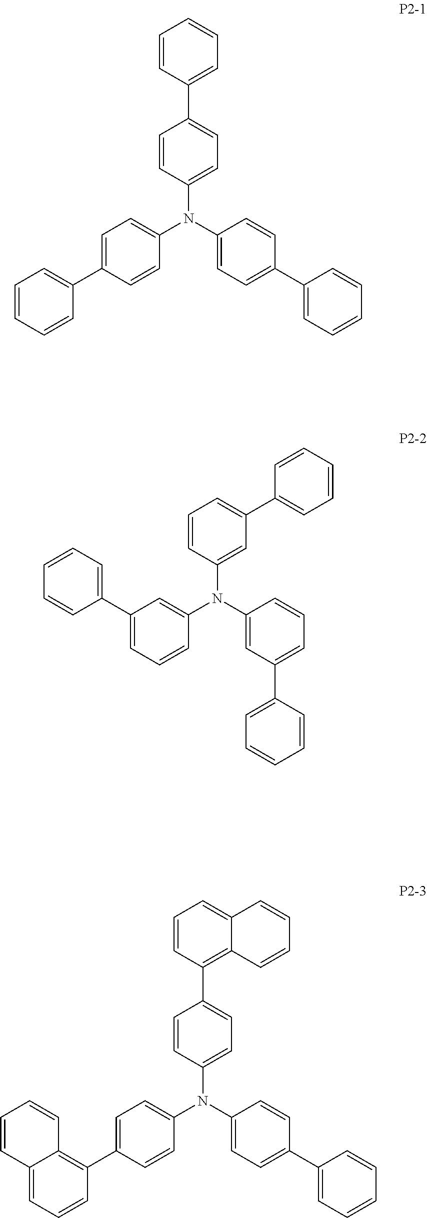 [SMILES: c1ccc(-c2ccc(N(c3ccc(-c4ccccc4)cc3)c3ccc(-c4ccccc4)cc3)cc2)cc1 ; c1ccc(-c2cccc(N(c3cccc(-c4ccccc4)c3)c3cccc(-c4ccccc4)c3)c2)cc1 ; c1ccc(-c2ccc(N(c3ccc(-c4cccc5ccccc45)cc3)c3ccc(-c4cccc5ccccc45)cc3)cc2)cc1]

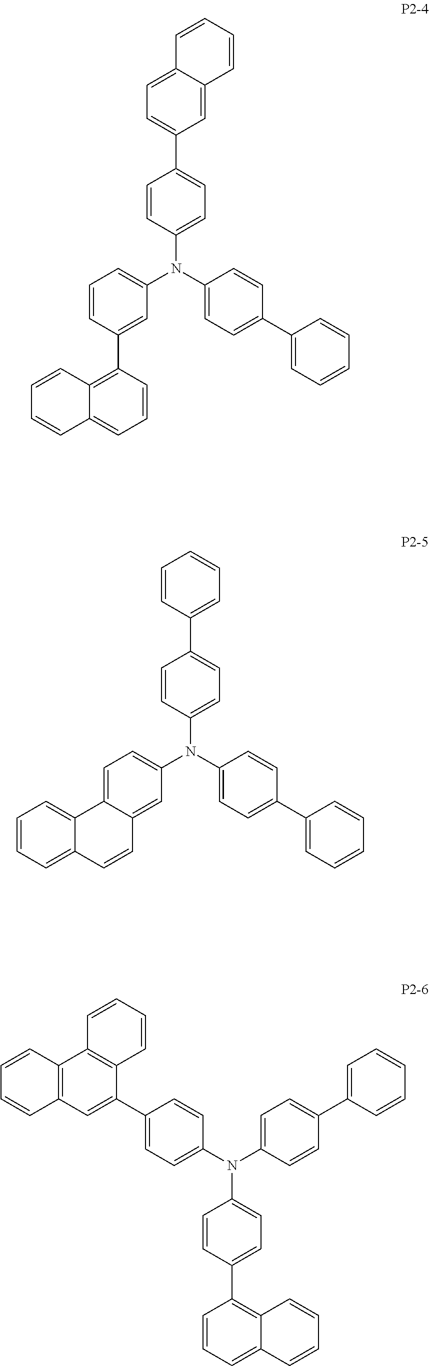 [SMILES: c1ccc(-c2ccc(N(c3ccc(-c4ccc5ccccc5c4)cc3)c3cccc(-c4cccc5ccccc45)c3)cc2)cc1 ; c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3ccc(-c4cc5ccccc5c5ccccc45)cc3)cc2)cc1]

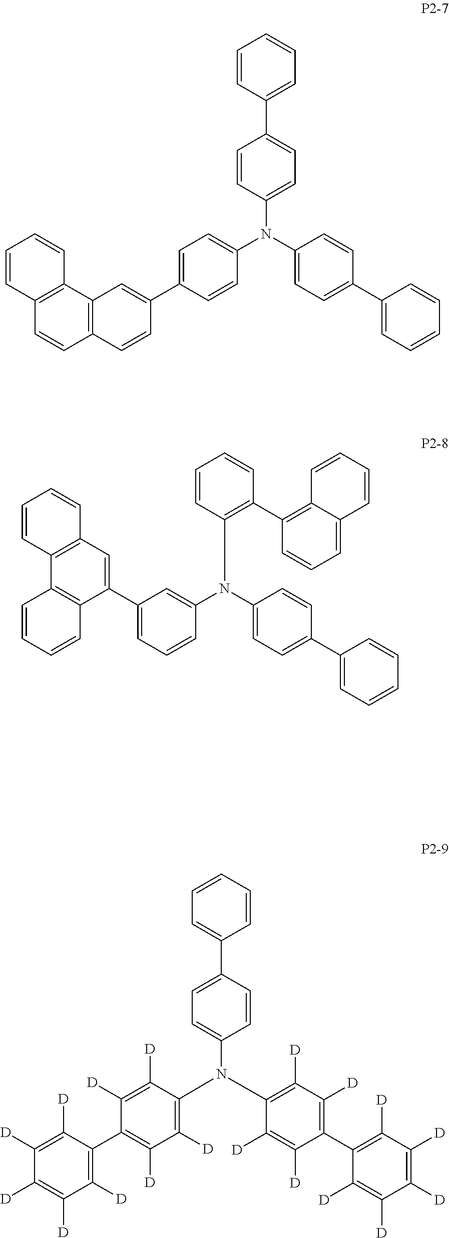 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1 ; [2H]c1c([2H])c([2H])c(-c2c([2H])c([2H])c(N(c3ccc(-c4ccccc4)cc3)c3c([2H])c([2H])c(-c4c([2H])c([2H])c([2H])c([2H])c4[2H])c([2H])c3[2H])c([2H])c2[2H])c([2H])c1[2H]]

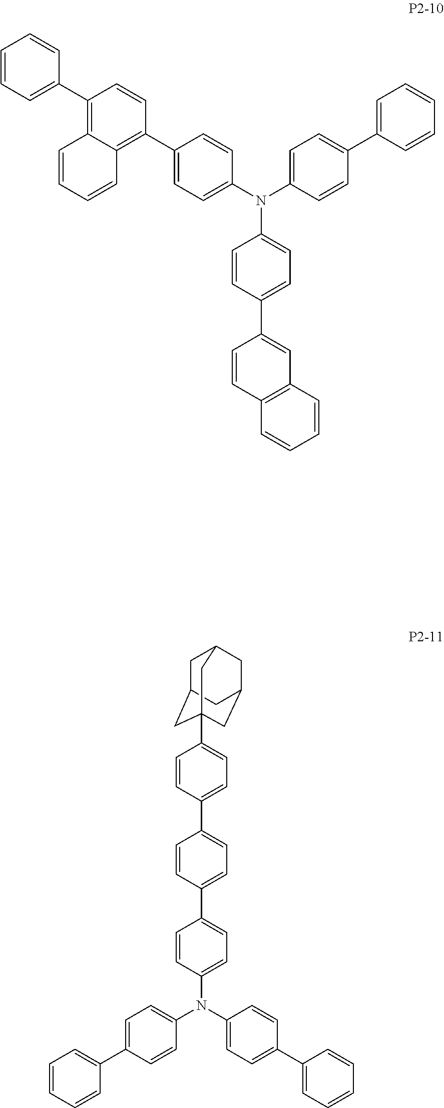 [SMILES: c1ccc(-c2ccc(N(c3ccc(-c4ccc5ccccc5c4)cc3)c3ccc(-c4ccc(-c5ccccc5)c5ccccc45)cc3)cc2)cc1 ; c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1]

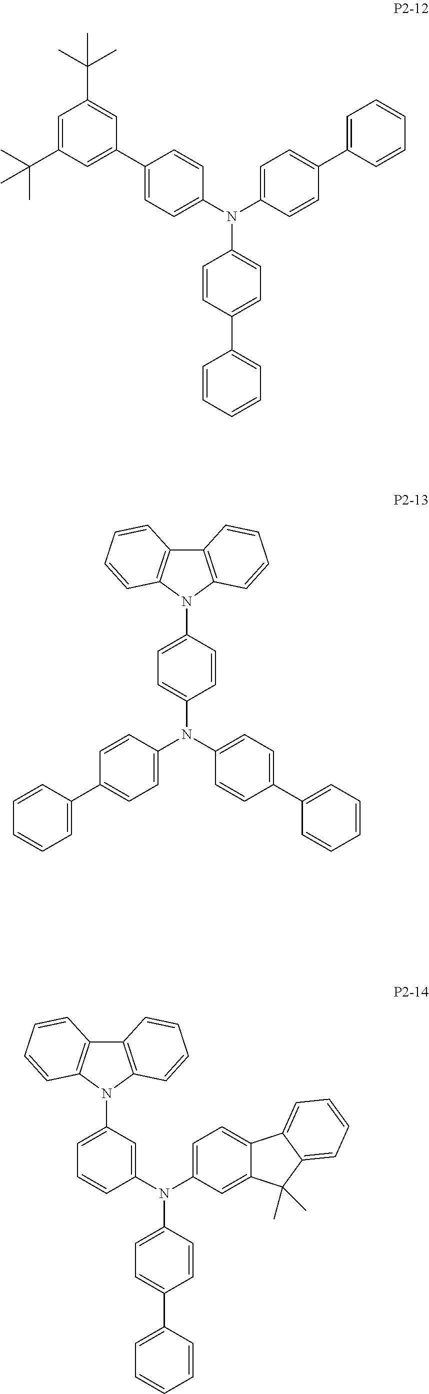 [SMILES: CC(C)(C)c1cc(-c2ccc(N(c3ccc(-c4ccccc4)cc3)c3ccc(-c4ccccc4)cc3)cc2)cc(C(C)(C)C)c1 ; c1ccc(-c2ccc(N(c3ccc(-c4ccccc4)cc3)c3ccc(-n4c5ccccc5c5ccccc54)cc3)cc2)cc1 ; CC1(C)c2ccccc2-c2ccc(N(c3ccc(-c4ccccc4)cc3)c3cccc(-n4c5ccccc5c5ccccc54)c3)cc21]

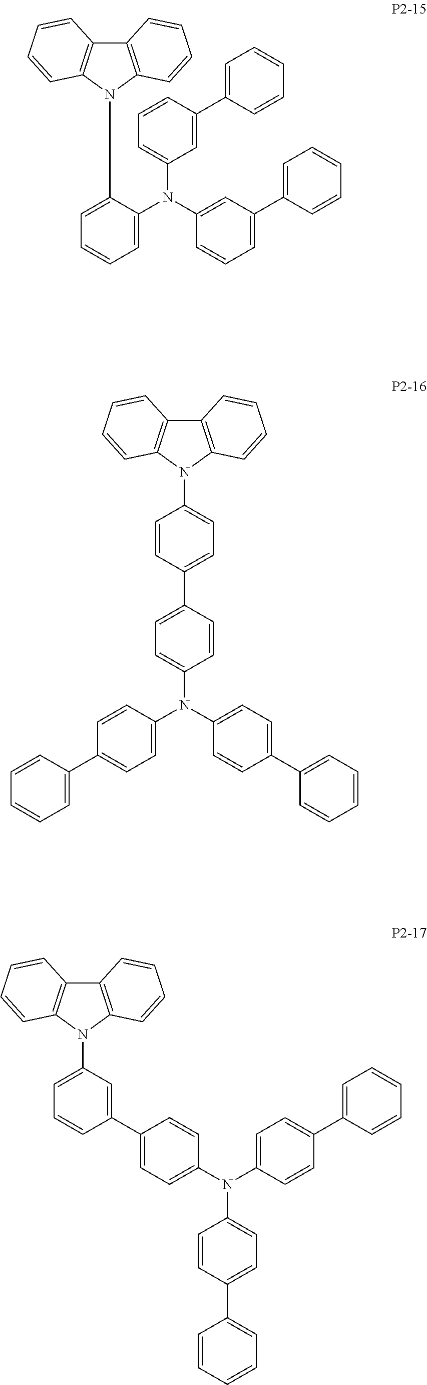 [SMILES: c1ccc(-c2cccc(N(c3cccc(-c4ccccc4)c3)c3ccccc3-n3c4ccccc4c4ccccc43)c2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4cccc(-n5c6ccccc6c6ccccc65)c4)cc3)cc2)cc1]

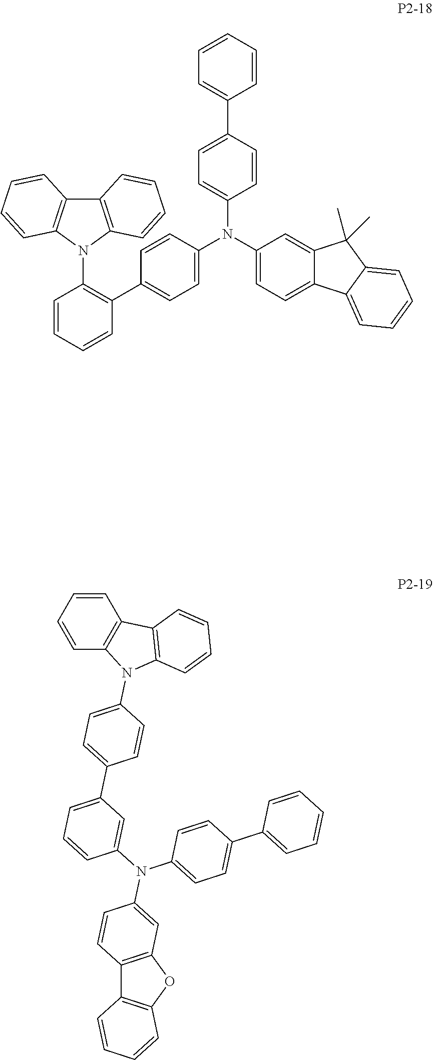 [SMILES: CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2ccc(N(c3cccc(-c4ccc(-n5c6ccccc6c6ccccc65)cc4)c3)c3ccc4c(c3)oc3ccccc34)cc2)cc1]

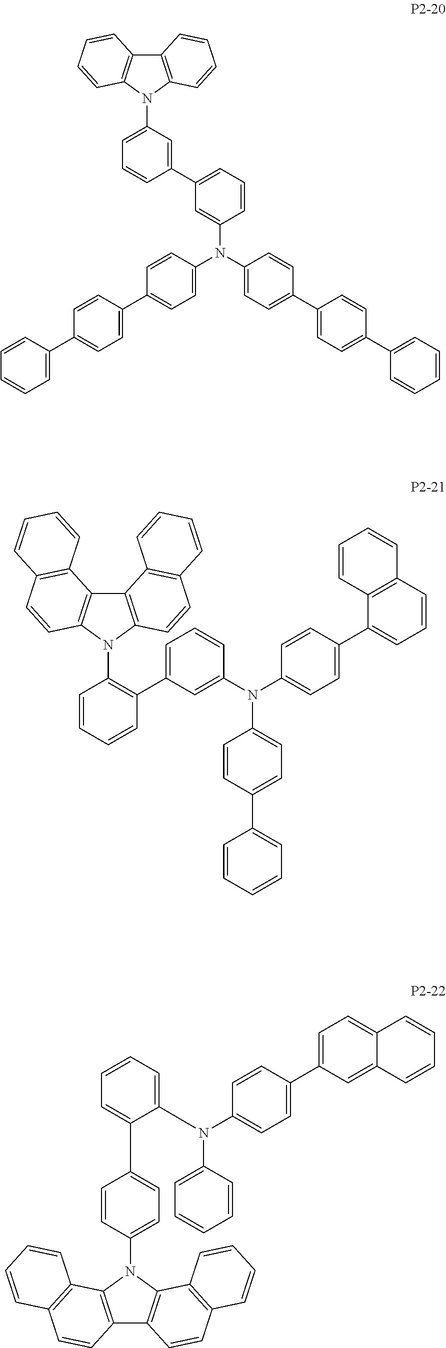 [SMILES: c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1 ; c1ccc(-c2ccc(N(c3ccc(-c4cccc5ccccc45)cc3)c3cccc(-c4ccccc4-n4c5ccc6ccccc6c5c5c6ccccc6ccc54)c3)cc2)cc1 ; c1ccc(N(c2ccc(-c3ccc4ccccc4c3)cc2)c2ccccc2-c2ccc(-n3c4c5ccccc5ccc4c4ccc5ccccc5c43)cc2)cc1]

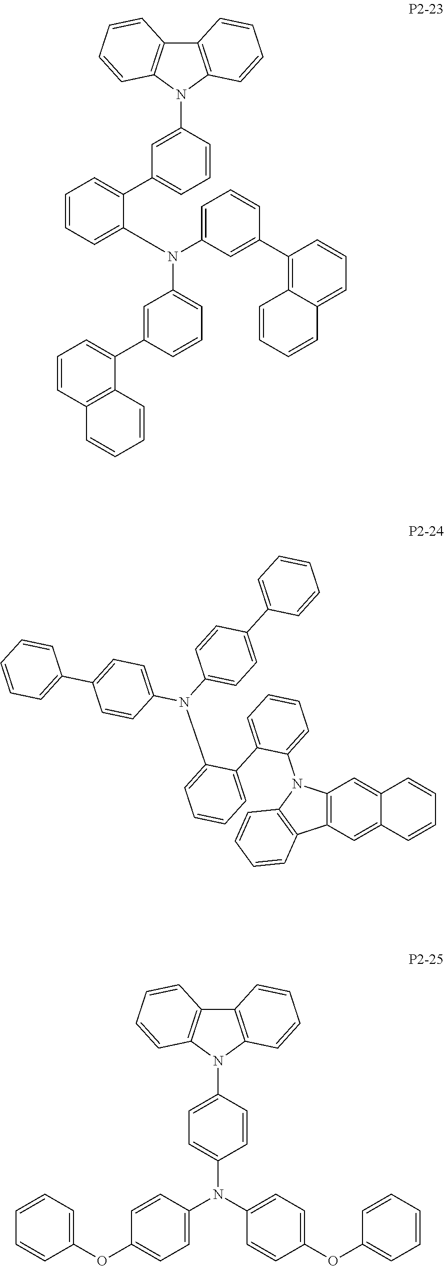 [SMILES: c1cc(-c2cccc3ccccc23)cc(N(c2cccc(-c3cccc4ccccc34)c2)c2ccccc2-c2cccc(-n3c4ccccc4c4ccccc43)c2)c1 ; c1ccc(-c2ccc(N(c3ccc(-c4ccccc4)cc3)c3ccccc3-c3ccccc3-n3c4ccccc4c4cc5ccccc5cc43)cc2)cc1 ; c1ccc(Oc2ccc(N(c3ccc(Oc4ccccc4)cc3)c3ccc(-n4c5ccccc5c5ccccc54)cc3)cc2)cc1]

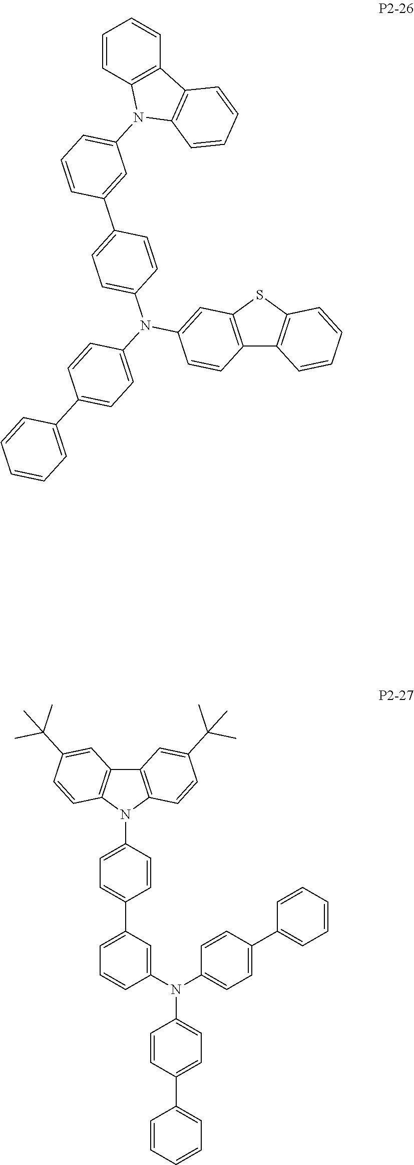 [SMILES: c1ccc(-c2ccc(N(c3ccc(-c4cccc(-n5c6ccccc6c6ccccc65)c4)cc3)c3ccc4c(c3)sc3ccccc34)cc2)cc1 ; CC(C)(C)c1ccc2c(c1)c1cc(C(C)(C)C)ccc1n2-c1ccc(-c2cccc(N(c3ccc(-c4ccccc4)cc3)c3ccc(-c4ccccc4)cc3)c2)cc1]

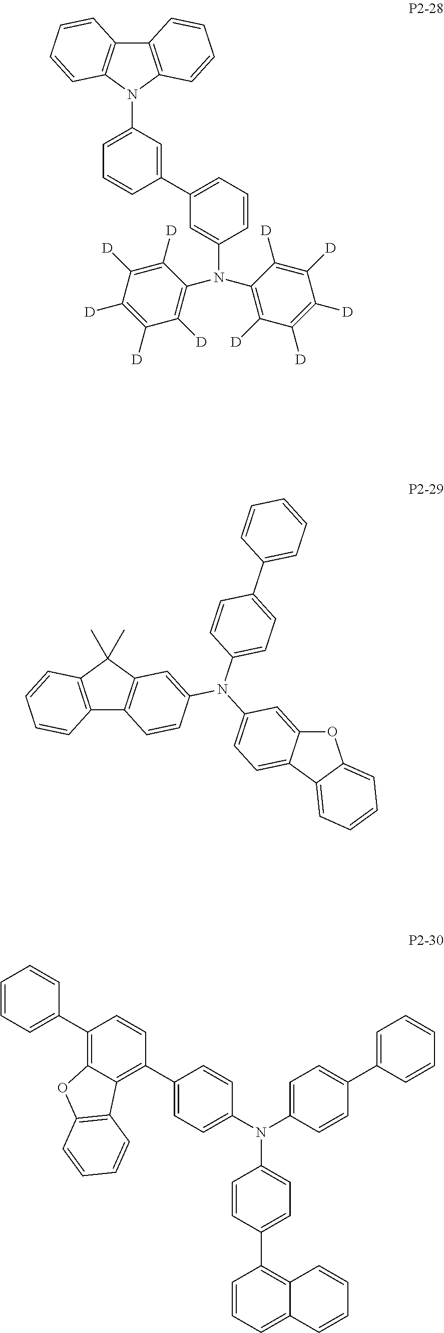 [SMILES: [2H]c1c([2H])c([2H])c(N(c2cccc(-c3cccc(-n4c5ccccc5c5ccccc54)c3)c2)c2c([2H])c([2H])c([2H])c([2H])c2[2H])c([2H])c1[2H] ; CC1(C)c2ccccc2-c2ccc(N(c3ccc(-c4ccccc4)cc3)c3ccc4c(c3)oc3ccccc34)cc21 ; c1ccc(-c2ccc(N(c3ccc(-c4cccc5ccccc45)cc3)c3ccc(-c4ccc(-c5ccccc5)c5oc6ccccc6c45)cc3)cc2)cc1]

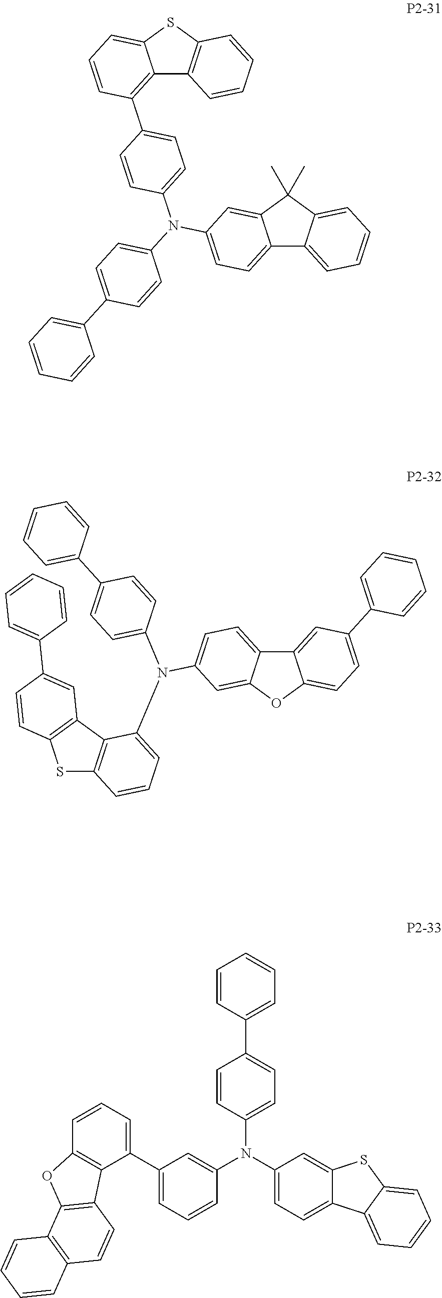 [SMILES: CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1 ; c1ccc(-c2ccc(N(c3cccc(-c4cccc5oc6c7ccccc7ccc6c45)c3)c3ccc4c(c3)sc3ccccc34)cc2)cc1]

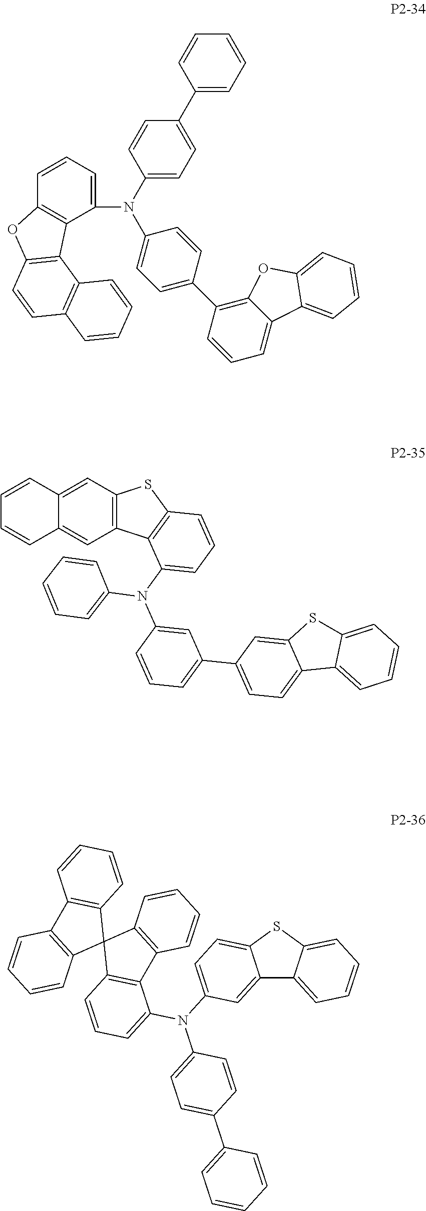 [SMILES: c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1 ; c1ccc(-c2ccc(N(c3ccc4sc5ccccc5c4c3)c3cccc4c3-c3ccccc3C43c4ccccc4-c4ccccc43)cc2)cc1]

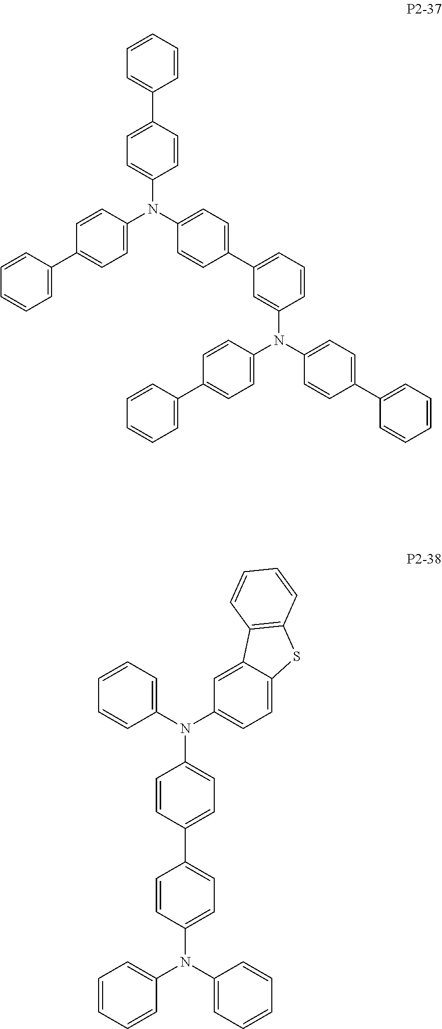 [SMILES: c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1]

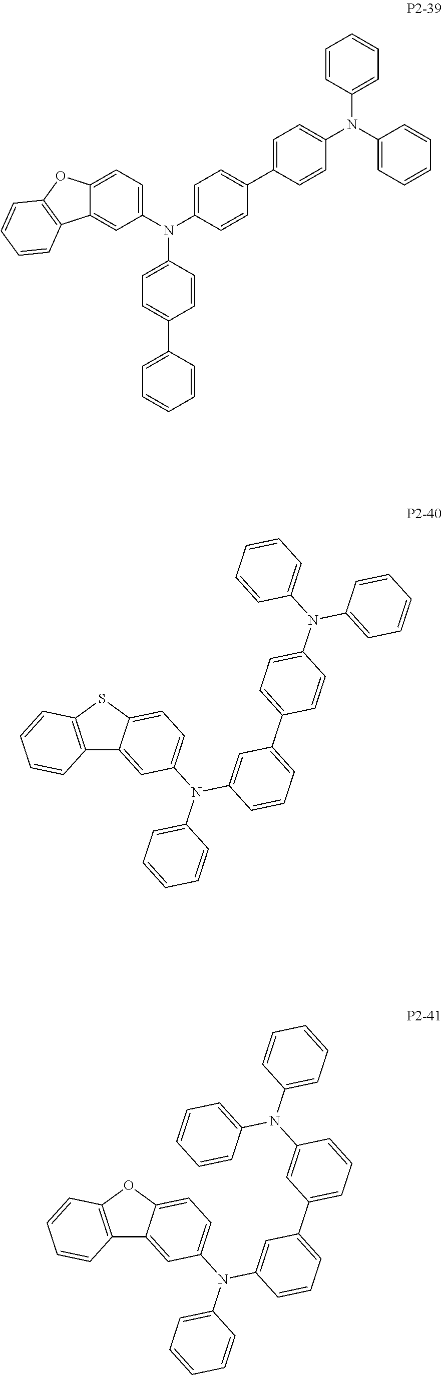 [SMILES: c1ccc(-c2ccc(N(c3ccc(-c4ccc(N(c5ccccc5)c5ccccc5)cc4)cc3)c3ccc4oc5ccccc5c4c3)cc2)cc1 ; c1ccc(N(c2ccccc2)c2ccc(-c3cccc(N(c4ccccc4)c4ccc5sc6ccccc6c5c4)c3)cc2)cc1 ; c1ccc(N(c2ccccc2)c2cccc(-c3cccc(N(c4ccccc4)c4ccc5oc6ccccc6c5c4)c3)c2)cc1]

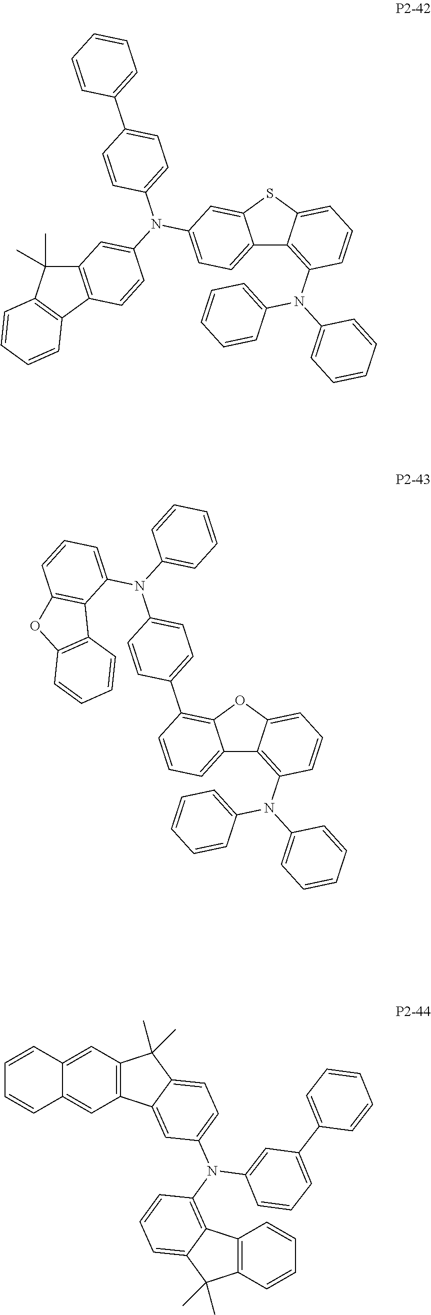 [SMILES: CC1(C)c2ccccc2-c2ccc(N(c3ccc(-c4ccccc4)cc3)c3ccc4c(c3)sc3cccc(N(c5ccccc5)c5ccccc5)c34)cc21 ; c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21]

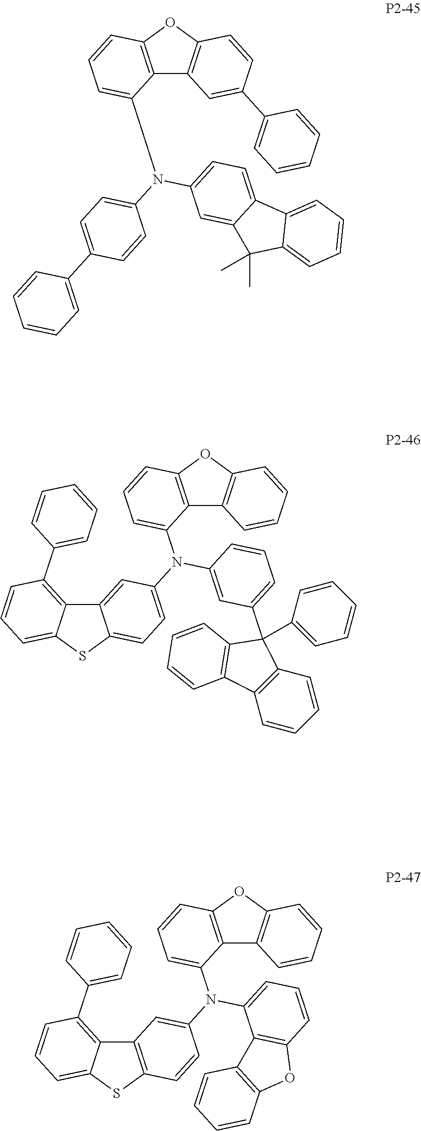 [SMILES: CC1(C)c2ccccc2-c2ccc(N(c3ccc(-c4ccccc4)cc3)c3cccc4oc5ccc(-c6ccccc6)cc5c34)cc21 ; c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1]

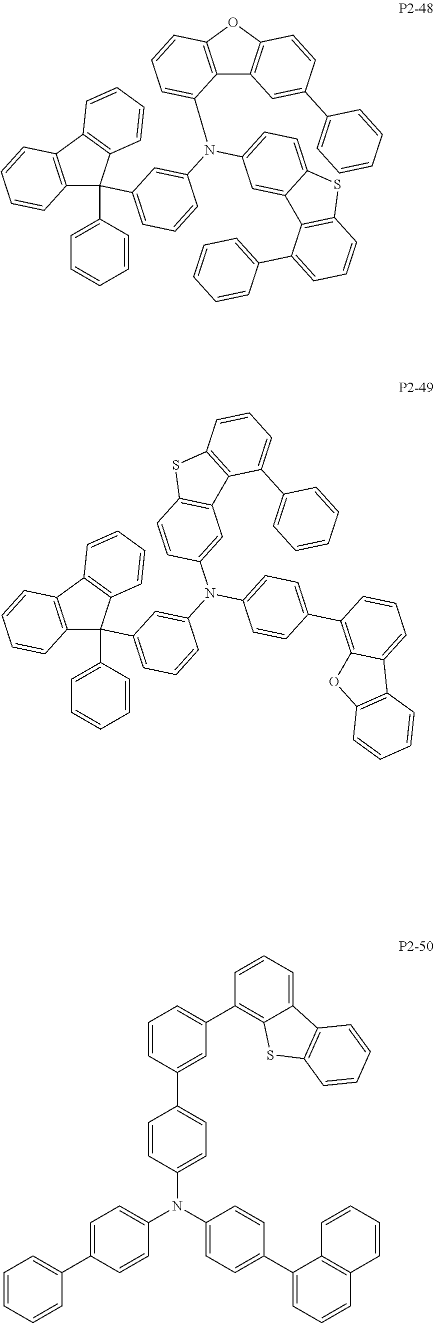 [SMILES: c1ccc(-c2ccc3oc4cccc(N(c5cccc(C6(c7ccccc7)c7ccccc7-c7ccccc76)c5)c5ccc6sc7cccc(-c8ccccc8)c7c6c5)c4c3c2)cc1 ; c1ccc(-c2cccc3sc4ccc(N(c5ccc(-c6cccc7c6oc6ccccc67)cc5)c5cccc(C6(c7ccccc7)c7ccccc7-c7ccccc76)c5)cc4c23)cc1 ; c1ccc(-c2ccc(N(c3ccc(-c4cccc(-c5cccc6c5sc5ccccc56)c4)cc3)c3ccc(-c4cccc5ccccc45)cc3)cc2)cc1]

The reorganization energy, particularly RE_{Hole}, of the compound of Formula 1 of the present invention included in the first light-emitting auxiliary layer affects the characteristics of the device. The reorganization energy (Reorganization Energy: RE) value of the compound of Formula 1 of the present invention may be in the range of 0.110 to 0.140.

Hereinafter, the reorganization energy is described.

Reorganization energy is the energy lost due to changes in molecular geometry during charge (electron or hole) transfer. It is dependent on molecular geometry and tends to be smaller when the difference between the potential energy surfaces (PES) of the neutral and charged states is smaller. The RE value can be obtained using the following equation.

$$R {E}_{h o l e} : {λ}^{+} = ( {E}_{N O C E} - {E}_{C O C E} ) + ( {E}_{C O N E} - {E}_{N O N E} ) \\ {RE}_{e l e c} : {λ}^{-} = ( {E}_{NOAE} - {E}_{A O A E} ) + ( {E}_{A O N E} - {E}_{N O N E} ) \\ NONE : Neutral geometry of neutral molecular ( = NO opt . ) \\ NOAE : Anion geometry of neutral molecular \\ NOCE : Catio n geometry of neutral molecular \\ AONE : Neutral geometry of Anion molecular \\ AOAE : Anion geometry of Anion molecular ( = AO opt . ) \\ CONE : Neutral geometry of cation molecular$$

$$COCE : Catio n geometry of cation molecular ( = CO opt . )$$

Reorganization energy and charge mobility have an inverse relationship. When r and T are held constant, the RE value directly influences the mobility of each material.

The relationship between reorganization energy (RE) and mobility can be expressed as the following equation, and it is described based on the charge transfer matrix element.

$$μ = k \frac{{r}^{2}}{2 {k}_{B} T / e} \\ k = ( \frac{4 {π}^{2}}{h} ) \frac{{t}^{2}}{\sqrt{4 π λ {k}_{B} T}} exp [ - \frac{λ}{4 {k}_{B} T} ] \\ λ : Reorganization energy \\ μ : mobility \\ r : dimer displacement \\ t : intermolecular charge transfer matrix element$$

As shown in the equation above, charge mobility increases as the RE value decreases.

To calculate the reorganization energy, a simulation tool that can compute the potential energy of a molecule based on its geometry is necessary. For example, Gaussian09 (hereinafter referred to as G09) and the Jaguar (hereinafter referred to as JG) module in Schrödinger Materials Science can be used. Both G09 and JG are quantum mechanical (QM) computational tools used for analyzing molecular properties, and they are capable of optimizing molecular structures and computing the single-point energy for a given molecular structure.

Quantum mechanical (QM) calculations performed on molecular structures require substantial computational resources. For example, such calculations may be executed using two cluster servers, each including four node workstations and one master workstation. Each node workstation is capable of performing molecular QM calculations via parallel processing based on symmetric multiprocessing (SMP), utilizing CPUs having 36 or more cores.

Using Gaussian 09 (G09), molecular structures optimized for neutral and charged states are calculated along with their corresponding potential energies (NONE and COCE), which are necessary for determining the reorganization energy. Subsequently, by altering only the charge of each of the two optimized structures, the potential energy of the neutral-state-optimized structure under the charged state (NOCE) and the potential energy of the charged-state-optimized structure under the neutral state (CONE) are calculated. The reorganization energy is then determined based on the following relationship.

$$R {E}_{c h a r g e} : λ = ( {E}_{N O C E} - {E}_{C O C E} ) + ( {E}_{C O N E} - {E}_{N O N E} )$$

Since Schrödinger provides a function for automatically performing the aforementioned calculation process, the JG module is capable of sequentially calculating the potential energies of each state and determining the rearrangement energy (RE) value by simply inputting the molecular structure (NO) of the ground state.

Hereinafter, the present invention will be described in further detail with reference to specific examples regarding the synthesis of compounds represented by Formula 1 and Formula 2 and the fabrication of an organic electronic device. However, the present invention is not limited to the following examples.

### [Synthesis Example 1] Compound of Formula 1

The compound (final product) represented by Formula 1 according to the present invention may be synthesized by reacting Sub1 with Sub2 as illustrated in Reaction Scheme 1. However, the present invention is not limited thereto.

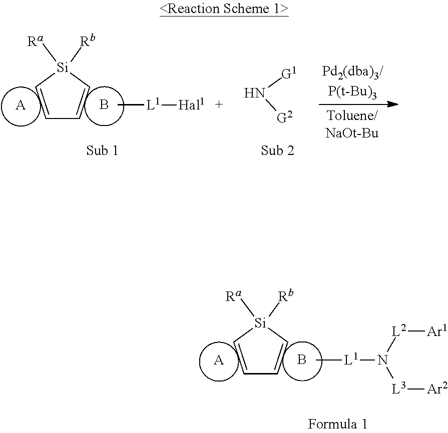

In the above Formula, Hal¹ is I, Br or Cl, G¹ is -L²-Ar¹, and G² is -L³-Ar².

### Example Compounds of Sub1

The compounds included in Sub1 may be compounds as listed below, but are not limited thereto. The FD-MS (Field Desorption-Mass Spectrometry) values of the compounds are shown in Table 1.

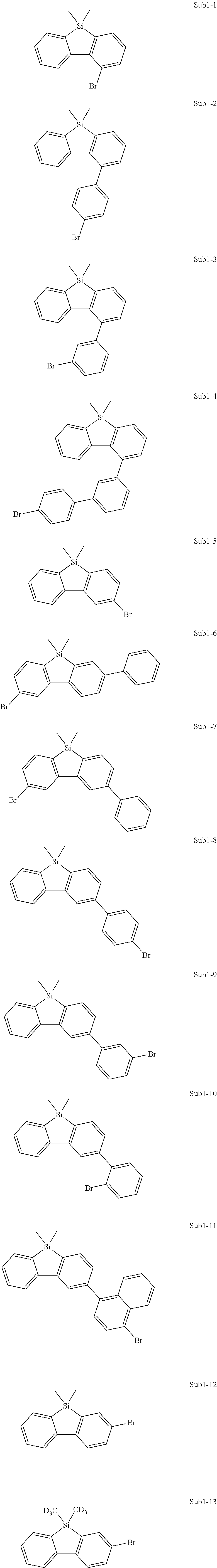

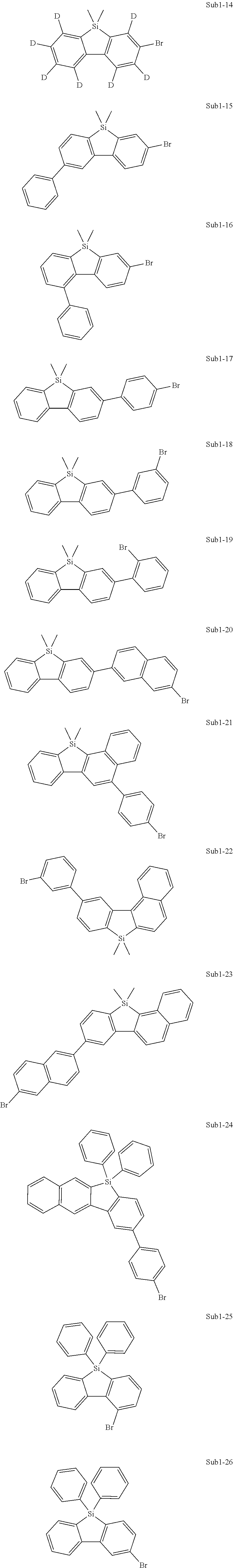

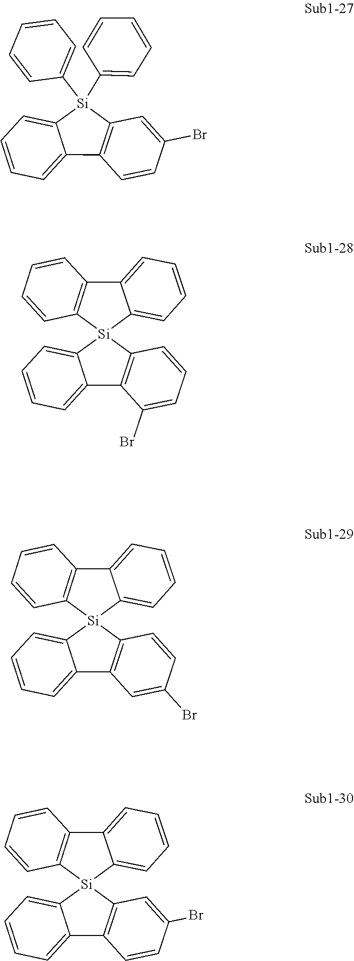 [SMILES: Brc1ccc2c(c1)[Si](c1ccccc1)(c1ccccc1)c1ccccc1-2 ; Brc1cccc2c1-c1ccccc1[Si]21c2ccccc2-c2ccccc21 ; Brc1ccc2c(c1)-c1ccccc1[Si]21c2ccccc2-c2ccccc21 ; Brc1ccc2c(c1)[Si]1(c3ccccc3-c3ccccc31)c1ccccc1-2]

TABLE 1

| Compound | FD-MS | Compound | FD-MS |
|---|---|---|---|
| Sub1-1 | m/z = 288(C₁₄H₁₃BrSi = 289.25) | Sub1-2 | m/z = 364.03(C₂₀H₁₇BrSi = 365.34) |
| Sub1-3 | m/z = 364.03(C₂₀H₁₇BrSi = 365.34) | Sub1-4 | m/z = 440.06(C₂₆H₂₁BrSi = 441.44) |
| Sub1-5 | m/z = 288(C₁₄H₁₃BrSi = 289.25) | Sub1-6 | m/z = 364.03(C₂₀H₁₇BrSi = 365.34) |
| Sub1-7 | m/z = 364.03(C₂₀H₁₇BrSi = 365.34) | Sub1-8 | m/z = 364.03(C₂₀H₁₇BrSi = 365.34) |
| Sub1-9 | m/z = 364.03(C₂₀H₁₇BrSi = 365.34) | Sub1-10 | m/z = 364.03(C₂₀H₁₇BrSi = 365.34) |
| Sub1-11 | m/z = 414.04(C₂₄H₁₉BrSi = 415.4) | Sub1-12 | m/z = 288(C₁₄H₁₃BrSi = 289.25) |
| Sub1-13 | m/z = 294.03(C₁₄H₇D₆BrSi = 295.28) | Sub1-14 | m/z = 295.04(C₁₄H₆D₇BrSi = 296.29) |
| Sub1-15 | m/z = 364.03(C₂₀H₁₇BrSi = 365.34) | Sub1-16 | m/z = 364.03(C₂₀H₁₇BrSi = 365.34) |
| Sub1-17 | m/z = 364.03(C₂₀H₁₇BrSi = 365.34) | Sub1-18 | m/z = 364.03(C₂₀H₁₇BrSi = 365.34) |
| Sub1-19 | m/z = 364.03(C₂₀H₁₇BrSi = 365.34) | Sub1-20 | m/z = 414.04(C₂₄H₁₉BrSi = 415.4) |
| Sub1-21 | m/z = 414.04(C₂₄H₁₉BrSi = 415.4) | Sub1-22 | m/z = 414.04(C₂₄H₁₉BrSi = 415.4) |
| Sub1-23 | m/z = 464.06(C₂₈H₂₁BrSi = 465.46) | Sub1-24 | m/z = 538.08(C₃₄H₂₃BrSi = 539.55) |
| Sub1-25 | m/z = 412.03(C₂₄H₁₇BrSi = 413.39) | Sub1-26 | m/z = 412.03(C₂₄H₁₇BrSi = 413.39) |
| Sub1-27 | m/z = 412.03(C₂₄H₁₇BrSi = 413.39) | Sub1-28 | m/z = 410.01(C₂₄H₁₅BrSi = 411.37) |
| Sub1-29 | m/z = 410.01(C₂₄H₁₅BrSi = 411.37) | Sub1-30 | m/z = 410.01(C₂₄H₁₅BrSi = 411.37) |

### Example Compounds of Sub2

Sub2 in Reaction Scheme 1 may be synthesized through the reaction pathway of Reaction Scheme 2 (as disclosed in the applicant's Korean Registered Patent No. 10-1251451, published on Apr. 5, 2013), but is not limited thereto.

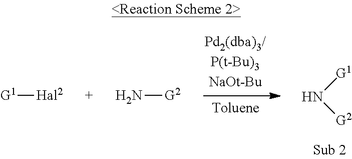

The compounds falling under Sub2 may be compounds as listed below, but are not limited thereto. The FD-MS (Field Desorption-Mass Spectrometry) values of the compounds are shown in Table 2.

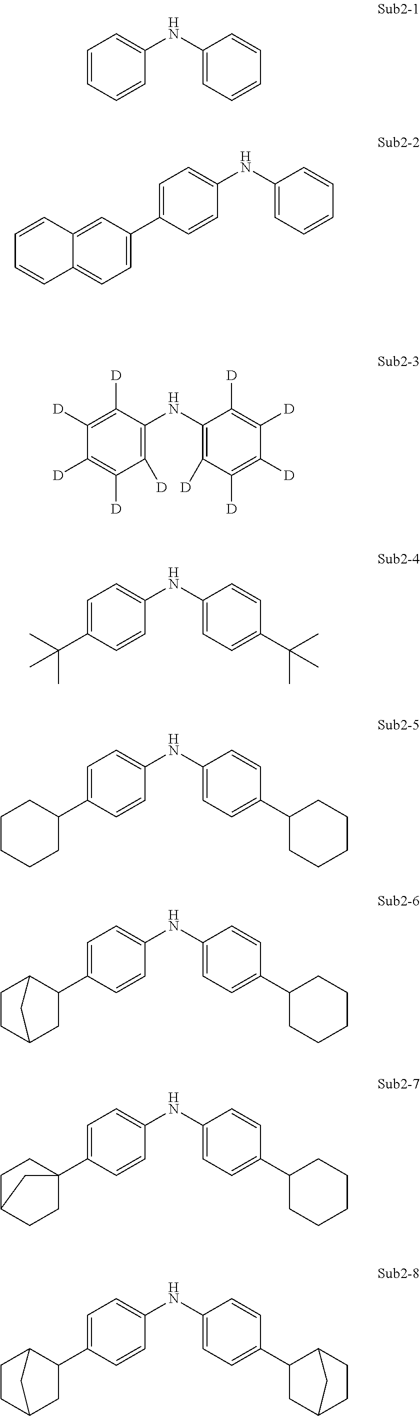

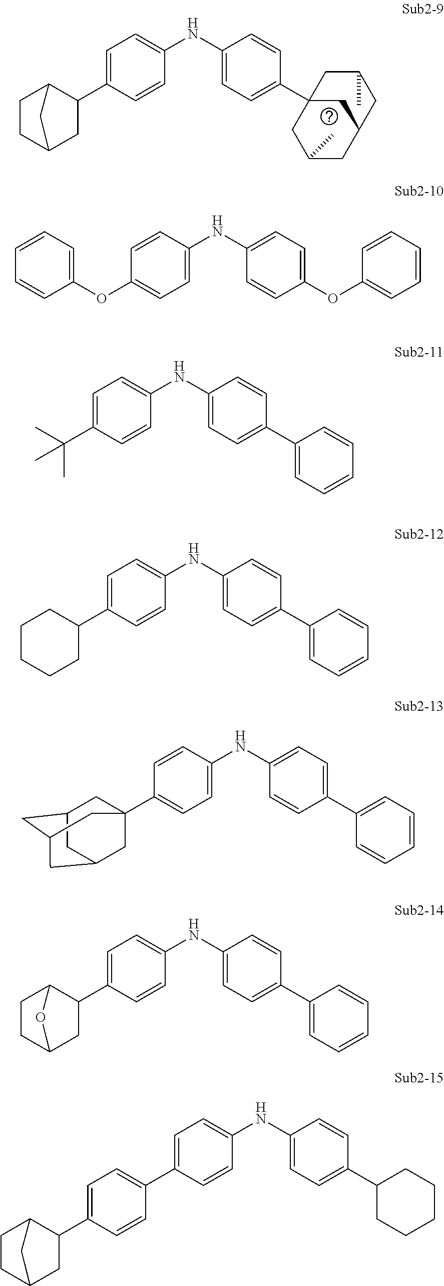

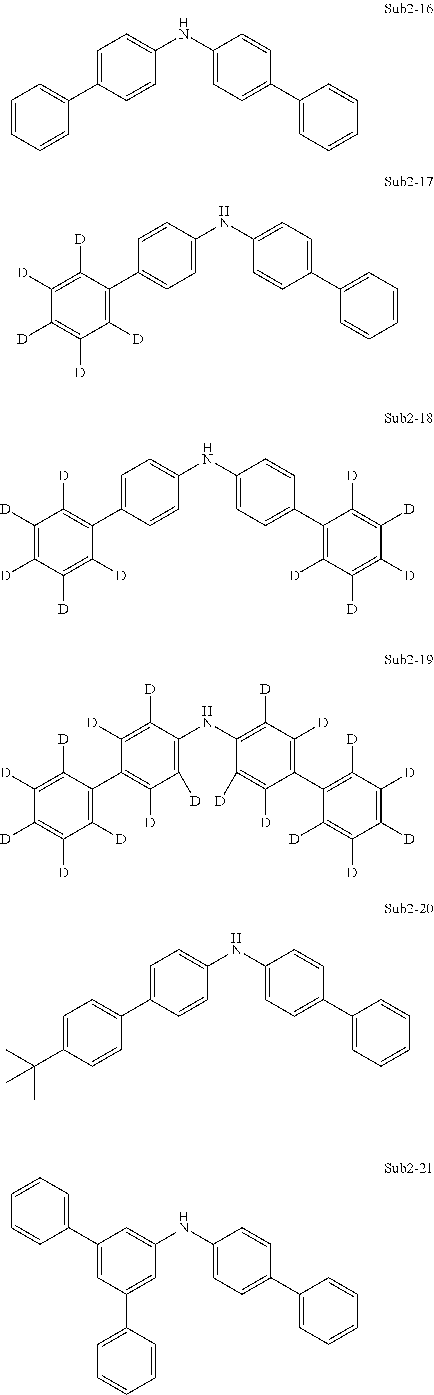 [SMILES: c1ccc(-c2ccc(Nc3ccc(-c4ccccc4)cc3)cc2)cc1 ; [2H]c1c([2H])c([2H])c(-c2ccc(Nc3ccc(-c4ccccc4)cc3)cc2)c([2H])c1[2H] ; [2H]c1c([2H])c([2H])c(-c2ccc(Nc3ccc(-c4c([2H])c([2H])c([2H])c([2H])c4[2H])cc3)cc2)c([2H])c1[2H] ; [2H]c1c([2H])c([2H])c(-c2c([2H])c([2H])c(Nc3c([2H])c([2H])c(-c4c([2H])c([2H])c([2H])c([2H])c4[2H])c([2H])c3[2H])c([2H])c2[2H])c([2H])c1[2H] ; CC(C)(C)c1ccc(-c2ccc(Nc3ccc(-c4ccccc4)cc3)cc2)cc1 ; c1ccc(-c2ccc(Nc3cc(-c4ccccc4)cc(-c4ccccc4)c3)cc2)cc1]

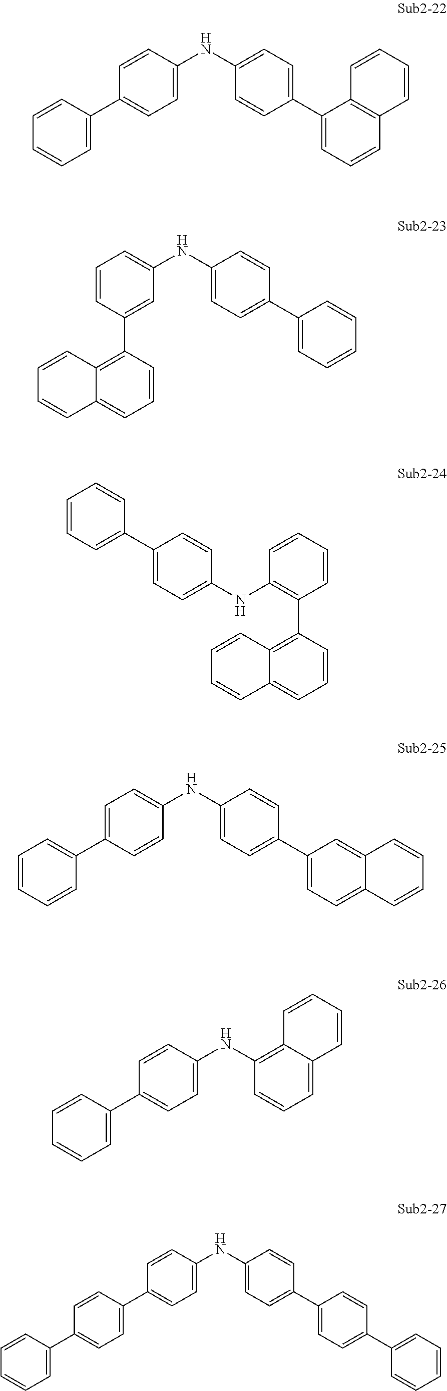 [SMILES: c1ccc(-c2ccc(Nc3ccc(-c4cccc5ccccc45)cc3)cc2)cc1 ; c1ccc(-c2ccc(Nc3cccc(-c4cccc5ccccc45)c3)cc2)cc1 ; c1ccc(-c2ccc(Nc3ccccc3-c3cccc4ccccc34)cc2)cc1 ; c1ccc(-c2ccc(Nc3ccc(-c4ccc5ccccc5c4)cc3)cc2)cc1 ; c1ccc(-c2ccc(Nc3cccc4ccccc34)cc2)cc1 ; c1ccc(-c2ccc(-c3ccc(Nc4ccc(-c5ccc(-c6ccccc6)cc5)cc4)cc3)cc2)cc1]

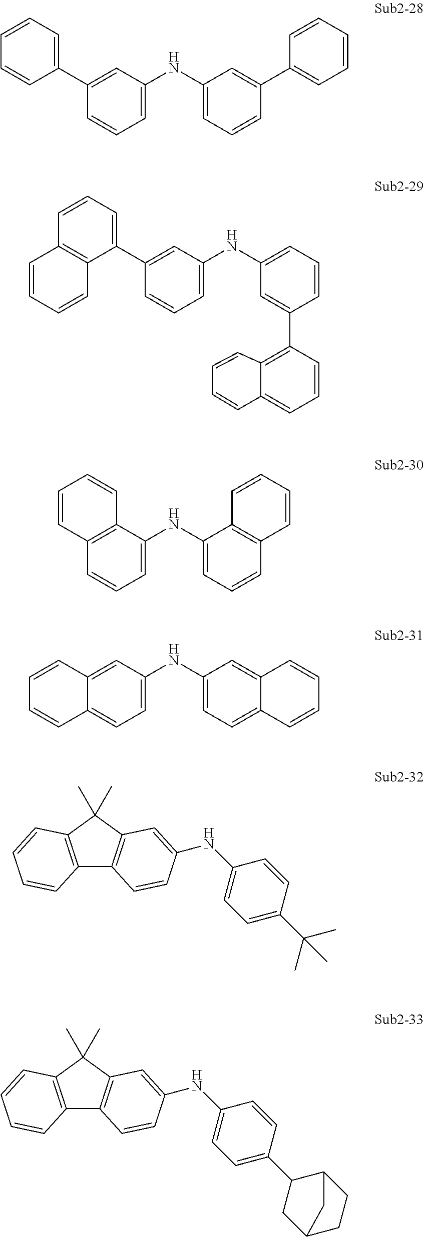 [SMILES: c1ccc(-c2cccc(Nc3cccc(-c4ccccc4)c3)c2)cc1 ; c1cc(Nc2cccc(-c3cccc4ccccc34)c2)cc(-c2cccc3ccccc23)c1 ; c1ccc2c(Nc3cccc4ccccc34)cccc2c1 ; c1ccc2cc(Nc3ccc4ccccc4c3)ccc2c1 ; CC(C)(C)c1ccc(Nc2ccc3c(c2)C(C)(C)c2ccccc2-3)cc1 ; CC1(C)c2ccccc2-c2ccc(Nc3ccc(C4CC5CCC4C5)cc3)cc21]

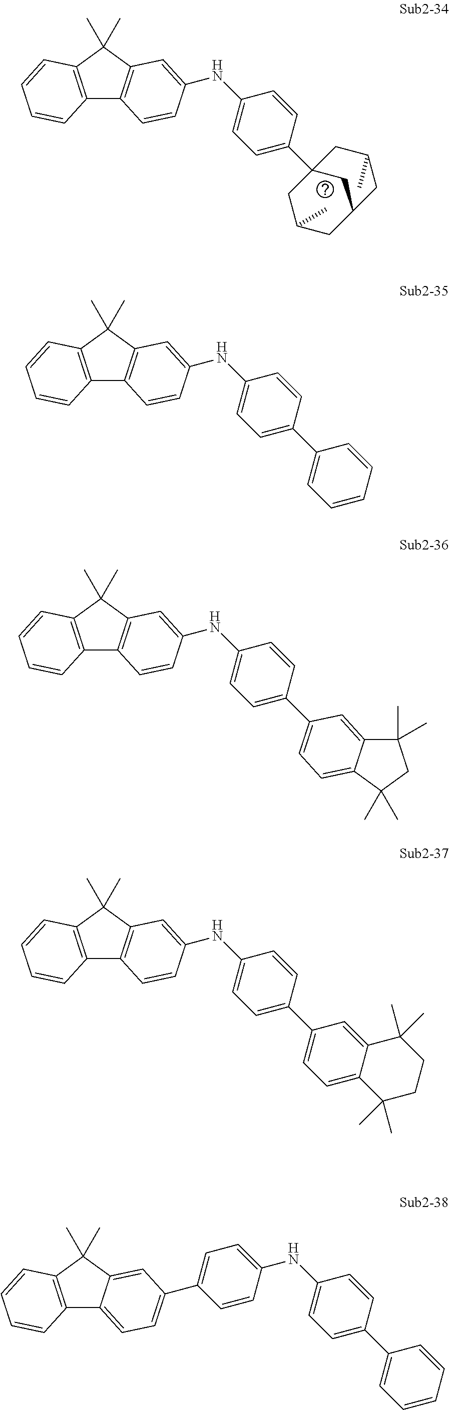 [SMILES: C[C@@H]1C[C@@H]2C[C@H](C)CC(c3ccc(Nc4ccc5c(c4)C(C)(C)c4ccccc4-5)cc3)(C1)C2 ; CC1(C)c2ccccc2-c2ccc(Nc3ccc(-c4ccccc4)cc3)cc21 ; CC1(C)CC(C)(C)c2cc(-c3ccc(Nc4ccc5c(c4)C(C)(C)c4ccccc4-5)cc3)ccc21 ; CC1(C)CCC(C)(C)c2cc(-c3ccc(Nc4ccc5c(c4)C(C)(C)c4ccccc4-5)cc3)ccc21 ; CC1(C)c2ccccc2-c2ccc(-c3ccc(Nc4ccc(-c5ccccc5)cc4)cc3)cc21]

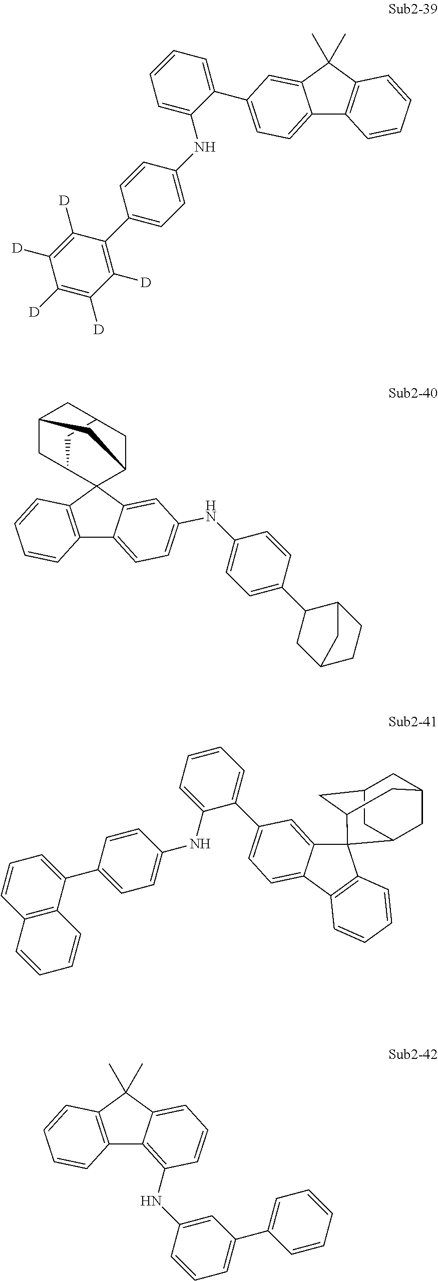 [SMILES: [2H]c1c([2H])c([2H])c(-c2ccc(Nc3ccccc3-c3ccc4c(c3)C(C)(C)c3ccccc3-4)cc2)c([2H])c1[2H] ; c1ccc2c(c1)-c1ccc(Nc3ccc(C4CC5CCC4C5)cc3)cc1C21[C@H]2CC3C[C@H](C2)C[C@H]1C3 ; c1ccc(-c2ccc3c(c2)C2(c4ccccc4-3)C3CC4CC(C3)CC2C4)c(Nc2ccc(-c3cccc4ccccc34)cc2)c1 ; CC1(C)c2ccccc2-c2c(Nc3cccc(-c4ccccc4)c3)cccc21]

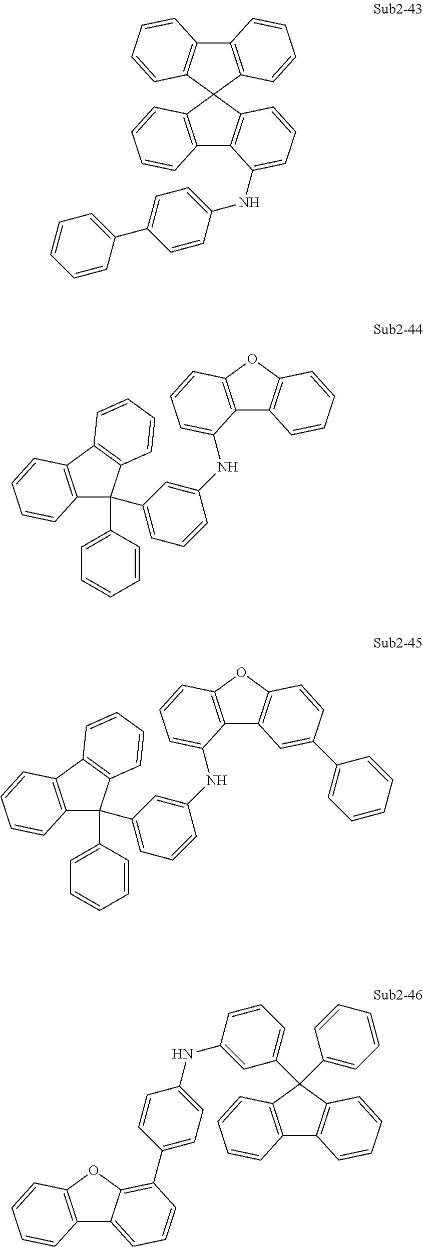 [SMILES: c1ccc(-c2ccc(Nc3cccc4c3-c3ccccc3C43c4ccccc4-c4ccccc43)cc2)cc1 ; c1ccc(C2(c3cccc(Nc4cccc5oc6ccccc6c45)c3)c3ccccc3-c3ccccc32)cc1 ; c1ccc(-c2ccc3oc4cccc(Nc5cccc(C6(c7ccccc7)c7ccccc7-c7ccccc76)c5)c4c3c2)cc1 ; c1ccc(C2(c3cccc(Nc4ccc(-c5cccc6c5oc5ccccc56)cc4)c3)c3ccccc3-c3ccccc32)cc1]

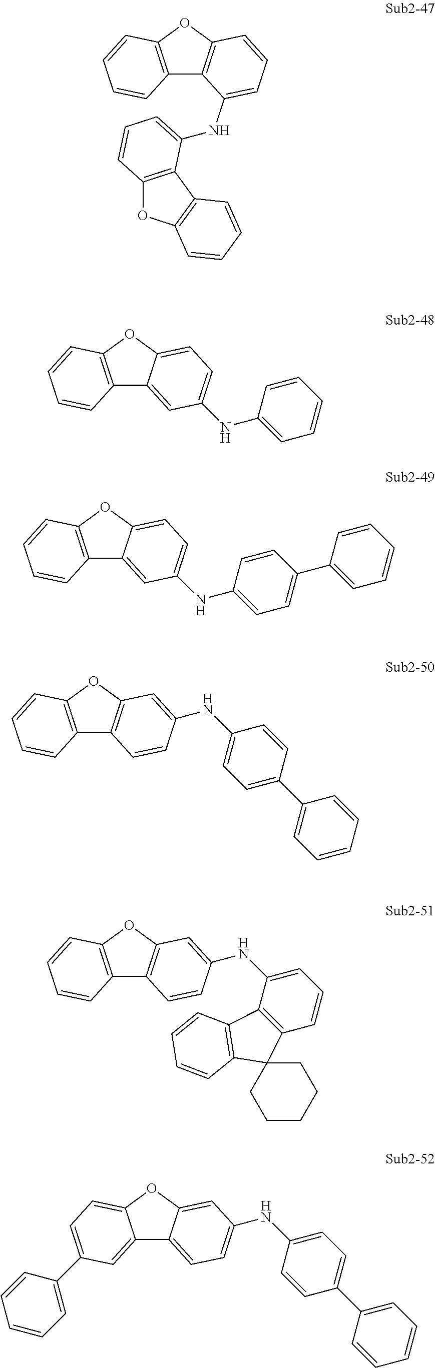 [SMILES: c1ccc2c(c1)oc1cccc(Nc3cccc4oc5ccccc5c34)c12 ; c1ccc(Nc2ccc3oc4ccccc4c3c2)cc1 ; c1ccc(-c2ccc(Nc3ccc4oc5ccccc5c4c3)cc2)cc1 ; c1ccc(-c2ccc(Nc3ccc4c(c3)oc3ccccc34)cc2)cc1 ; c1ccc2c(c1)-c1c(Nc3ccc4c(c3)oc3ccccc34)cccc1C21CCCCC1 ; c1ccc(-c2ccc(Nc3ccc4c(c3)oc3ccc(-c5ccccc5)cc34)cc2)cc1]

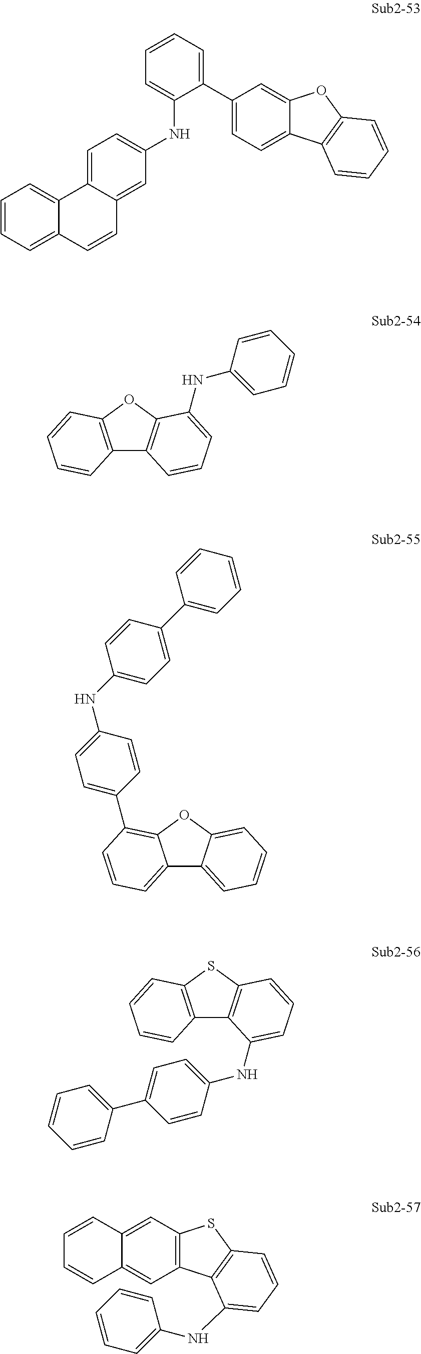 [SMILES: c1ccc(-c2ccc3c(c2)oc2ccccc23)c(Nc2ccc3c(ccc4ccccc43)c2)c1 ; c1ccc(Nc2cccc3c2oc2ccccc23)cc1 ; c1ccc(-c2ccc(Nc3ccc(-c4cccc5c4oc4ccccc45)cc3)cc2)cc1 ; c1ccc(-c2ccc(Nc3cccc4sc5ccccc5c34)cc2)cc1 ; c1ccc(Nc2cccc3sc4cc5ccccc5cc4c23)cc1]

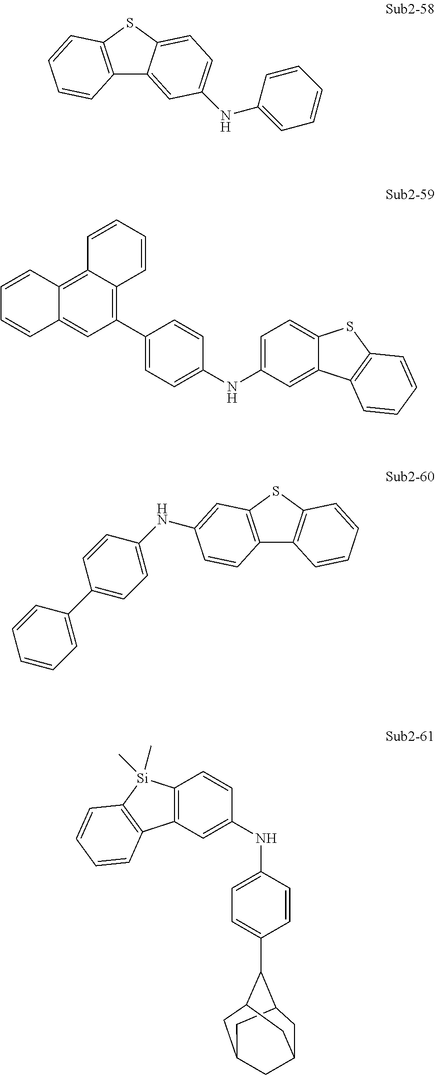 [SMILES: c1ccc(Nc2ccc3sc4ccccc4c3c2)cc1 ; c1ccc2c(c1)cc(-c1ccc(Nc3ccc4sc5ccccc5c4c3)cc1)c1ccccc12 ; c1ccc(-c2ccc(Nc3ccc4c(c3)sc3ccccc34)cc2)cc1 ; C[Si]1(C)c2ccccc2-c2cc(Nc3ccc(C4C5CC6CC(C5)CC4C6)cc3)ccc21]

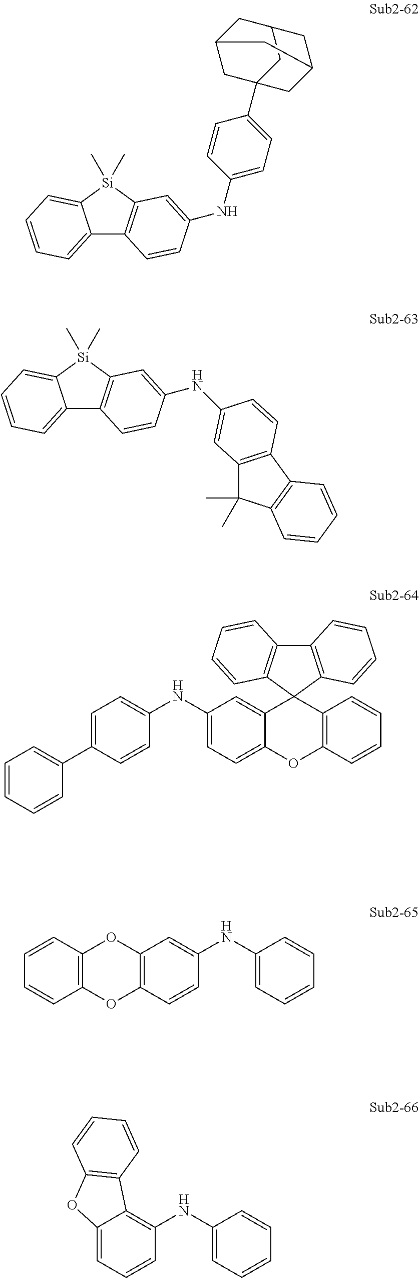 [SMILES: C[Si]1(C)c2ccccc2-c2ccc(Nc3ccc(C45CC6CC(CC(C6)C4)C5)cc3)cc21 ; CC1(C)c2ccccc2-c2ccc(Nc3ccc4c(c3)[Si](C)(C)c3ccccc3-4)cc21 ; c1ccc(-c2ccc(Nc3ccc4c(c3)C3(c5ccccc5O4)c4ccccc4-c4ccccc43)cc2)cc1 ; c1ccc(Nc2ccc3c(c2)Oc2ccccc2O3)cc1 ; c1ccc(Nc2cccc3oc4ccccc4c23)cc1]

TABLE 2

| Compound | FD-MS | Compound | FD-MS |
|---|---|---|---|
| Sub2-1 | m/z = 169.09(C₁₂H₁₁N = 169.23) | Sub2-2 | m/z = 295.14(C₂₂H₁₇N = 295.38) |
| Sub2-3 | m/z = 179.15(C₁₂HD₁₀N = 179.29) | Sub2-4 | m/z = 281.21(C₂₀H₂₇N = 281.44) |
| Sub2-5 | m/z = 333.25(C₂₄H₃₁N = 333.52) | Sub2-6 | m/z = 345.25(C₂₅H₃₁N = 345.53) |
| Sub2-7 | m/z = 345.25(C₂₅H₃₁N = 345.53) | Sub2-8 | m/z = 357.25(C₂₆H₃₁N = 357.54) |
| Sub2-9 | m/z = 397.28(C₂₉H₃₅N = 397.61) | Sub2-10 | m/z = 353.14(C₂₄H₁₉NO₂ = 353.42) |
| Sub2-11 | m/z = 301.18(C₂₂H₂₃N = 301.43) | Sub2-12 | m/z = 327.2(C₂₄H₂₅N = 327.47) |
| Sub2-13 | m/z = 379.23(C₂₈H₂₉N = 379.55) | Sub2-14 | m/z = 341.18(C₂₄H₂₃NO = 341.45) |
| Sub2-15 | m/z = 421.28(C₃₁H₃₅N = 421.63) | Sub2-16 | m/z = 321.15(C₂₄H₁₉N = 321.42) |
| Sub2-17 | m/z = 326.18(C₂₄H₁₄D₅N = 326.45) | Sub2-18 | m/z = 331.21(C₂₄H₉D₁₀N = 331.48) |
| Sub2-19 | m/z = 339.26(C₂₄HD₁₈N = 339.53) | Sub2-20 | m/z = 377.21(C₂₈H₂₇N = 377.53) |
| Sub2-21 | m/z = 397.18(C₃₀H₂₃N = 397.52) | Sub2-22 | m/z = 371.17(C₂₈H₂₁N = 371.48) |
| Sub2-23 | m/z = 371.17(C₂₈H₂₁N = 371.48) | Sub2-24 | m/z = 371.17(C₂₈H₂₁N = 371.48) |
| Sub2-25 | m/z = 371.17(C₂₈H₂₁N = 371.48) | Sub2-26 | m/z = 295.14(C₂₂H₁₇N = 295.38) |
| Sub2-27 | m/z = 473.21(C₃₆H₂₇N = 473.62) | Sub2-28 | m/z = 321.15(C₂₄H₁₉N = 321.42) |
| Sub2-29 | m/z = 421.18(C₃₂H₂₃N = 421.54) | Sub2-30 | m/z = 269.12(C₂₀H₁₅N = 269.35) |
| Sub2-31 | m/z = 269.12(C₂₀H₁₅N = 269.35) | Sub2-32 | m/z = 341.21(C₂₅H₂₇N = 341.5) |
| Sub2-33 | m/z = 379.23(C₂₈H₂₉N = 379.55) | Sub2-34 | m/z = 419.26(C₃₁H₃₃N = 419.61) |
| Sub2-35 | m/z = 361.18(C₂₇H₂₃N = 361.49) | Sub2-36 | m/z = 457.28(C₃₄H₃₅N = 457.66) |
| Sub2-37 | m/z = 471.29(C₃₅H₃₇N = 471.69) | Sub2-38 | m/z = 437.21(C₃₃H₂₇N = 437.59) |
| Sub2-39 | m/z = 442.25(C₃₃H₂₂D₅N = 442.62) | Sub2-40 | m/z = 471.29(C₃₅H₃₇N = 471.69) |
| Sub2-41 | m/z = 579.29(C₄₄H₃₇N = 579.79) | Sub2-42 | m/z = 361.18(C₂₇H₂₃N = 361.49) |
| Sub2-43 | m/z = 483.2(C₃₇H₂₅N = 483.61) | Sub2-44 | m/z = 499.19(C₃₇H₂₅NO = 499.61) |
| Sub2-45 | m/z = 575.22(C₄₃H₂₉NO = 575.71) | Sub2-46 | m/z = 575.22(C₄₃H₂₉NO = 575.71) |
| Sub2-47 | m/z = 349.11(C₂₄H₁₅NO₂ = 349.39) | Sub2-48 | m/z = 259.1(C₁₈H₁₃NO = 259.31) |
| Sub2-49 | m/z = 335.13(C₂₄H₁₇NO = 335.41) | Sub2-50 | m/z = 335.13(C₂₄H₁₇NO = 335.41) |
| Sub2-51 | m/z = 415.19(C₃₀H₂₅NO = 415.54) | Sub2-52 | m/z = 411.16(C₃₀H₂₁NO = 411.5) |
| Sub2-53 | m/z = 435.16(C₃₂H₂₁NO = 435.53) | Sub2-54 | m/z = 259.1(C₁₈H₁₃NO = 259.31) |
| Sub2-55 | m/z = 411.16(C₃₀H₂₁NO = 411.5) | Sub2-56 | m/z = 351.11(C₂₄H₁₇NS = 351.47) |
| Sub2-57 | m/z = 325.09(C₂₂H₁₅NS = 325.43) | Sub2-58 | m/z = 275.08(C₁₈H₁₃NS = 275.37) |
| Sub2-59 | m/z = 451.14(C₃₂H₂₁NS = 451.59) | Sub2-60 | m/z = 351.11(C₂₄H₁₇NS = 351.47) |
| Sub2-61 | m/z = 435.24(C₃₀H₃₃NSi = 435.69) | Sub2-62 | m/z = 435.24(C₃₀H₃₃NSi = 435.69) |
| Sub2-63 | m/z = 417.19(C₂₉H₂₇NSi = 417.63) | Sub2-64 | m/z = 499.19(C₃₇H₂₅NO = 499.61) |
| Sub2-65 | m/z = 275.09(C₁₈H₁₃NO₂ = 275.31) | Sub2-66 | m/z = 259.10(C₁₈H₁₃NO = 259.31) |

### Synthesis Example of the Final Compound

### 1. Synthesis Example of P1-1

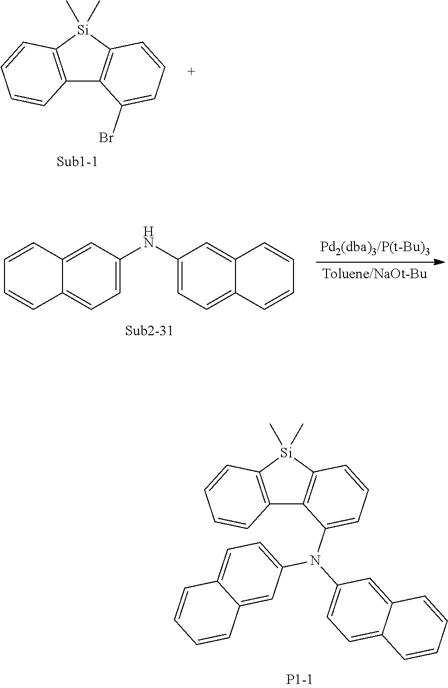 [SMILES: C[Si]1(C)c2ccccc2-c2c(Br)cccc21 ; c1ccc2cc(Nc3ccc4ccccc4c3)ccc2c1 ; C[Si]1(C)c2ccccc2-c2c(N(c3ccc4ccccc4c3)c3ccc4ccccc4c3)cccc21]

Sub1-1 (5.0 g, 17.3 mmol) was dissolved in toluene (86 mL), followed by the addition of Sub2-31 (4.7 g, 17.3 mmol), Pd₂(dba)₃ (0.47 g, 0.52 mmol), P(t-Bu)₃ (0.21 g, 1.04 mmol) and NaOt-Bu (3.3 g, 34.6 mmol). The reaction was carried out at 80° C. When the reaction was completed, the reaction products were extracted with CH₂Cl₂ and water, and the organic layer was dried over MgSO₄ and concentrated. Then, the concentrate was purified by silica gel column chromatography and recrystallized to afford 6.2 g of the product (yield: 75%).

### 2. Synthesis Example of P1-8

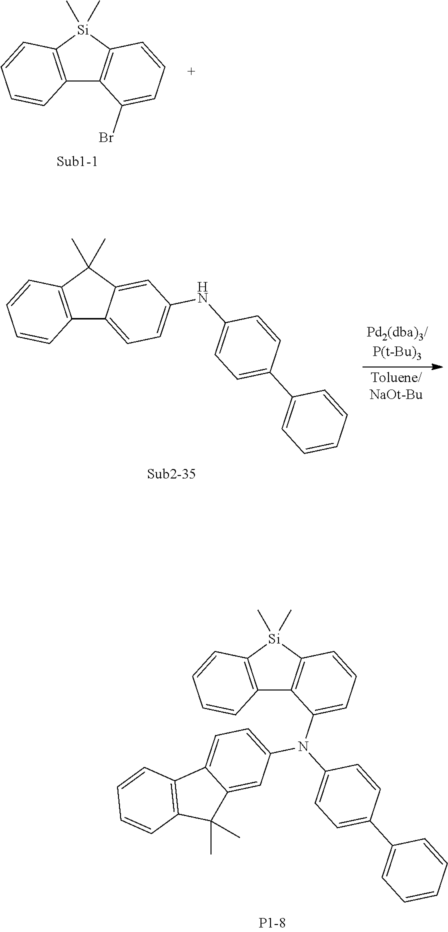 [SMILES: C[Si]1(C)c2ccccc2-c2c(Br)cccc21 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3cccc4c3-c3ccccc3[Si]4(C)C)cc21]

Sub1-1 (5.0 g, 17.3 mmol) was dissolved in toluene (86 mL), followed by the addition of Sub2-35 (6.2 g, 17.3 mmol), Pd₂(dba)₃ (0.47 g, 0.52 mmol), P(t-Bu)₃ (0.21 g, 1.04 mmol) and NaOt-Bu (3.3 g, 34.6 mmol). The reaction was carried out using the same method as described in the synthesis example of P1-1, affording 7.6 g of the product (yield: 77%).

### 3. Synthesis Example of P1-20

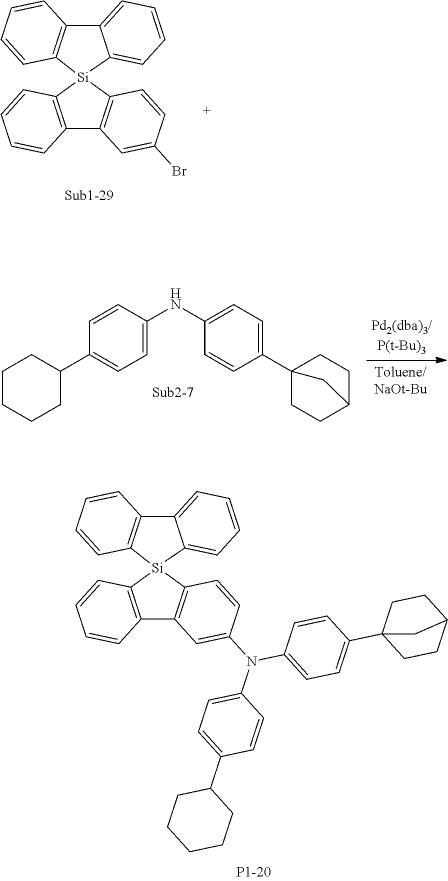 [SMILES: Brc1ccc2c(c1)-c1ccccc1[Si]21c2ccccc2-c2ccccc21 ; c1cc(C2CCCCC2)ccc1Nc1ccc(C23CCC(CC2)C3)cc1 ; c1ccc2c(c1)-c1ccccc1[Si]21c2ccccc2-c2cc(N(c3ccc(C4CCCCC4)cc3)c3ccc(C45CCC(CC4)C5)cc3)ccc21]

Sub1-29 (5.0 g, 12.2 mmol) was dissolved in toluene (61 mL), followed by the addition of Sub2-7 (4.2 g, 12.2 mmol), Pd₂(dba)₃ (0.33 g, 0.36 mmol), P(t-Bu)₃ (0.15 g, 0.73 mmol) and NaOt-Bu (2.3 g, 24.3 mmol). The reaction was carried out using the same method as described in the synthesis example of P1-1, affording 6.1 g of the product (yield: 74%).

### 4. Synthesis Example of P1-21

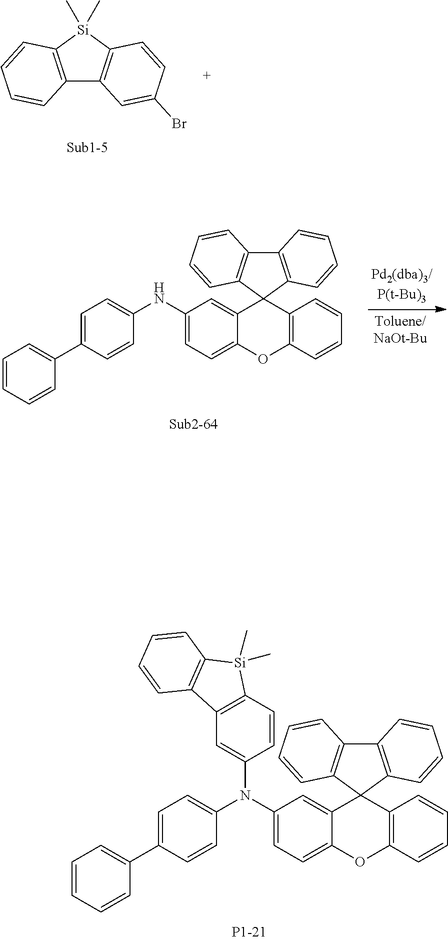 [SMILES: C[Si]1(C)c2ccccc2-c2cc(Br)ccc21 ; c1ccc(-c2ccc(Nc3ccc4c(c3)C3(c5ccccc5O4)c4ccccc4-c4ccccc43)cc2)cc1 ; C[Si]1(C)c2ccccc2-c2cc(N(c3ccc(-c4ccccc4)cc3)c3ccc4c(c3)C3(c5ccccc5O4)c4ccccc4-c4ccccc43)ccc21]

Sub1-5 (5.0 g, 17.3 mmol) was dissolved in toluene (86 mL), followed by the addition of Sub2-64 (8.6 g, 17.3 mmol), Pd₂(dba)₃ (0.47 g, 0.52 mmol), P(t-Bu)₃ (0.21 g, 1.04 mmol) and NaOt-Bu (3.3 g, 34.6 mmol). The reaction was carried out using the same method as described in the synthesis example of P1-1, affording 8.9 g of the product (yield: 73%).

### 5. Synthesis Example of P1-41

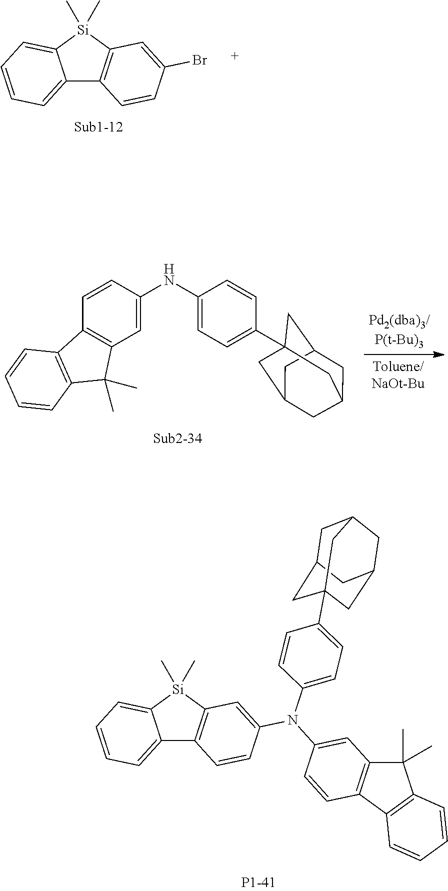 [SMILES: C[Si]1(C)c2ccccc2-c2ccc(Br)cc21 ; CC1(C)c2ccccc2-c2ccc(Nc3ccc(C45CC6CC(CC(C6)C4)C5)cc3)cc21 ; CC1(C)c2ccccc2-c2ccc(N(c3ccc(C45CC6CC(CC(C6)C4)C5)cc3)c3ccc4c(c3)[Si](C)(C)c3ccccc3-4)cc21]

Sub1-12 (5.0 g, 17.3 mmol) was dissolved in toluene (86 mL), followed by the addition of Sub2-34 (7.3 g, 17.3 mmol), Pd₂(dba)₃ (0.47 g, 0.52 mmol), P(t-Bu)₃ (0.21 g, 1.04 mmol) and NaOt-Bu (3.3 g, 34.6 mmol). The reaction was carried out using the same method as described in the synthesis example of P1-1, affording 8.1 g of the product (yield: 75%).

### 6. Synthesis Example of P1-45

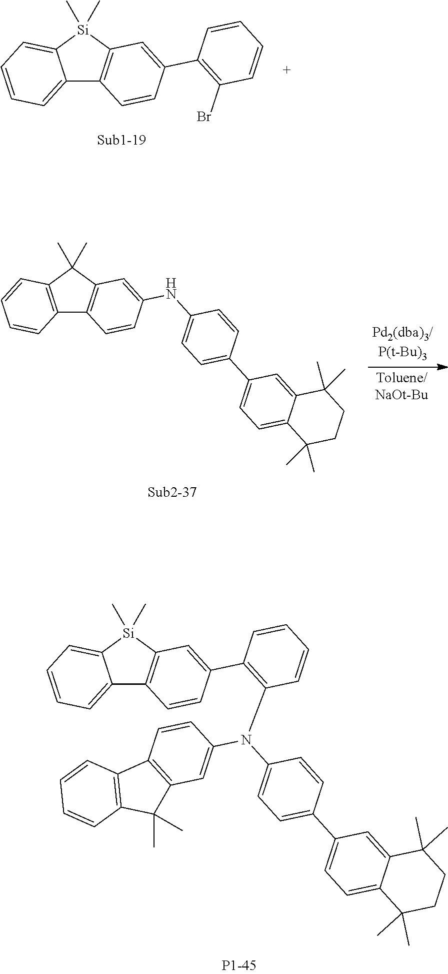 [SMILES: C[Si]1(C)c2ccccc2-c2ccc(-c3ccccc3Br)cc21 ; CC1(C)CCC(C)(C)c2cc(-c3ccc(Nc4ccc5c(c4)C(C)(C)c4ccccc4-5)cc3)ccc21 ; CC1(C)CCC(C)(C)c2cc(-c3ccc(N(c4ccc5c(c4)C(C)(C)c4ccccc4-5)c4ccccc4-c4ccc5c(c4)[Si](C)(C)c4ccccc4-5)cc3)ccc21]

Sub1-19 (5.0 g, 13.7 mmol) was dissolved in toluene (68 mL) in a round-bottom flask, followed by the addition of Sub2-37 (6.5 g, 13.7 mmol), Pd₂(dba)₃ (0.38 g, 0.41 mmol), P(t-Bu)₃ (0.17 g, 0.82 mmol) and NaOt-Bu (2.6 g, 27.4 mmol). The reaction was carried out using the same method as described in the synthesis example of P1-1, affording 5.6 g of the product (yield: 54%).

Meanwhile, the FD-MS values of the compounds P1-1 to P1-64 of the present invention, prepared according to the above synthesis examples, are shown in Table 3.

TABLE 3

| Compound | FD-MS | Compound | FD-MS |
|---|---|---|---|
| P1-1 | m/z = 477.19(C₃₄H₂₇NSi = 477.68) | P1-2 | m/z = 477.19(C₃₄H₂₇NSi = 477.68) |
| P1-3 | m/z = 529.22(C₃₈H₃₁NSi = 529.76) | P1-4 | m/z = 553.32(C₃₉H₄₃NSi = 553.87) |
| P1-5 | m/z = 653.25(C₄₈H₃₅NSi = 653.9) | P1-6 | m/z = 651.24(C₄₈H₃₃NSi = 651.88) |
| P1-7 | m/z = 543.2(C₃₈H₂₉NOSi = 543.74) | P1-8 | m/z = 569.25(C₄₁H₃₅NSi = 569.82) |
| P1-9 | m/z = 463.25(C₃₂H₁₇D₁₀NSi = 463.72) | P1-10 | m/z = 559.2(C₃₈H₂₉NO₂Si = 559.74) |
| P1-11 | m/z = 509.25(C₃₆H₃₅NSi = 509.77) | P1-12 | m/z = 663.33(C₄₈H₄₅NSi = 663.98) |
| P1-13 | m/z = 529.22(C₃₈H₃₁NSi = 529.76) | P1-14 | m/z = 579.24(C₄₂H₃₃NSi = 579.82) |
| P1-15 | m/z = 541.32(C₃₈H₄₃NSi = 541.85) | P1-16 | m/z = 585.29(C₄₂H₃₉NSi = 585.87) |
| P1-17 | m/z = 665.35(C₄₈H₄₇NSi = 666) | P1-18 | m/z = 613.32(C₄₄H₄₃NSi = 613.92) |
| P1-19 | m/z = 529.22(C₃₈H₃₁NSi = 529.76) | P1-20 | m/z = 675.33(C₄₉H₄₅NSi = 675.99) |
| P1-21 | m/z = 707.26(C₅₁H₃₇NOSi = 707.95) | P1-22 | m/z = 659.21(C₄₆H₃₃NSSi = 659.92) |
| P1-23 | m/z = 681.29(C₅₀H₃₉NSi = 681.95) | P1-24 | m/z = 645.29(C₄₇H₃₉NSi = 645.92) |
| P1-25 | m/z = 605.25(C₄₄H₃₅NSi = 605.86) | P1-26 | m/z = 605.25(C₄₄H₃₅NSi = 605.86) |
| P1-27 | m/z = 605.25(C₄₄H₃₅NSi = 605.86) | P1-28 | m/z = 629.25(C₄₆H₃₅NSi = 629.88) |
| P1-29 | m/z = 769.36(C₅₄H₅₁NSi₂ = 770.18) | P1-30 | m/z = 799.36(C₅₉H₄₉NSi = 800.13) |
| P1-31 | m/z = 675.3(C₄₈H₄₁NOSi = 675.95) | P1-32 | m/z = 741.38(C₅₄H₅₁NSi = 742.09) |
| P1-33 | m/z = 377.16(C₂₆H₂₃NSi = 377.56) | P1-34 | m/z = 529.22(C₃₈H₃₁NSi = 529.76) |
| P1-35 | m/z = 529.22(C₃₈H₃₁NSi = 529.76) | P1-36 | m/z = 579.24(C₄₂H₃₃NSi = 579.82) |
| P1-37 | m/z = 653.25(C₄₈H₃₅NSi = 653.9) | P1-38 | m/z = 651.24(C₄₈H₃₃NSi = 651.88) |
| P1-39 | m/z = 477.19(C₃₄H₂₇NSi = 477.68) | P1-40 | m/z = 535.27(C₃₈H₃₇NSi = 535.81) |
| P1-41 | m/z = 627.33(C₄₅H₄₅NSi = 627.95) | P1-42 | m/z = 543.2(C₃₈H₂₉NOSi = 543.74) |
| P1-43 | m/z = 605.35(C₄₃H₄₇NSi = 605.94) | P1-44 | m/z = 625.26(C₄₃H₃₉NSi₂ = 625.96) |
| P1-45 | m/z = 755.39(C₅₅H₅₃NSi = 756.12) | P1-46 | m/z = 605.25(C₄₄H₃₅NSi = 605.86) |
| P1-47 | m/z = 635.21(C₄₄H₃₃NSSi = 635.9) | P1-48 | m/z = 593.22(C₄₂H₃₁NOSi = 593.8) |
| P1-49 | m/z = 713.3(C₅₁H₃₁D₆NOSi = 713.98) | P1-50 | m/z = 489.29(C₃₄H₃₉NSi = 489.78) |
| P1-51 | m/z = 539.29(C₃₈H₂₁D₁₀NSi = 539.82) | P1-52 | m/z = 652.33(C₄₇H₃₂D₇NSi = 652.96) |
| P1-53 | m/z = 643.31(C₄₄H₄₅NSi₂ = 644.02) | P1-54 | m/z = 681.29(C₅₀H₃₉NSi = 681.95) |
| P1-55 | m/z = 655.27(C₄₈H₃₇NSi = 655.92) | P1-56 | m/z = 705.38(C₅₁H₅₁NSi = 706.06) |
| P1-57 | m/z = 617.35(C₄₄H₄₇NSi = 617.95) | P1-58 | m/z = 587.3(C₄₂H₄₁NSi = 587.88) |
| P1-59 | m/z = 623.26(C₄₄H₃₇NOSi = 623.87) | P1-60 | m/z = 679.36(C₄₉H₄₉NSi = 680.02) |
| P1-61 | m/z = 787.36(C₅₈H₄₉NSi = 788.12) | P1-62 | m/z = 650.32(C₄₇H₃₄D₅NSi = 650.95) |
| P1-63 | m/z = 610.29(C₄₄H₃₀D₅NSi = 610.89) | P1-64 | m/z = 643.23(C₄₆H₃₃NOSi = 643.86) |

### [Synthesis Example 2] (Compound of Formula 2)

The compound (final product) represented by Formula 2 according to the present invention may be synthesized by reacting Sub3 with Sub2 as shown in Reaction Scheme 3, but is not limited thereto.

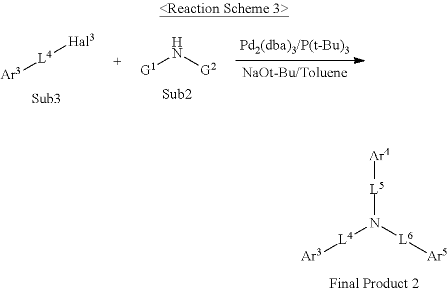

In the above Formula, Hal³ is I, Br or Cl, G¹ is -L⁵-Ar⁴, and G² is -L⁶-Ar⁵.

### Example Compounds of Sub3

The compounds included in Sub3 may be compounds as listed below, but are not limited thereto. The FD-MS values of the compounds are shown in Table 4.

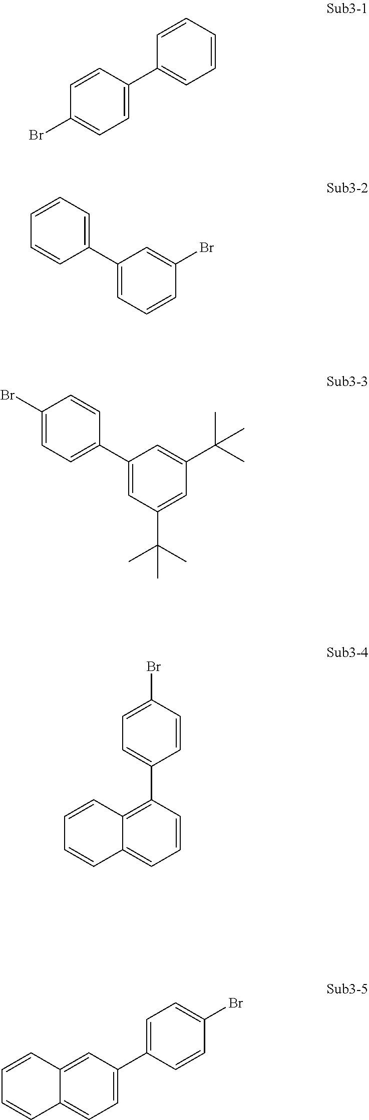 [SMILES: Brc1ccc(-c2ccccc2)cc1 ; Brc1cccc(-c2ccccc2)c1 ; CC(C)(C)c1cc(-c2ccc(Br)cc2)cc(C(C)(C)C)c1 ; Brc1ccc(-c2cccc3ccccc23)cc1 ; Brc1ccc(-c2ccc3ccccc3c2)cc1]

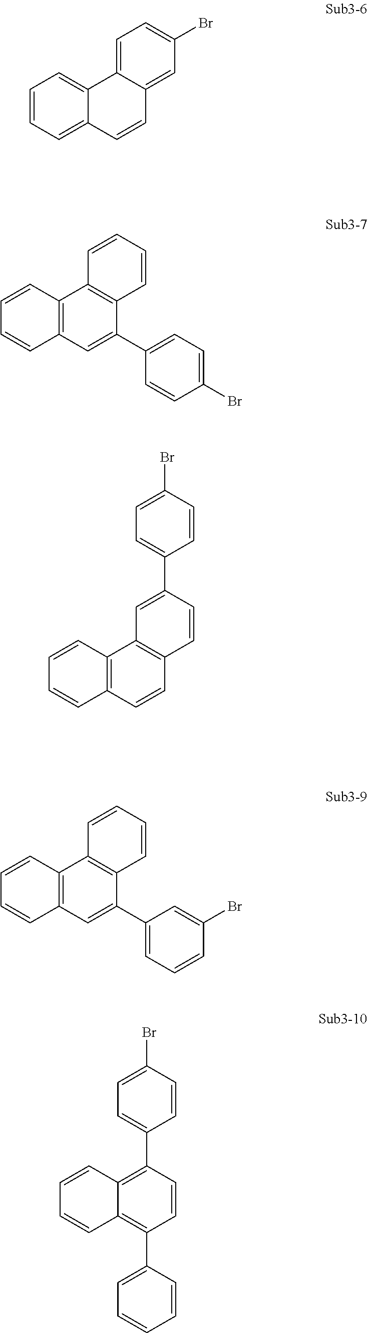 [SMILES: Brc1ccc2c(ccc3ccccc32)c1 ; Brc1ccc(-c2cc3ccccc3c3ccccc23)cc1 ; Brc1ccc(-c2ccc3ccc4ccccc4c3c2)cc1 ; Brc1cccc(-c2cc3ccccc3c3ccccc23)c1 ; Brc1ccc(-c2ccc(-c3ccccc3)c3ccccc23)cc1]

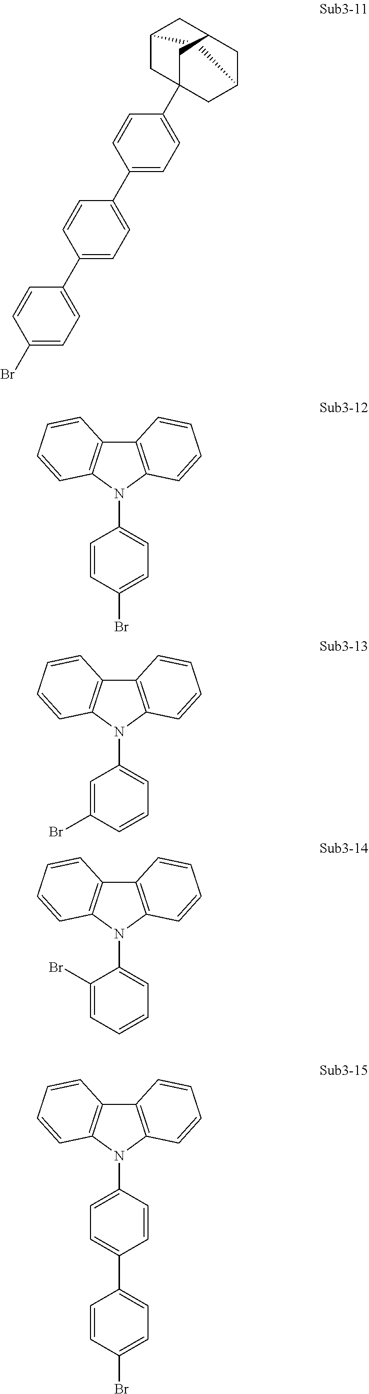

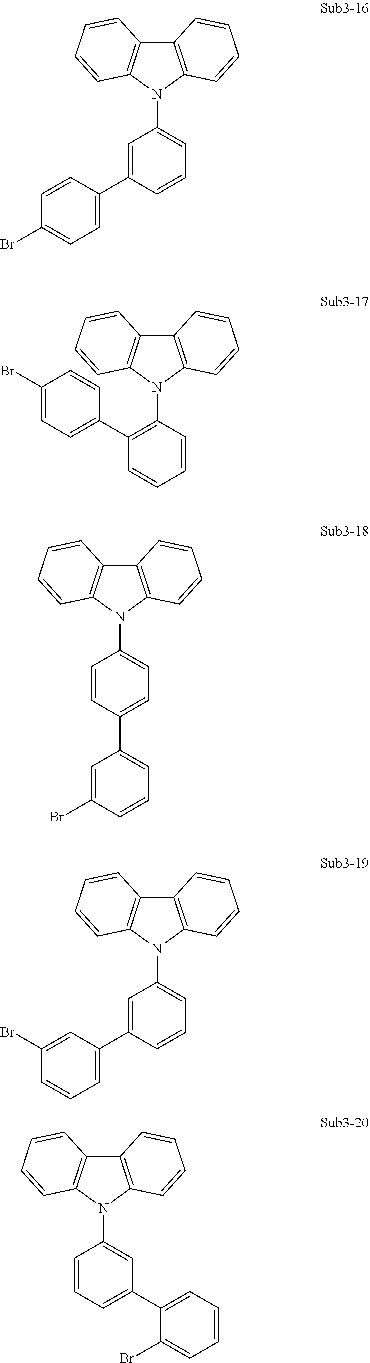

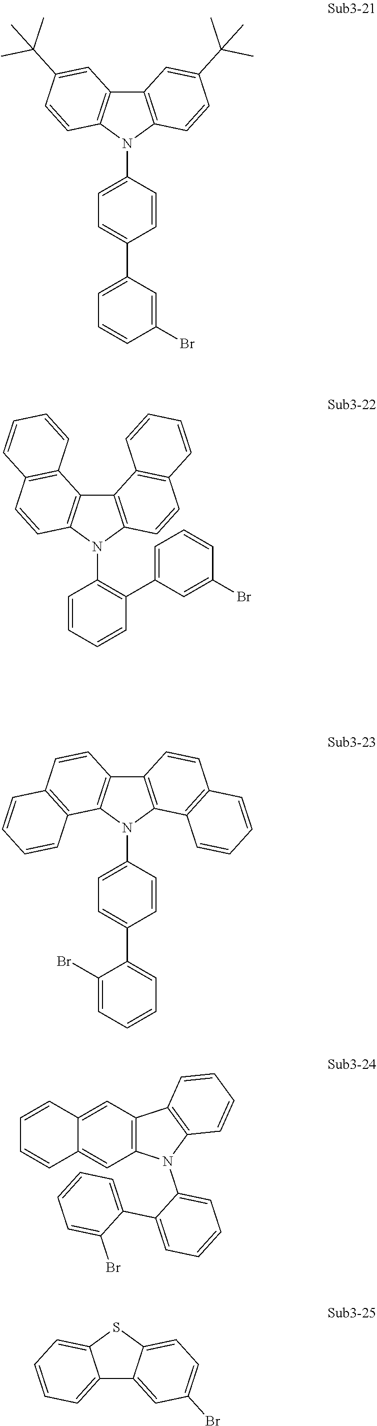 [SMILES: CC(C)(C)c1ccc2c(c1)c1cc(C(C)(C)C)ccc1n2-c1ccc(-c2cccc(Br)c2)cc1 ; Brc1cccc(-c2ccccc2-n2c3ccc4ccccc4c3c3c4ccccc4ccc32)c1 ; Brc1ccccc1-c1ccc(-n2c3c4ccccc4ccc3c3ccc4ccccc4c32)cc1 ; Brc1ccccc1-c1ccccc1-n1c2ccccc2c2cc3ccccc3cc21 ; Brc1ccc2sc3ccccc3c2c1]

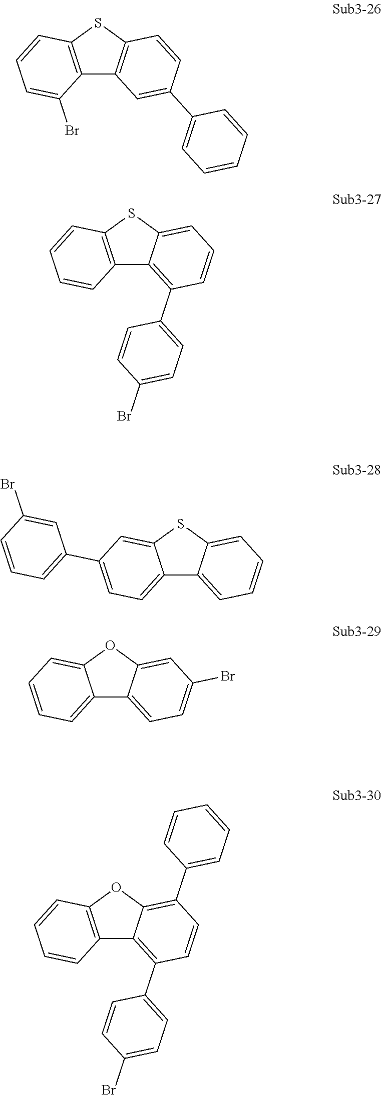 [SMILES: Brc1cccc2sc3ccc(-c4ccccc4)cc3c12 ; Brc1ccc(-c2cccc3sc4ccccc4c23)cc1 ; Brc1cccc(-c2ccc3c(c2)sc2ccccc23)c1 ; Brc1ccc2c(c1)oc1ccccc12 ; Brc1ccc(-c2ccc(-c3ccccc3)c3oc4ccccc4c23)cc1]

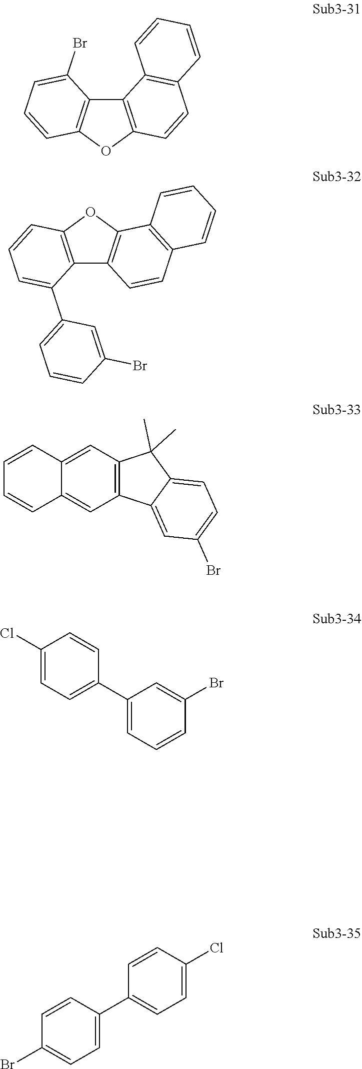 [SMILES: Brc1cccc2oc3ccc4ccccc4c3c12 ; Brc1cccc(-c2cccc3oc4c5ccccc5ccc4c23)c1 ; CC1(C)c2ccc(Br)cc2-c2cc3ccccc3cc21 ; Clc1ccc(-c2cccc(Br)c2)cc1 ; Clc1ccc(-c2ccc(Br)cc2)cc1]

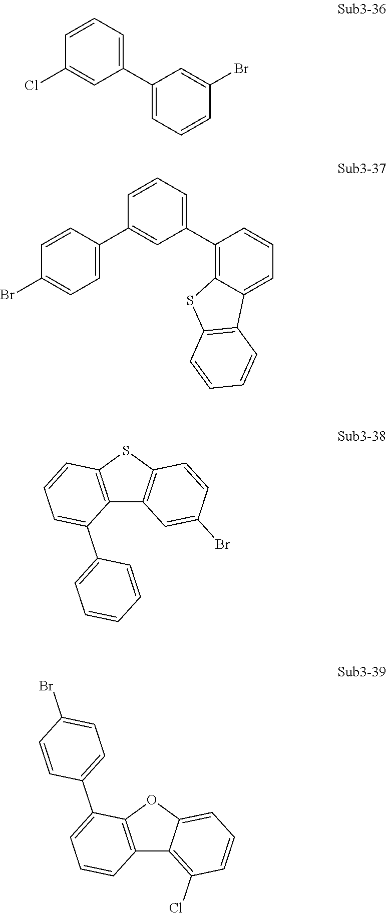 [SMILES: Clc1cccc(-c2cccc(Br)c2)c1 ; Brc1ccc(-c2cccc(-c3cccc4c3sc3ccccc34)c2)cc1 ; Brc1ccc2sc3cccc(-c4ccccc4)c3c2c1 ; Clc1cccc2oc3c(-c4ccc(Br)cc4)cccc3c12]

TABLE 4

| Compound | FD-MS | Compound | FD-MS |
|---|---|---|---|
| Sub3-1 | m/z = 231.99(C₁₂H₉Br = 233.11) | Sub3-2 | m/z = 231.99(C₁₂H₉Br = 233.11) |
| Sub3-3 | m/z = 344.11(C₂₀H₂₅Br = 345.32) | Sub3-4 | m/z = 282(C₁₆H₁₁Br = 283.17) |
| Sub3-5 | m/z = 282(C₁₆H₁₁Br = 283.17) | Sub3-6 | m/z = 255.99(C₁₄H₉Br = 257.13) |
| Sub3-7 | m/z = 332.02(C₂₀H₁₃Br = 333.23) | Sub3-8 | m/z = 332.02(C₂₀H₁₃Br = 333.23) |
| Sub3-9 | m/z = 332.02(C₂₀H₁₃Br = 333.23) | Sub3-10 | m/z = 358.04(C₂₂H₁₅Br = 359.27) |
| Sub3-11 | m/z = 442.13(C₂₈H₂₇Br = 443.43) | Sub3-12 | m/z = 321.02(C₁₈H₁₂BrN = 322.21) |
| Sub3-13 | m/z = 321.02(C₁₈H₁₂BrN = 322.21) | Sub3-14 | m/z = 321.02(C₁₈H₁₂BrN = 322.21) |
| Sub3-15 | m/z = 397.05(C₂₄H₁₆BrN = 398.3) | Sub3-16 | m/z = 397.05(C₂₄H₁₆BrN = 398.3) |
| Sub3-17 | m/z = 397.05(C₂₄H₁₆BrN = 398.3) | Sub3-18 | m/z = 397.05(C₂₄H₁₆BrN = 398.3) |
| Sub3-19 | m/z = 397.05(C₂₄H₁₆BrN = 398.3) | Sub3-20 | m/z = 397.05(C₂₄H₁₆BrN = 398.3) |
| Sub3-21 | m/z = 509.17(C₃₂H₃₂BrN = 510.52) | Sub3-22 | m/z = 497.08(C₃₂H₂₀BrN = 498.42) |
| Sub3-23 | m/z = 497.08(C₃₂H₂₀BrN = 498.42) | Sub3-24 | m/z = 447.06(C₂₈H₁₈BrN = 448.36) |
| Sub3-25 | m/z = 261.95(C₁₂H₇BrS = 263.15) | Sub3-26 | m/z = 337.98(C₁₈H₁₁BrS = 339.25) |
| Sub3-27 | m/z = 337.98(C₁₈H₁₁BrS = 339.25) | Sub3-28 | m/z = 337.98(C₁₈H₁₁BrS = 339.25) |
| Sub3-29 | m/z = 245.97(C₁₂H₇BrO = 247.09) | Sub3-30 | m/z = 398.03(C₂₄H₁₅BrO = 399.29) |
| Sub3-31 | m/z = 295.98(C₁₆H₉BrO = 297.15) | Sub3-32 | m/z = 372.01(C₂₂H₁₃BrO = 373.25) |
| Sub3-33 | m/z = 322.04(C₁₉H₁₅Br = 323.23) | Sub3-34 | m/z = 265.95(C₁₂H₈BrCl = 267.55) |
| Sub3-35 | m/z = 265.95(C₁₂H₈BrCl = 267.55) | Sub3-36 | m/z = 265.95(C₁₂H₈BrCl = 267.55) |
| Sub3-37 | m/z = 414.01(C₂₄H₁₅BrS = 415.35) | Sub3-38 | m/z = 337.98(C₁₈H₁₁BrS = 339.25) |
| Sub3-39 | m/z = 355.96(C₁₈H₁₀BrClO = 357.63) | | |

### Synthesis Example of the Final Compound

### 1. Synthesis Example of P2-1

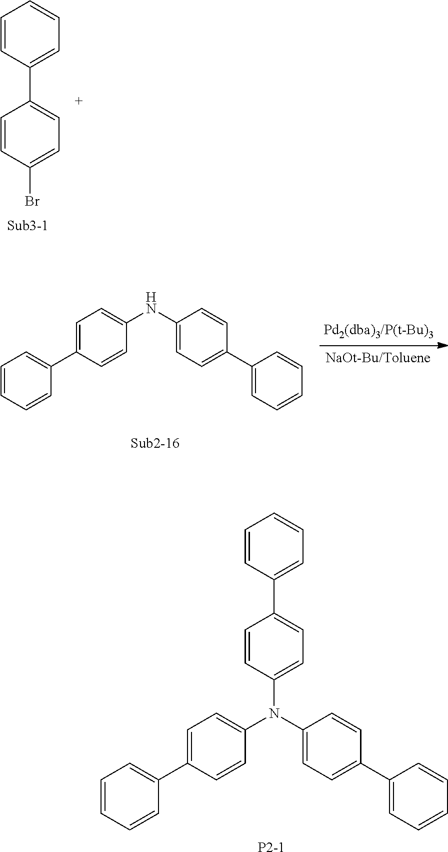 [SMILES: Brc1ccc(-c2ccccc2)cc1 ; c1ccc(-c2ccc(Nc3ccc(-c4ccccc4)cc3)cc2)cc1 ; c1ccc(-c2ccc(N(c3ccc(-c4ccccc4)cc3)c3ccc(-c4ccccc4)cc3)cc2)cc1 ; "P2-1"]

Sub3-1 (5.0 g, 21.6 mmol) was dissolved in toluene (108 mL), followed by the addition of Sub2-16 (5.0 g, 21.6 mmol), Pd₂(dba)₃ (0.59 g, 0.65 mmol), P(t-Bu)₃ (0.26 g, 1.29 mmol) and NaOt-Bu (4.1 g, 43.1 mmol). The reaction was carried out at 80° C. When the reaction was completed, the reaction products were extracted with CH₂Cl₂ and water, and the organic layer was dried over MgSO₄ and concentrated. Then, the concentrate was purified by silica gel column chromatography and recrystallized to afford 8.1 g of the product (yield: 79%).

### 2. Synthesis Example of P2-6

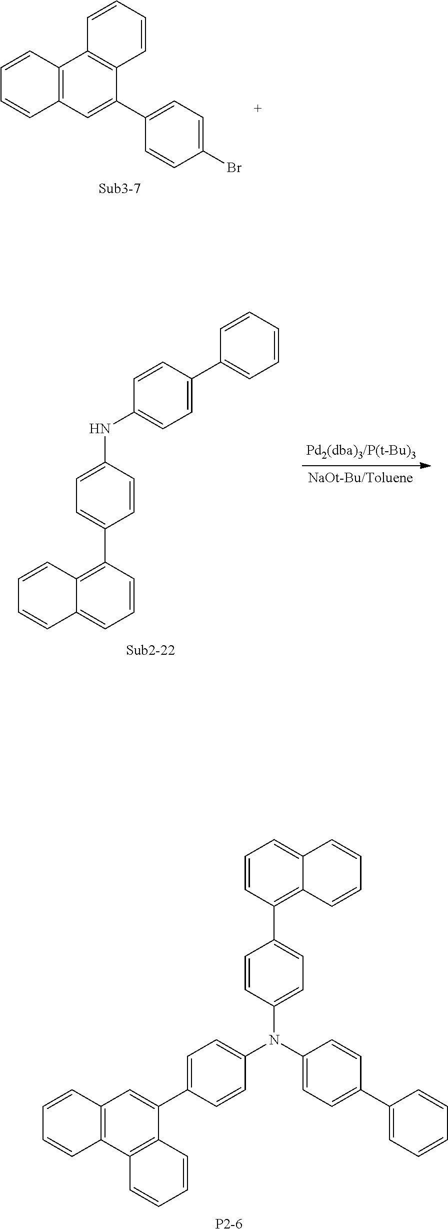 [SMILES: Brc1ccc(-c2cc3ccccc3c3ccccc23)cc1 ; "Sub3-7" ; c1ccc(-c2ccc(Nc3ccc(-c4cccc5ccccc45)cc3)cc2)cc1 ; c1ccc(-c2ccc(N(c3ccc(-c4cccc5ccccc45)cc3)c3ccc(-c4cc5ccccc5c5ccccc45)cc3)cc2)cc1 ; "P2-6"]

Sub3-7 (5.0 g, 15.0 mmol) was dissolved in toluene (75 mL), followed by the addition of Sub2-22 (5.6 g, 15.0 mmol), Pd₂(dba)₃ (0.41 g, 0.45 mmol), P(t-Bu)₃ (0.18 g, 0.90 mmol) and NaOt-Bu (2.9 g, 30.0 mmol). The reaction was carried out using the same method as described in the synthesis example of P2-1, affording 7.2 g of the product (yield: 76%).

### 3. Synthesis Example of P2-17

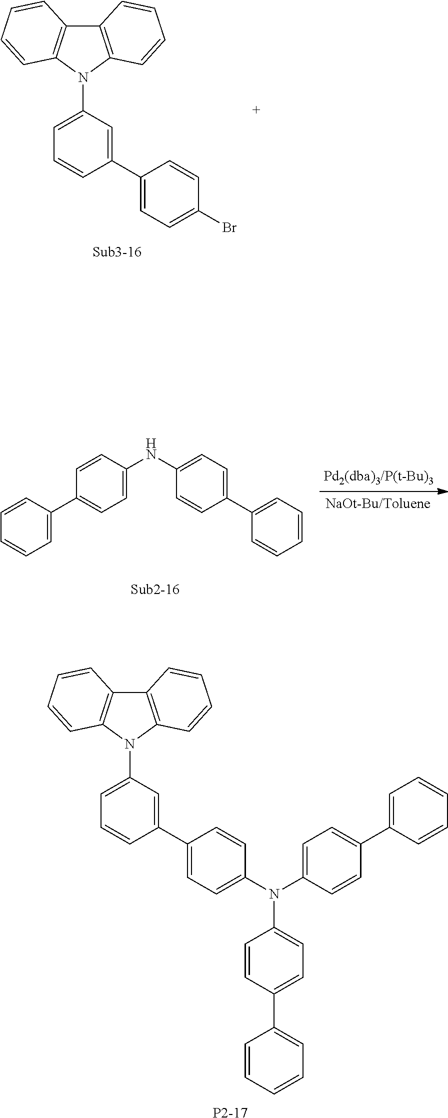

Sub3-16 (5.0 g, 12.6 mmol) was dissolved in toluene (635 mL), followed by the addition of Sub2-16 (4.0 g, 12.6 mmol), Pd₂(dba)₃ (0.34 g, 0.38 mmol), P(t-Bu)₃ (0.15 g, 0.75 mmol) and NaOt-Bu (2.4 g, 25.1 mmol). The reaction was carried out using the same method as described in the synthesis example of P2-1, affording 6.3 g of the product (yield: 78%).

### 4. Synthesis Example of P2-29

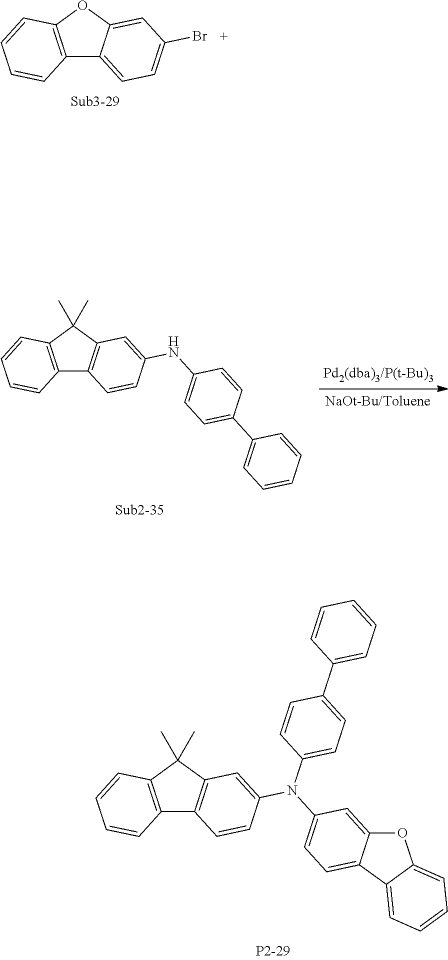 [SMILES: Brc1ccc2c(c1)oc1ccccc12 ; CC1(C)c2ccccc2-c2ccc(Nc3ccc(-c4ccccc4)cc3)cc21 ; CC1(C)c2ccccc2-c2ccc(N(c3ccc(-c4ccccc4)cc3)c3ccc4c(c3)oc3ccccc34)cc21]

Sub3-29 (5.0 g, 20.2 mmol) was dissolved in toluene (100 mL), followed by the addition of Sub2-35 (7.3 g, 20.2 mmol), Pd₂(dba)₃ (0.56 g, 0.61 mmol), P(t-Bu)₃ (0.25 g, 1.21 mmol) and NaOt-Bu (3.9 g, 40.5 mmol). The reaction was carried out using the same method as described in the synthesis example of P2-1, affording 7.7 g of the product (yield: 72%).

### 5. Synthesis Example of P2-40

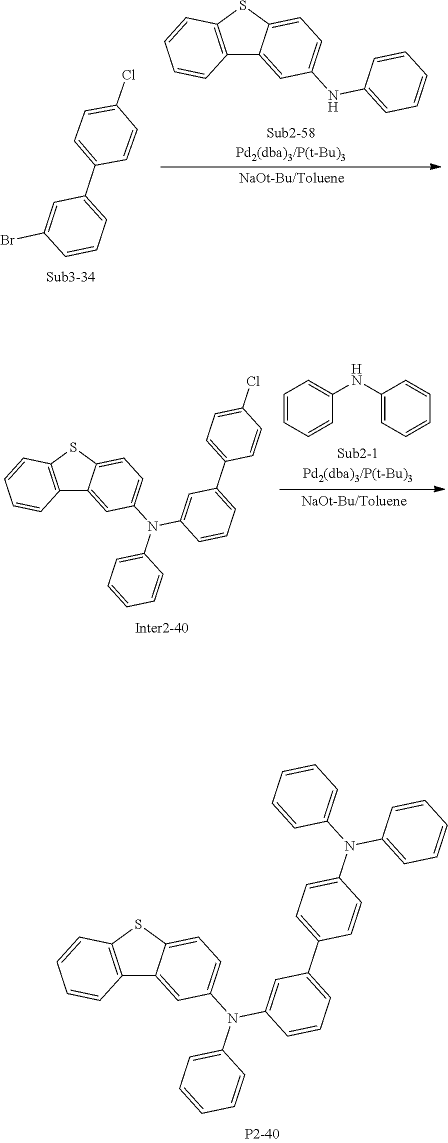

### (1) Synthesis of Inter2-40

Sub3-34 (5.0 g, 13.6 mmol) was dissolved in toluene (68 mL), followed by the addition of Sub2-58 (3.7 g, 13.6 mmol), Pd₂(dba)₃ (0.37 g, 0.41 mmol), P(t-Bu)₃ (0.17 g, 0.82 mmol) and NaOt-Bu (2.6 g, 27.2 mmol). The reaction was carried out at 60° C. When the reaction was completed, the reaction products were extracted with CH₂Cl₂ and water, and the organic layer was dried over MgSO₄ and concentrated. Then, the concentrate was purified by silica gel column chromatography and recrystallized to afford 4.9 g of the product (yield: 78%).

### (2) Synthesis of P2-40

Inter2-40 (4.9 g, 10.6 mmol) was dissolved in toluene (53 mL), followed by the addition of Sub2-1 (1.8 g, 10.6 mmol), Pd₂(dba)₃ (0.29 g, 0.32 mmol), P(t-Bu)₃ (0.13 g, 0.64 mmol) and NaOt-Bu (2.0 g, 21.2 mmol). The reaction was carried out using the same method as described in the synthesis example of P2-1, affording 4.8 g of the product (yield: 76%).

### 6. Synthesis Example of P2-43

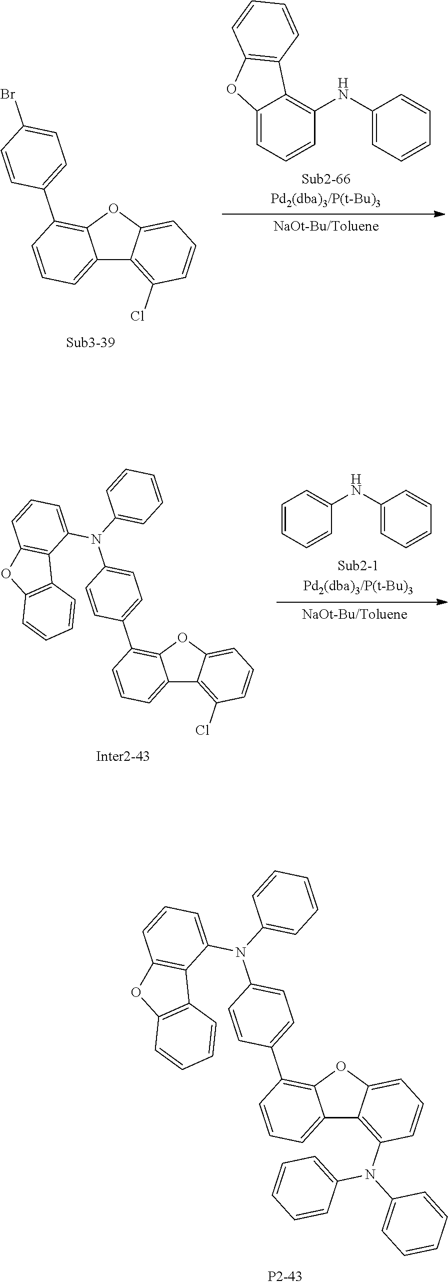 [SMILES: Clc1cccc2oc3c(-c4ccc(Br)cc4)cccc3c12 ; c1ccc(Nc2cccc3oc4ccccc4c23)cc1 ; Clc1cccc2oc3c(-c4ccc(N(c5ccccc5)c5cccc6oc7ccccc7c56)cc4)cccc3c12 ; c1ccc(Nc2ccccc2)cc1 ; c1ccc(N(c2ccc(-c3cccc4c3oc3cccc(N(c5ccccc5)c5ccccc5)c34)cc2)c2cccc3oc4ccccc4c23)cc1]

### (1) Synthesis of Inter2-43

Sub3-39 (5.0 g, 14.0 mmol) was dissolved in toluene (70 mL), followed by the addition of Sub2-66 (3.6 g, 14.0 mmol), Pd₂(dba)₃ (0.38 g, 0.42 mmol), P(t-Bu)₃ (0.17 g, 0.84 mmol) and NaOt-Bu (2.7 g, 28.0 mmol). The reaction was carried out using the same method as described in the synthesis example of Inter2-40, affording 5.9 g of the product (yield: 79%).

### (2) Synthesis of P2-43

Inter2-43 (5.9 g, 11.0 mmol) was dissolved in toluene (55 mL), followed by the addition of Sub2-1 (1.9 g, 11.0 mmol), Pd₂(dba)₃ (0.13 g, 0.66 mmol), P(t-Bu)₃ (0.13 g, 0.66 mmol) and NaOt-Bu (2.1 g, 22.1 mmol). The reaction was carried out using the same method as described in the synthesis example of P2-40, affording 5.2 g of the product (yield: 71%).

### 7. Synthesis Example of P2-44

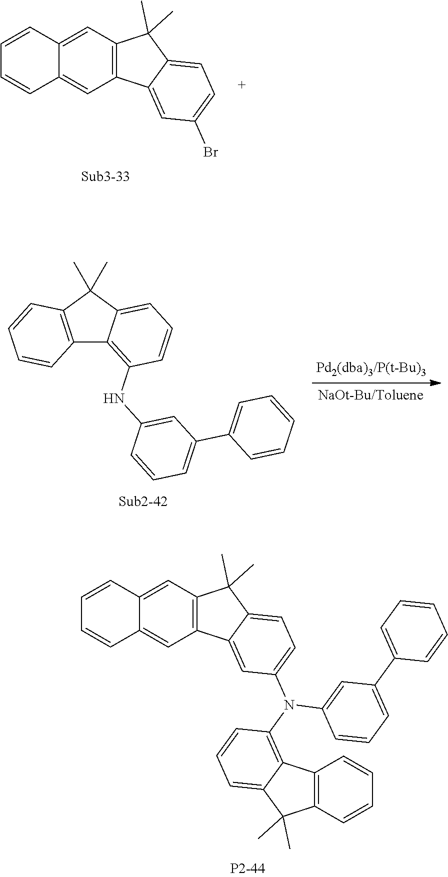 [SMILES: CC1(C)c2ccc(Br)cc2-c2cc3ccccc3cc21 ; CC1(C)c2ccccc2-c2c(Nc3cccc(-c4ccccc4)c3)cccc21 ; CC1(C)c2ccc(N(c3cccc(-c4ccccc4)c3)c3cccc4c3-c3ccccc3C4(C)C)cc2-c2cc3ccccc3cc21]

Sub3-33 (5.0 g, 15.5 mmol) was dissolved in toluene (77 mL), followed by the addition of Sub2-42 (5.6 g, 15.5 mmol), Pd₂(dba)₃ (0.42 g, 0.46 mmol), P(t-Bu)₃ (0.19 g, 0.93 mmol) and NaOt-Bu (3.0 g, 30.9 mmol). The reaction was carried out using the same method as described in the synthesis example of P2-40, affording 6.7 g of the product (yield: 72%).

The ED-MS values of the compounds P2-1 to P2-50 of the present invention, prepared according to the above synthesis examples, are shown in Table 5.

TABLE 5

| Compound | FD-MS | Compound | FD-MS |
|---|---|---|---|
| P2-1 | m/z = 473.21(C₃₆H₂₇N = 473.62) | P2-2 | m/z = 473.21(C₃₆H₂₇N = 473.62) |
| P2-3 | m/z = 573.25(C₄₄H₃₁N = 573.74) | P2-4 | m/z = 573.25(C₄₄H₃₁N = 573.74) |
| P2-5 | m/z = 497.21(C₃₈H₂₇N = 497.64) | P2-6 | m/z = 623.26(C₄₈H₃₃N = 623.8) |
| P2-7 | m/z = 573.25(C₄₄H₃₁N = 573.74) | P2-8 | m/z = 623.26(C₄₈H₃₃N = 623.8) |
| P2-9 | m/z = 491.33(C₃₆H₉D₁₈N = 491.73) | P2-10 | m/z = 649.28(C₅₀H₃₅N = 649.84) |
| P2-11 | m/z = 683.36(C₅₂H₄₅N = 683.94) | P2-12 | m/z = 585.34(C₄₄H₄₃N = 585.84) |
| P2-13 | m/z = 562.24(C₄₂H₃₀N₂ = 562.72) | P2-14 | m/z = 602.27(C₄₅H₃₄N₂ = 602.78) |
| P2-15 | m/z = 562.24(C₄₂H₃₀N₂ = 562.72) | P2-16 | m/z = 638.27(C₄₈H₃₄N₂ = 638.81) |
| P2-17 | m/z = 638.27(C₄₈H₃₄N₂ = 638.81) | P2-18 | m/z = 678.3(C₅₁H₃₈N₂ = 678.88) |
| P2-19 | m/z = 652.25(C₄₈H₃₂N₂O = 652.8) | P2-20 | m/z = 790.33(C₆₀H₄₂N₂ = 791.01) |
| P2-21 | m/z = 788.32(C₆₀H₄₀N₂ = 788.99) | P2-22 | m/z = 712.29(C₅₄H₃₆N₂ = 712.9) |
| P2-23 | m/z = 738.3(C₅₆H₃₈N₂ = 738.93) | P2-24 | m/z = 688.29(C₅₂H₃₆N₂ = 688.87) |
| P2-25 | m/z = 594.23(C₄₂H₃₀N₂O₂ = 594.71) | P2-26 | m/z = 668.23(C₄₈H₃₂N₂S = 668.86) |
| P2-27 | m/z = 750.4(C₅₆H₅₀N₂ = 751.03) | P2-28 | m/z = 496.27(C₃₆H₁₆D₁₀N₂ = 496.68) |
| P2-29 | m/z = 527.22(C₃₉H₂₉NO = 527.67) | P2-30 | m/z = 689.27(C₅₂H₃₅NO = 689.86) |
| P2-31 | m/z = 619.23(C₄₅H₃₃NS = 619.83) | P2-32 | m/z = 669.21(C₄₈H₃₁NOS = 669.84) |
| P2-33 | m/z = 643.2(C₄₆H₂₉NOS = 643.8) | P2-34 | m/z = 627.22(C₄₆H₂₉NO₂ = 627.74) |
| P2-35 | m/z = 583.14(C₄₀H₂₅NS₂ = 583.77) | P2-36 | m/z = 665.22(C₄₉H₃₁NS = 665.85) |
| P2-37 | m/z = 792.35(C₆₀H₄₄N₂ = 793.03) | P2-38 | m/z = 594.21(C₄₂H₃₀N₂S = 594.78) |
| P2-39 | m/z = 654.27(C₄₈H₃₄N₂O = 654.81) | P2-40 | m/z = 594.21(C₄₂H₃₀N₂S = 594.78) |
| P2-41 | m/z = 578.24(C₄₂H₃₀N₂O = 578.72) | P2-42 | m/z = 710.28(C₅₁H₃₈N₂S = 710.94) |
| P2-43 | m/z = 668.25(C₄₈H₃₂N₂O₂ = 668.8) | P2-44 | m/z = 603.29(C₄₆H₃₇N = 603.81) |
| P2-45 | m/z = 603.26(C₄₅H₃₃NO = 603.77) | P2-46 | m/z = 757.24(C₅₅H₃₅NOS = 757.95) |
| P2-47 | m/z = 607.16(C₄₂H₂₅NO₂S = 607.73) | P2-48 | m/z = 833.28(C₆₁H₃₉NOS = 834.05) |
| P2-49 | m/z = 833.28(C₆₁H₃₉NOS = 834.05) | P2-50 | m/z = 705.25(C₅₂H₃₅NS = 705.92) |

### Manufacturing and Evaluation of Organic Electronic Device

### [Test Example 1] Red Organic Electroluminescent Device (Light-Emitting Auxiliary Layer)

A hole injection layer with a thickness of 70 nm was formed by vacuum-depositing 4,4′,4″-tris[2-naphthyl(phenyl)amino]triphenylamine (abbreviated as 2-TNATA) on an ITO layer (anode). Then, a hole transport layer with a thickness of 70 nm was formed by vacuum-depositing N,N′-bis(1-naphthalenyl)-N,N′-bis-phenyl-(1,1′-biphenyl)-4,4′-diamine (abbreviated as NPB) on the hole injection layer.

Subsequently, a first light-emitting auxiliary layer was formed by vacuum-depositing Compound P1-1 of the present invention to a thickness of 70 nm on the hole transport layer. Then, a second light-emitting auxiliary layer was formed by vacuum-depositing Compound P2-3 of the present invention to a thickness of 5 nm on the first light-emitting auxiliary layer.

Next, a light-emitting layer having a thickness of 40 nm was formed on the second light-emitting auxiliary layer using 4,4′-N,N′-dicarbazole-biphenyl (abbreviated as CBP) as a host and bis(1-phenylisoquinolyl)iridium(III)acetylacetonate (abbreviated as (piq)₂Ir(acac)) as a dopant, and the dopant was doped into the host at a weight ratio of 95:5 (host:dopant).

Subsequently, a hole blocking layer having a thickness of 5 nm was formed by vacuum-depositing (1,1′-biphenyl-4-olato)bis(2-methyl-8-quinolinolato)aluminum (hereinafter abbreviated as “BAlq”) on the light-emitting layer. An electron transporting layer was then formed by vacuum-depositing bis(10-hydroxybenzo[h]quinolinato)beryllium (hereinafter abbreviated as “BeBq₂”) to a thickness of 30 nm on the hole blocking layer. Thereafter, an electron-injecting layer having a thickness of 0.2 nm was formed by depositing LiF on the electron transporting layer, followed by deposition of Al to form a cathode having a thickness of 150 nm.

### [Test Example 2] to [Test Example 45]

Organic electroluminescent devices were fabricated in the same manner as in Example 1, except that the compounds listed in Table 6 were used for the first and second light-emitting auxiliary layers.

### Comparative Example 1

An organic electroluminescent device was fabricated in the same manner as in Example 1, except that the following comparative compound A was used as the material for the second light-emitting auxiliary layer instead of Compound P2-3 of the present invention.

### <Comparative Compound A>

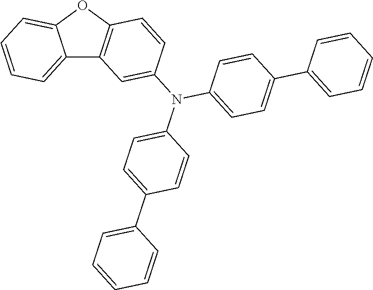 [SMILES: c1ccc(-c2ccc(N(c3ccc(-c4ccccc4)cc3)c3ccc4oc5ccccc5c4c3)cc2)cc1]

The electroluminescent (EL) characteristics of the organic electroluminescent devices fabricated according to the Test Examples of the present invention and Comparative Examples were measured by applying a forward DC voltage using a PR-650 photometer from Photo Research. The T95 lifetime was measured at a standard luminance of 2500 cd/m² using a lifetime measurement system manufactured by Mc Science. The measurement results are shown in Table 6 below.

TABLE 6

| | | | | Current | | |
|---|---|---|---|---|---|---|
| | | | Voltage | Density | Efficiency | |
| | EAL 1 | EAL 2 | (V) | (mA/cm²) | (cd/A) | T(95) |
| comp. Ex(1) | Comp. compdA | Com.(P2-3) | 5.3 | 12.2 | 20.5 | 104.5 |
| Test Ex.(1) | Com.(P1-1) | Com.(P2-3) | 5.1 | 10.5 | 23.8 | 121.1 |
| Test Ex.(2) | | Com.(P2-17) | 5.1 | 9.9 | 25.3 | 132.2 |
| Test Ex.(3) | | Com.(P2-29) | 5.1 | 11.5 | 21.7 | 117.2 |
| Test Ex.(4) | | Com.(P2-43) | 5.1 | 9.7 | 25.9 | 126.7 |
| Test Ex.(5) | | Com.(P2-44) | 5.1 | 11.0 | 22.7 | 114.6 |
| Test Ex.(6) | Com.(P1-3) | Com.(P2-3) | 5.0 | 10.7 | 23.4 | 123.0 |
| Test Ex.(7) | | Com.(P2-17) | 5.0 | 10.1 | 24.8 | 134.4 |
| Test Ex.(8) | | Com.(P2-29) | 5.1 | 11.8 | 21.1 | 119.1 |
| Test Ex.(9) | | Com.(P2-43) | 5.0 | 9.8 | 25.5 | 128.1 |
| Test Ex.(10) | | Com.(P2-44) | 5.0 | 11.2 | 22.2 | 116.8 |
| Test Ex.(11) | Com.(P1-8) | Com.(P2-3) | 5.0 | 10.4 | 24.1 | 123.5 |
| Test Ex.(12) | | Com.(P2-17) | 5.0 | 9.8 | 25.5 | 134.8 |
| Test Ex.(13) | | Com.(P2-29) | 5.0 | 11.4 | 22.0 | 120.1 |
| Test Ex.(14) | | Com.(P2-43) | 5.0 | 9.5 | 26.3 | 128.9 |
| Test Ex.(15) | | Com.(P2-44) | 5.0 | 11.0 | 22.8 | 117.4 |
| Test Ex.(16) | Com.(P1-13) | Com.(P2-3) | 4.8 | 10.2 | 24.6 | 117.3 |
| Test Ex.(17) | | Com.(P2-17) | 4.8 | 9.6 | 26.1 | 128.7 |
| Test Ex.(18) | | Com.(P2-29) | 4.8 | 11.2 | 22.2 | 114.6 |
| Test Ex.(19) | | Com.(P2-43) | 4.8 | 9.4 | 26.6 | 122.9 |
| Test Ex.(20) | | Com.(P2-44) | 4.8 | 10.6 | 23.5 | 112.3 |
| Test Ex.(21) | Com.(P1-20) | Com.(P2-3) | 4.9 | 10.3 | 24.2 | 114.7 |
| Test Ex.(22) | | Com.(P2-17) | 4.9 | 9.7 | 25.8 | 125.4 |
| Test Ex.(23) | | Com.(P2-29) | 4.9 | 11.4 | 21.9 | 110.6 |
| Test Ex.(24) | | Com.(P2-43) | 4.9 | 9.4 | 26.6 | 120.1 |
| Test Ex.(25) | | Com.(P2-44) | 4.9 | 10.8 | 23.2 | 109.2 |
| Test Ex.(26) | Com.(P1-21) | Com.(P2-3) | 4.9 | 10.1 | 24.8 | 119.1 |
| Test Ex.(27) | | Com.(P2-17) | 4.9 | 9.5 | 26.2 | 130.2 |
| Test Ex.(28) | | Com.(P2-29) | 5.0 | 11.2 | 22.4 | 116.1 |
| Test Ex.(29) | | Com.(P2-43) | 4.9 | 9.3 | 27.0 | 124.9 |
| Test Ex.(30) | | Com.(P2-44) | 4.9 | 10.6 | 23.5 | 112.9 |
| Test Ex.(31) | Com.(P1-35) | Com.(P2-3) | 4.7 | 9.9 | 25.2 | 116.1 |
| Test Ex.(32) | | Com.(P2-17) | 4.7 | 9.3 | 26.9 | 127.7 |
| Test Ex.(33) | | Com.(P2-29) | 4.7 | 10.9 | 22.9 | 112.4 |
| Test Ex.(34) | | Com.(P2-43) | 4.7 | 9.1 | 27.4 | 121.9 |
| Test Ex.(35) | | Com.(P2-44) | 4.7 | 10.4 | 24.0 | 110.6 |
| Test Ex.(36) | Com.(P1-41) | Com.(P2-3) | 4.6 | 9.4 | 26.7 | 119.7 |
| Test Ex.(37) | | Com.(P2-17) | 4.6 | 8.9 | 28.2 | 131.4 |
| Test Ex.(38) | | Com.(P2-29) | 4.7 | 10.4 | 24.1 | 116.3 |
| Test Ex.(39) | | Com.(P2-43) | 4.6 | 8.6 | 29.0 | 125.9 |
| Test Ex.(40) | | Com.(P2-44) | 4.6 | 9.9 | 25.3 | 113.7 |
| Test Ex.(41) | Com.(P1-45) | Com.(P2-3) | 4.6 | 9.5 | 26.3 | 115.5 |
| Test Ex.(42) | | Com.(P2-17) | 4.6 | 9.0 | 27.8 | 126.4 |
| Test Ex.(43) | | Com.(P2-29) | 4.6 | 10.5 | 23.7 | 112.5 |
| Test Ex.(44) | | Com.(P2-43) | 4.6 | 8.8 | 28.4 | 121.1 |
| Test Ex.(45) | | Com.(P2-44) | 4.6 | 10.0 | 24.9 | 110.1 |

As shown in Table 6, it can be seen that the driving voltage, efficiency, and lifetime of the device were all improved when a compound of Formula 1 of the present invention was used to form a first light-emitting auxiliary layer, compared to the case where Comparative Compound A was used. While Comparative Compound A has a structure in which an amino group is substituted on a dibenzothiophene, the compound of the present invention has a structure in which an amino group is substituted on a dibenzosilole. With the introduction of dibenzosilole, the packing density is improved, resulting in a lower driving voltage of the device, and increased refractive index and thermal stability, which appear to enhance the efficiency and lifetime of the device.

To investigate the influence of the reorganization energy values of Comparative Compound A and the inventive compound P1-13 on device characteristics, the reorganization energy of each compound was examined. Table 7 below shows the calculated RE_{Hole} values of these compounds.

TABLE 7

| Compound | Reorganization Energy (RE) |
|---|---|
| Comp. compd A | 0.142 |
| P1-13 | 0.137 |

Looking at Table 7, it can be seen that the RE value varies depending on the substitution of the amine group. Compared to Comparative Compound A, the compound P1-13 of the present invention has a lower RE value. Therefore, it appears that the hole mobility of the compound P1-13 of the present invention is faster than that of Comparative Compound A, resulting in a lower driving voltage. However, simply using a material with a fast hole mobility does not necessarily improve the efficiency and lifespan of the device, as properties of the compound, such as the energy level difference with a light-emitting layer, affect the entire device. Therefore, it is necessary to introduce a second light-emitting auxiliary layer to improve the efficiency and lifespan of the device.

The energy level characteristics of the second light-emitting auxiliary layer were measured using the DFT method (B3LYP/6-31g(D)) of the Gaussian program, and the measurement results are shown in Table 8 below.

TABLE 8

| Compound | P2-3 | P2-17 | P2-29 | P2-43 | P2-44 |
|---|---|---|---|---|---|
| G. HOMO | −5.001 | −5.018 | −4.832 | −5.004 | −4.978 |
| G. LUMO | −1.106 | −0.871 | −1.064 | −1.087 | −1.378 |
| G. T1 | 2.570 | 2.726 | 2.648 | 2.778 | 2.511 |

As shown in Table 8, it was confirmed that a compound with a lower HOMO level in the second light-emitting auxiliary layer improves the efficiency of the device. This is likely because efficient hole injection into the host material occurs from the second light-emitting auxiliary layer, and as the LUMO value increases, it can more effectively block electrons coming from the host material. As a result, it appears to have affected the device's efficiency and lifespan.

Therefore, it seems that the first light-emitting auxiliary layer affects the driving voltage, while the second light-emitting auxiliary layer affects the device's efficiency and lifespan.

The foregoing description is merely illustrative of the present invention and various modifications may be made by those of ordinary skill in the art without departing from the essential characteristics of the invention. The scope of protection of the present invention should be interpreted based on the following claims, and all technical equivalents thereof should be construed as falling within the scope of the invention.

1: An organic electronic device comprising:
a first electrode;
a second electrode;
a light-emitting layer disposed between the first electrode and the second electrode;
a hole transport layer between the first electrode and the light-emitting layer; and
a plurality of light-emitting auxiliary layers positioned between the light-emitting layer and the hole transport layer, the plurality of light-emitting auxiliary layers comprising:
a first light-emitting auxiliary layer adjacent to the hole transport layer, the first light-emitting auxiliary layer comprising a compound represented by Formula 1; and
a second light-emitting auxiliary layer adjacent to the light-emitting layer, the second light-emitting auxiliary layer comprising a compound represented by Formula 2: 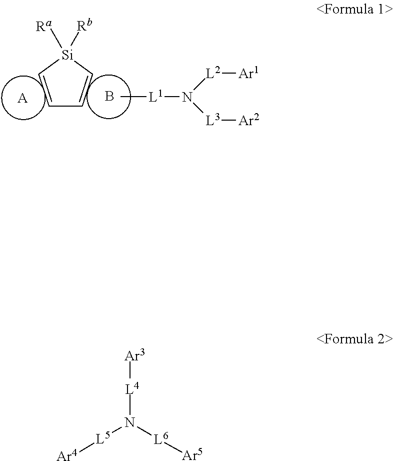
wherein:
a A ring and a B ring are each independently a C₆-C₆₀ aryl ring, wherein the A ring may be substituted with one or more R¹s, which may be the same or different, and the B ring may be substituted with one or more R²s, which may be the same or different,
R^{a}, R^{b}, R¹ and R² are each independently selected from the group consisting of hydrogen, deuterium, halogen, a cyano group, a nitro group, a C₆-C₆₀ aryl group, a fluorenyl group, a C₂-C₆₀ heterocyclic group containing at least one heteroatom of O, N, S, Si and P, a C₃-C₆₀ aliphatic ring group, a C₁-C₂₀ alkyl group, a C₂-C₂₀ alkenyl group, a C₂-C₂₀ alkynyl group, a C₁-C₂₀ alkoxyl group, a C₆-C₆₀ aryloxy group, and -L′-N(Rₐ)(R_{b}), and adjacent R^{a} and R^{b} may be bonded to each other to form a ring,
L¹ to L⁶ are each independently selected from the group consisting of a single bond, a C₆-C₆₀ arylene group, a fluorenylene group, a C₃-C₆₀ aliphatic ring group, and a C₂-C₆₀ heterocyclic group containing at least one heteroatom of O, N, S, Si and P,
Ar¹ to Ar⁵ are each independently selected from the group consisting of a C₆-C₆₀ aryl group, a fluorenyl group, a C₃-C₆₀ aliphatic ring group, a C₂-C₆₀ heterocyclic group containing at least one heteroatom of O, N, S, Si and P, a C₁-C₂₀ alkyl group, and -L′-N(Rₐ)(R_{b}),
L′ is selected from the group consisting of a single bond, a C₆-C₃₀ arylene group, a fluorenylene group, a C₂-C₃₀ heterocyclic group containing at least one heteroatom of O, N, S, Si and P, and a C₃-C₃₀ aliphatic ring group,
Rₐ and R_{b} are each independently selected from the group consisting of a C₆-C₃₀ aryl group, a fluorenyl group, a C₂-C₃₀ heterocyclic group containing at least one heteroatom of O, N, S, Si and P, and a C₃-C₃₀ aliphatic ring group, and
the aryl group, the arylene group, the fluorenyl group, the fluorenylene group, the heterocyclic group, the aliphatic ring group, the alkyl group, the alkenyl group, the alkynyl group, the alkoxyl group, the aryloxyl group, and the ring formed by adjacent groups may be each substituted with one or more substituents selected from the group consisting of deuterium, halogen, a silane group unsubstituted or substituted with a C₁-C₂₀ alkyl group or a C₆-C₂₀ aryl group, a phosphine oxide substituted or unsubstituted with a C₁-C₂₀ alkyl group or a C₆-C₂₀ aryl group, siloxane group, a cyano group, a nitro group, C₁-C₂₀ alkylthio group, C₁-C₂₀ alkoxy group, C₆-C₃₀ aryloxy group, C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}).

2: The organic electronic device of claim 1, wherein Formula 1 is represented by Formula 1-1: 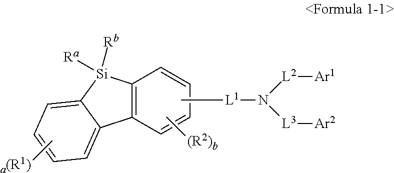
in Formula 1-1, R¹, R², R^{a}, R^{b}, L¹ to L³, Ar¹, Ar² are the same as defined in claim 1, a is an integer of 0 to 4, and b is an integer of 0 to 3.

3: The organic electronic device of claim 2, wherein Formula 1-1 is one of Formula 1-2 to Formula 1-4: 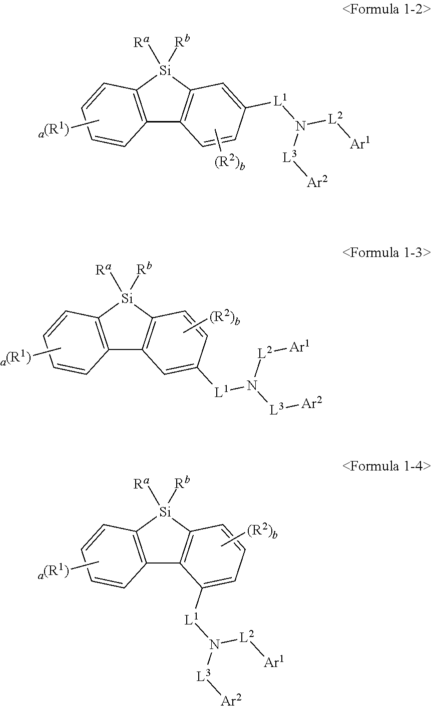
in Formula 1-2 to Formula 1-4, R¹, R², R^{a}, R^{b}, L¹ to L³, Ar¹, Ar², a, b are the same as defined in claim 2.

4: The organic electronic device of claim 1, wherein Ar³ is selected from the group consisting of Formula Ar-1 to Formula Ar-3: 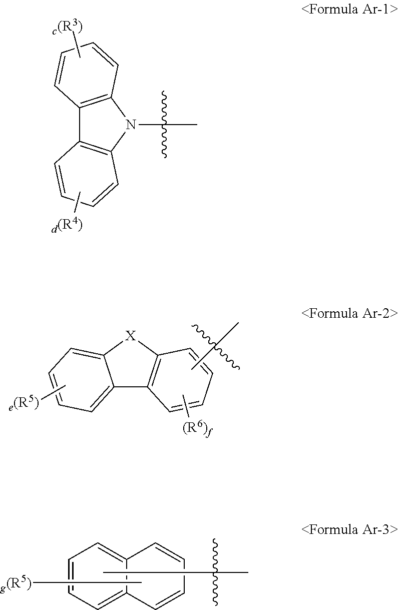
in Formula Ar-1 to Formula Ar-3,
X is O or S,
R³ to R⁷ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₃₀ aryloxy group, a C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring, c, d and e are each an integer of 0 to 4, f is an integer of 0 to 3, and g is an integer of 0 to 7.

5: The organic electronic device of claim 1, wherein Formula 2 is represented by Formula 2-1: 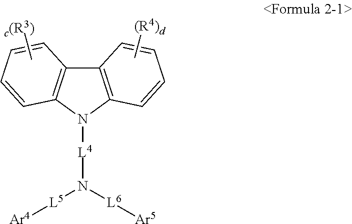
in Formula 2-1, Ar⁴, Ar⁵, L⁴ to L⁶ are the same as defined in claim 1,
R³ and R⁴ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₃₀ aryloxy group, a C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and adjacent groups may be bonded to each other to form a ring, and c and d are each an integer of 0 to 4.

6: The organic electronic device of claim 1, wherein at least one of the L¹ to L⁶ is selected from the group consisting of Formula L-1 to Formula L-12: 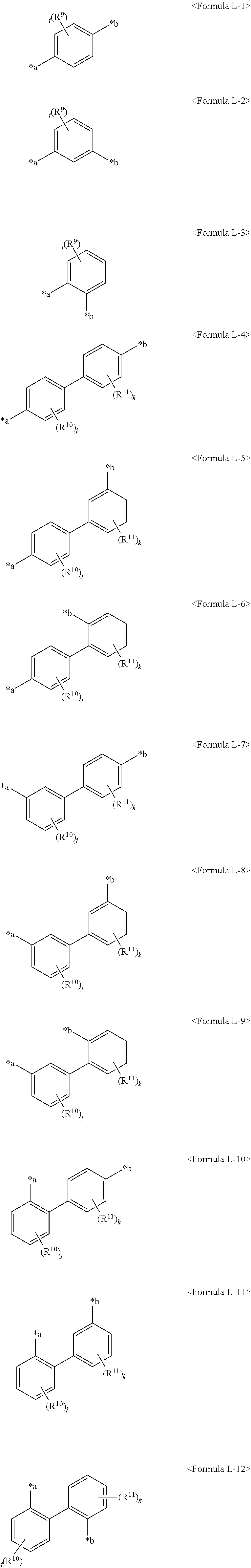
in Formula L-1 to Formula L-12,
*a represents the position bonded to the N of the amine group, *b represents the position bonded to Ar1 to Ar5 or the B ring,
R⁹ to R¹¹ are each independently selected from the group consisting of hydrogen, deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, siloxane group, a cyano group, a nitro group, a C₁-C₂₀ alkylthio group, a C₁-C₂₀ alkoxyl group, a C₆-C₃₀ aryloxy group, a C₆-C₃₀ arylthio group, a C₁-C₂₀ alkyl group, a C₂-C₂₀ alkenyl group, a C₂-C₂₀ alkynyl group, a C₆-C₃₀ aryl group, a fluorenyl group, a C₂-C₃₀ heterocyclic group comprising at least one heteroatom selected from the group consisting of O, N, S, Si and P, a C₃-C₃₀ aliphatic ring group, and -L′-N(Rₐ)(R_{b}), and i, j and k are each an integer of 0 to 4.

7: The organic electronic device of claim 1, wherein the compound represented by Formula 1 is one of the following compounds:

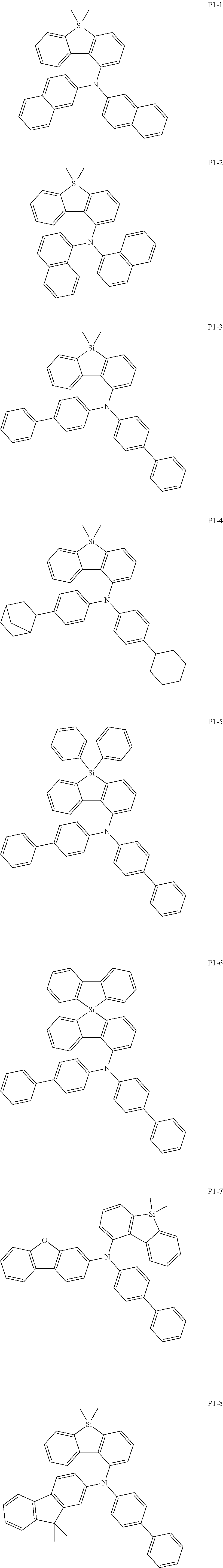

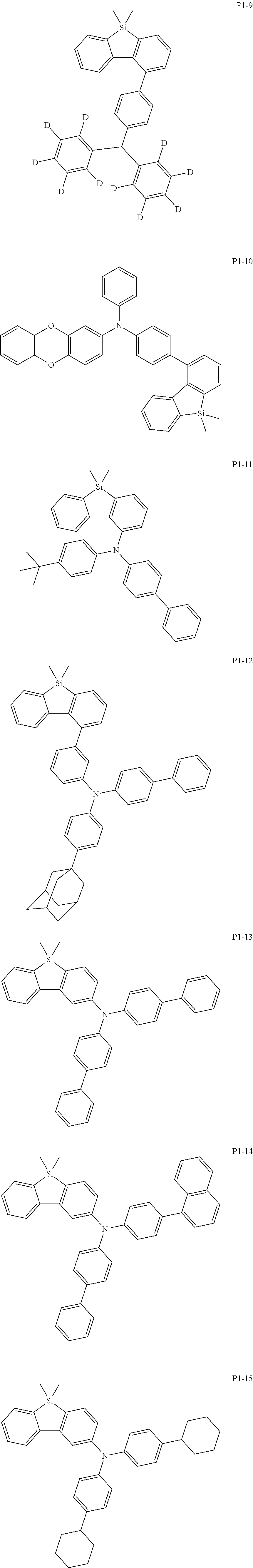

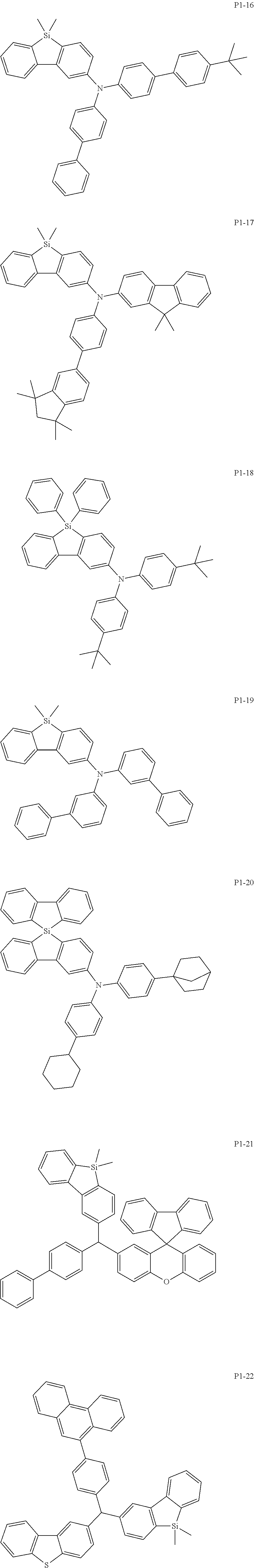

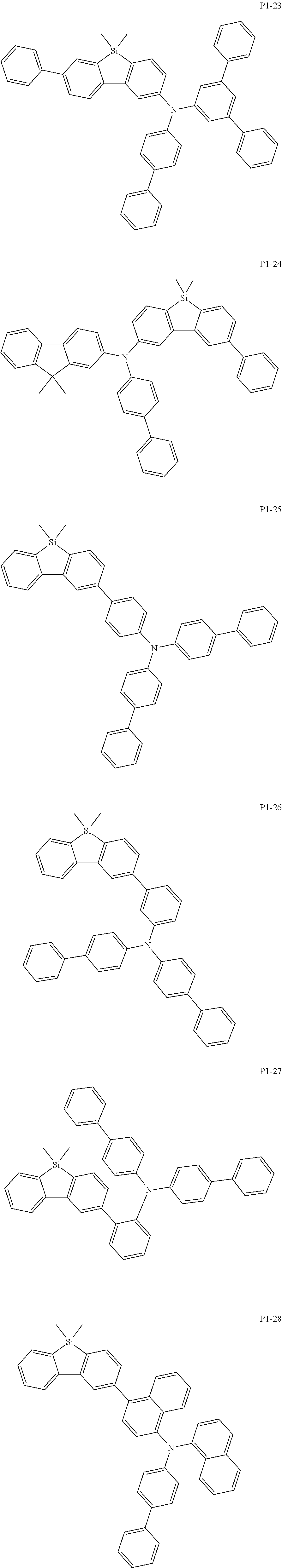

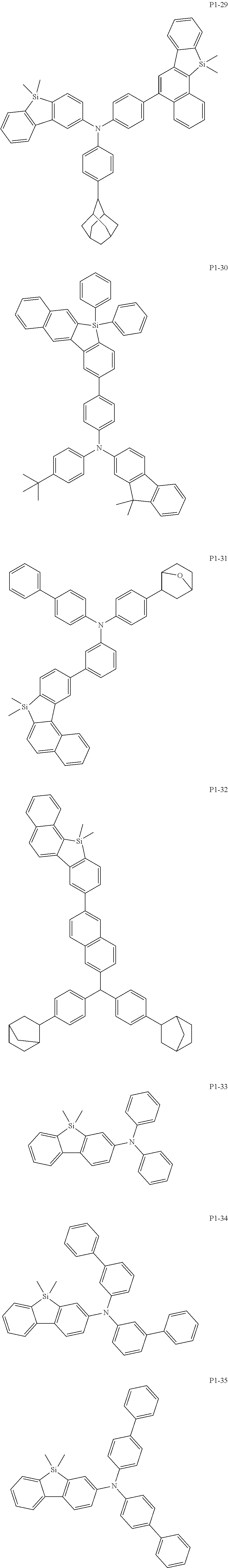

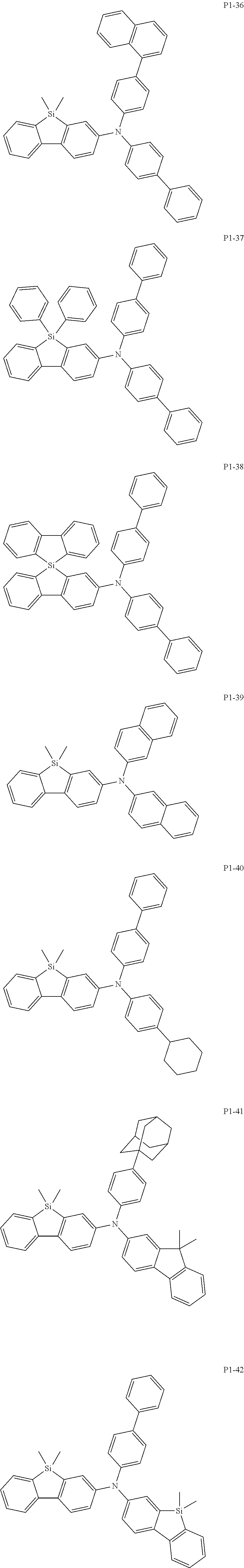

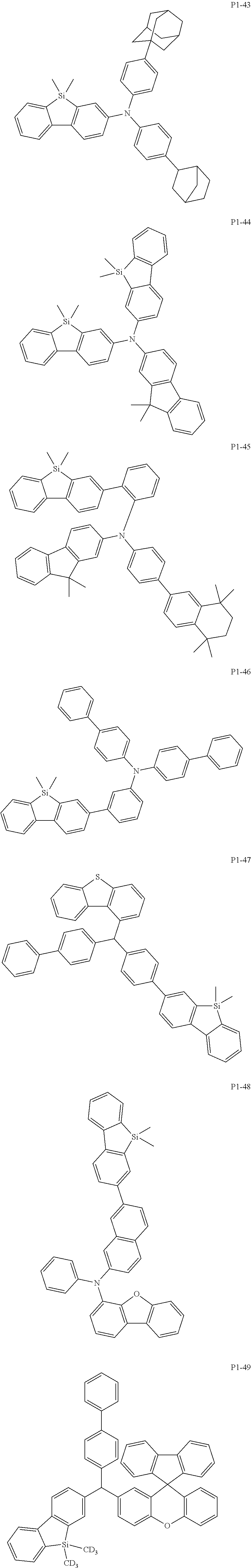

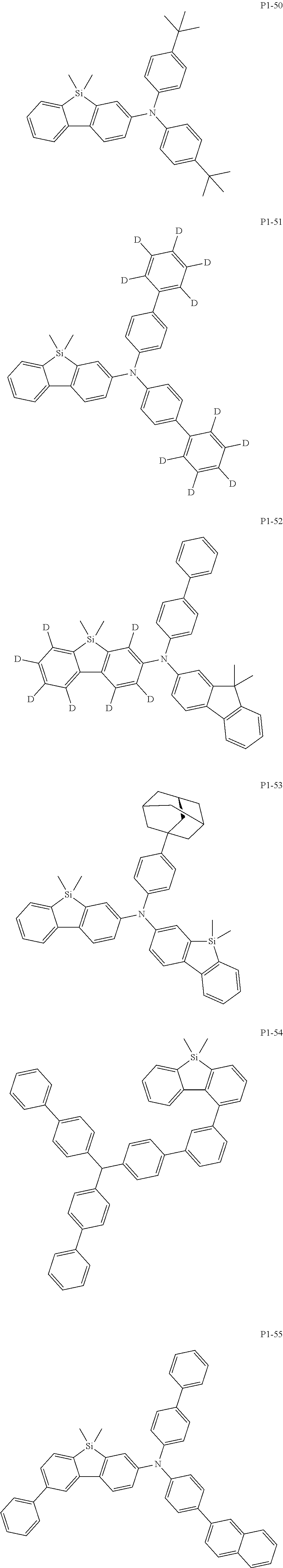

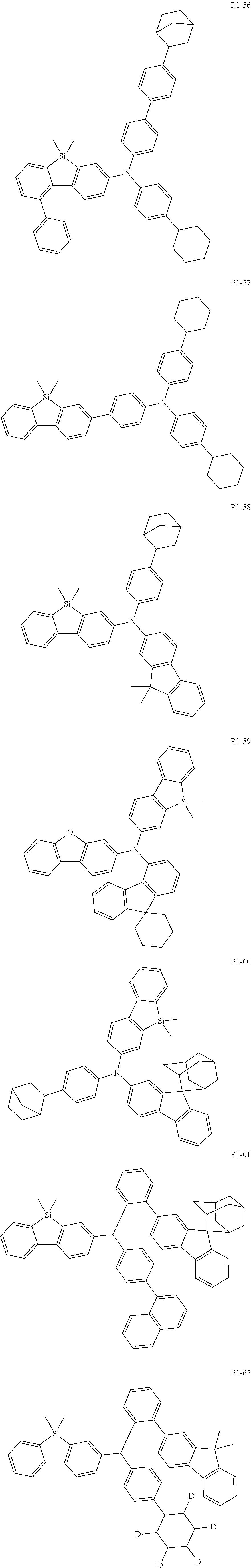

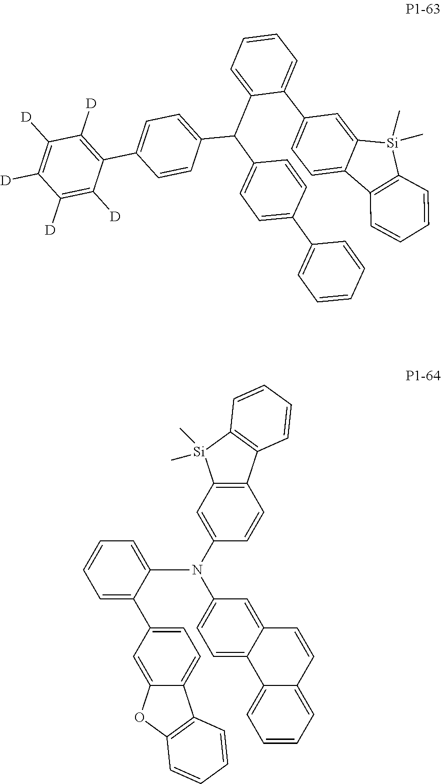 [SMILES: [2H]c1c([2H])c([2H])c(-c2ccc(C(c3ccc(-c4ccccc4)cc3)c3ccccc3-c3ccc4c(c3)[Si](C)(C)c3ccccc3-4)cc2)c([2H])c1[2H] ; C[Si]1(C)c2ccccc2-c2ccc(N(c3ccc4c(ccc5ccccc54)c3)c3ccccc3-c3ccc4c(c3)oc3ccccc34)cc21]

8: The organic electronic device of claim 1, wherein compound represented by Formula 2 is one of the following compounds:

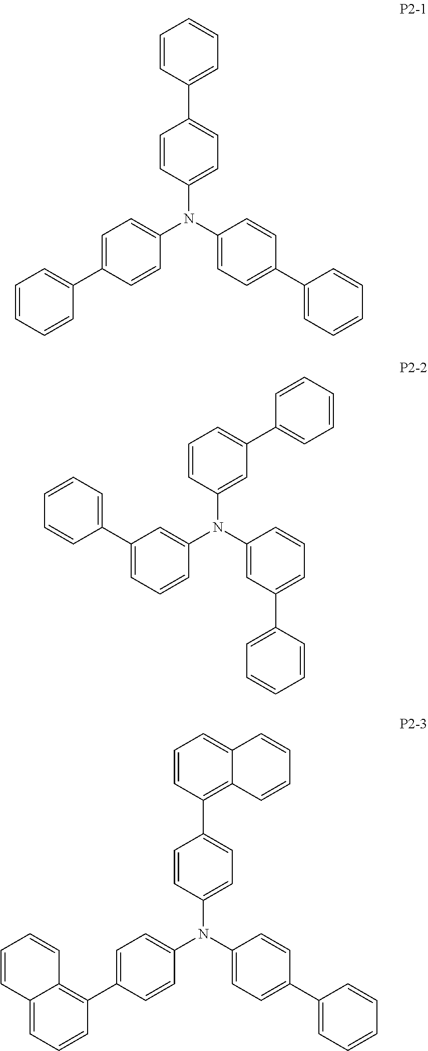

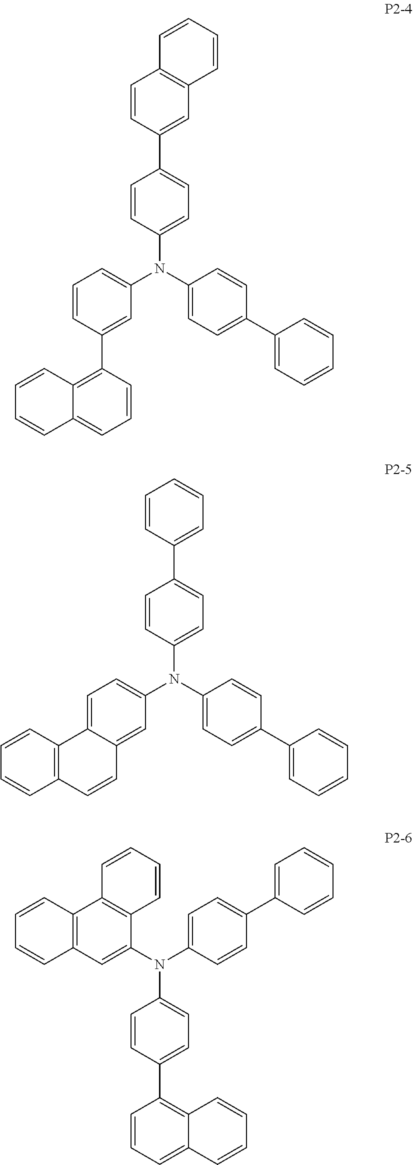 [SMILES: c1ccc(-c2ccc(N(c3ccc(-c4ccc5ccccc5c4)cc3)c3cccc(-c4cccc5ccccc45)c3)cc2)cc1 ; c1ccc(-c2ccc(N(c3ccc(-c4ccccc4)cc3)c3ccc4c(ccc5ccccc54)c3)cc2)cc1 ; c1ccc(-c2ccc(N(c3ccc(-c4cccc5ccccc45)cc3)c3cc4ccccc4c4ccccc34)cc2)cc1]

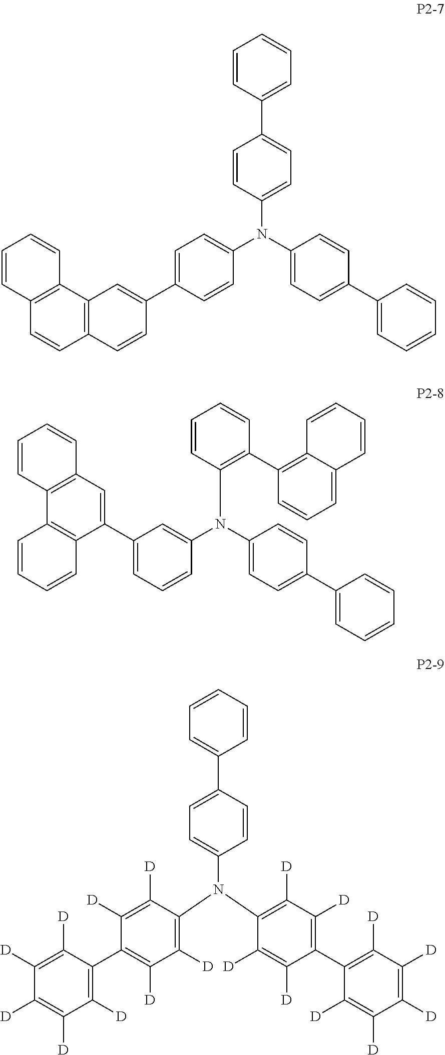 [SMILES: c1ccc(-c2ccc(N(c3ccc(-c4ccccc4)cc3)c3ccc(-c4ccc5ccc6ccccc6c5c4)cc3)cc2)cc1 ; c1ccc(-c2ccc(N(c3cccc(-c4cc5ccccc5c5ccccc45)c3)c3ccccc3-c3cccc4ccccc34)cc2)cc1 ; [2H]c1c([2H])c([2H])c(-c2c([2H])c([2H])c(N(c3ccc(-c4ccccc4)cc3)c3c([2H])c([2H])c(-c4c([2H])c([2H])c([2H])c([2H])c4[2H])c([2H])c3[2H])c([2H])c2[2H])c([2H])c1[2H]]

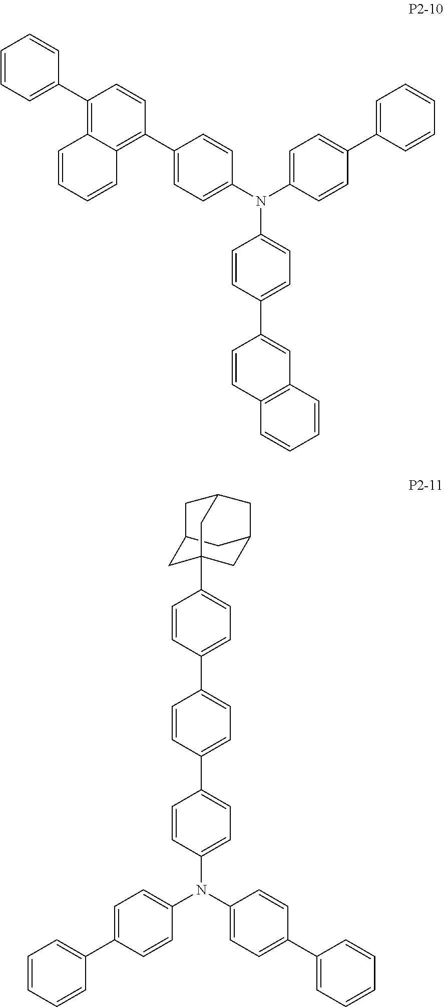 [SMILES: c1ccc(-c2ccc(N(c3ccc(-c4ccc5ccccc5c4)cc3)c3ccc(-c4ccc(-c5ccccc5)c5ccccc45)cc3)cc2)cc1 ; c1ccc(-c2ccc(N(c3ccc(-c4ccccc4)cc3)c3ccc(-c4ccc(-c5ccc(C67CC8CC(CC(C8)C6)C7)cc5)cc4)cc3)cc2)cc1]

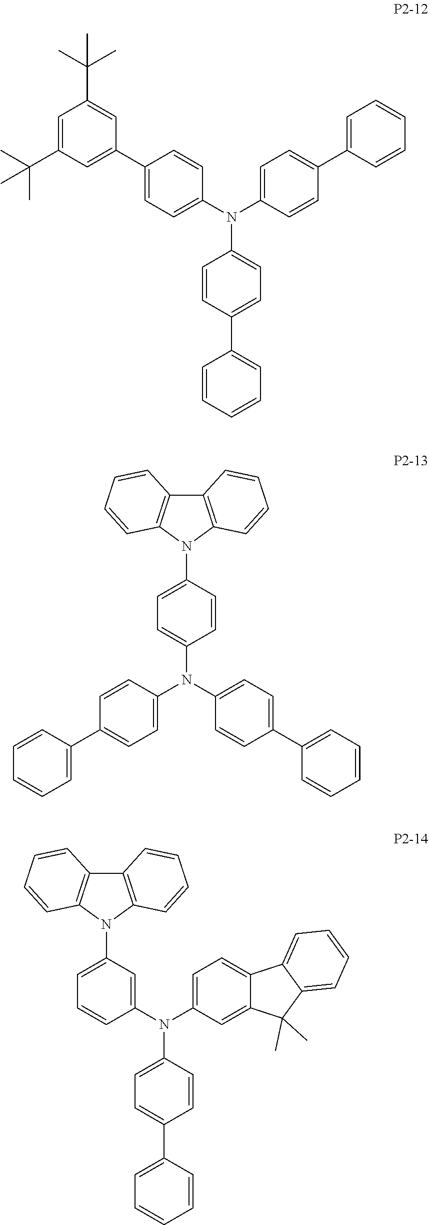 [SMILES: CC(C)(C)c1cc(-c2ccc(N(c3ccc(-c4ccccc4)cc3)c3ccc(-c4ccccc4)cc3)cc2)cc(C(C)(C)C)c1 ; c1ccc(-c2ccc(N(c3ccc(-c4ccccc4)cc3)c3ccc(-n4c5ccccc5c5ccccc54)cc3)cc2)cc1 ; CC1(C)c2ccccc2-c2ccc(N(c3ccc(-c4ccccc4)cc3)c3cccc(-n4c5ccccc5c5ccccc54)c3)cc21]

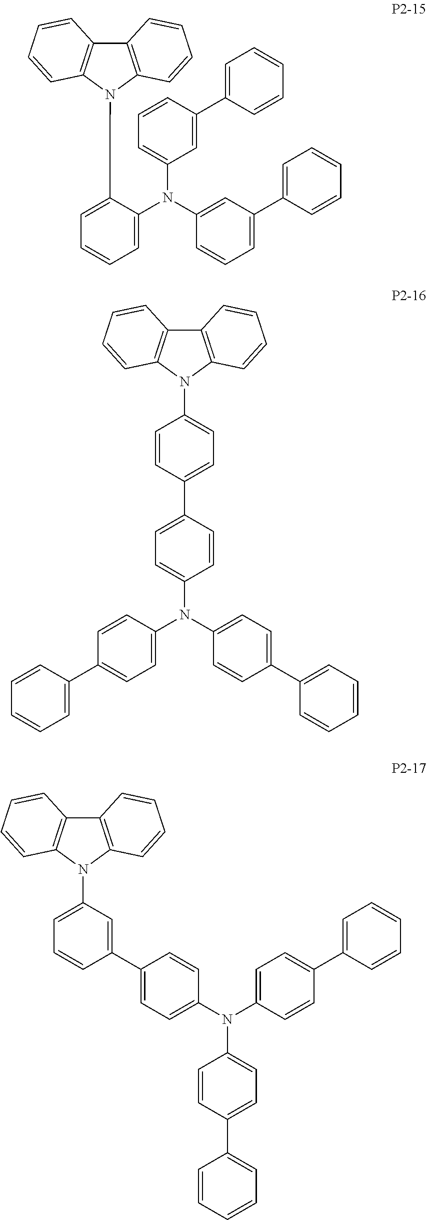

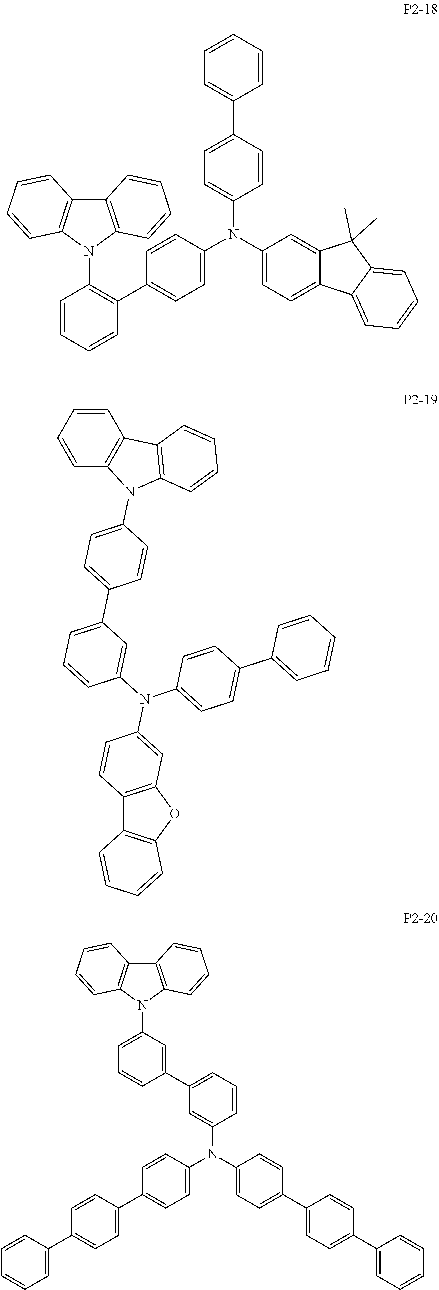 [SMILES: CC1(C)c2ccccc2-c2ccc(N(c3ccc(-c4ccccc4)cc3)c3ccc(-c4ccccc4-n4c5ccccc5c5ccccc54)cc3)cc21 ; c1ccc(-c2ccc(N(c3cccc(-c4ccc(-n5c6ccccc6c6ccccc65)cc4)c3)c3ccc4c(c3)oc3ccccc34)cc2)cc1 ; c1ccc(-c2ccc(-c3ccc(N(c4ccc(-c5ccc(-c6ccccc6)cc5)cc4)c4cccc(-c5cccc(-n6c7ccccc7c7ccccc76)c5)c4)cc3)cc2)cc1]

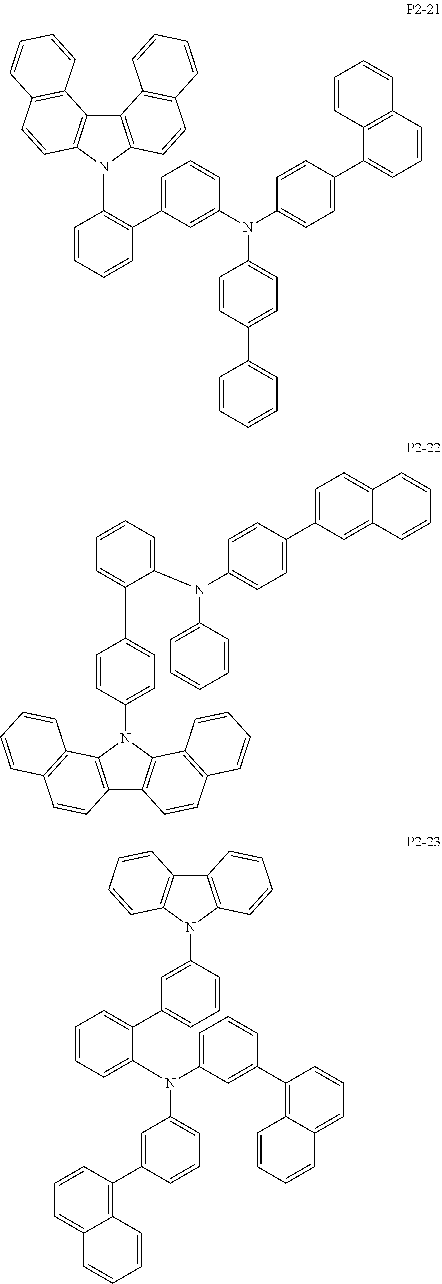

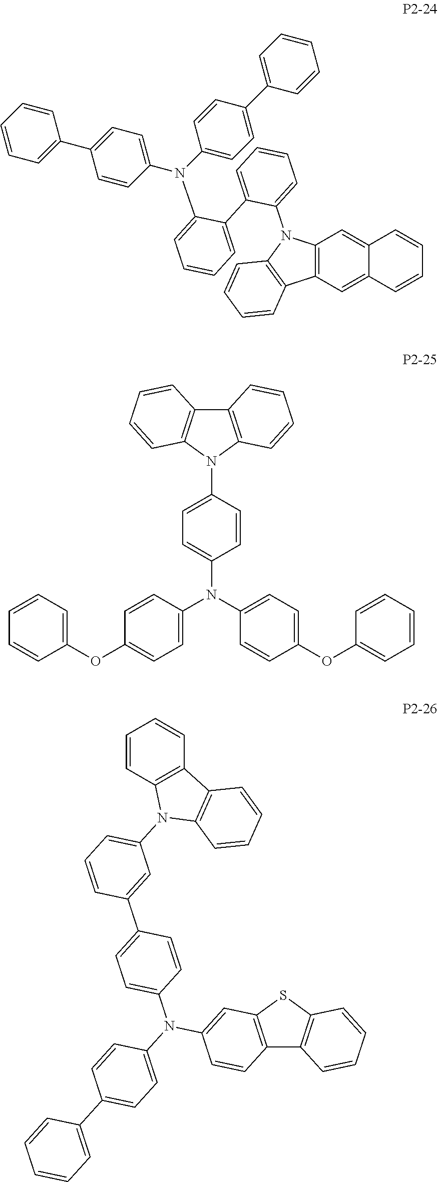 [SMILES: c1ccc(-c2ccc(N(c3ccc(-c4ccccc4)cc3)c3ccccc3-c3ccccc3-n3c4ccccc4c4cc5ccccc5cc43)cc2)cc1 ; c1ccc(Oc2ccc(N(c3ccc(Oc4ccccc4)cc3)c3ccc(-n4c5ccccc5c5ccccc54)cc3)cc2)cc1 ; c1ccc(-c2ccc(N(c3ccc(-c4cccc(-n5c6ccccc6c6ccccc65)c4)cc3)c3ccc4c(c3)sc3ccccc34)cc2)cc1]

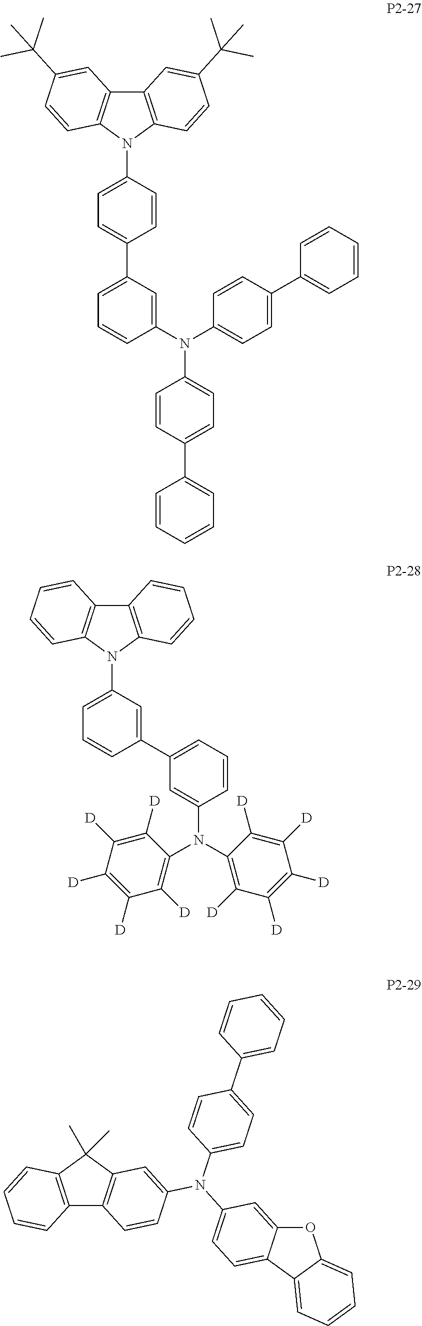

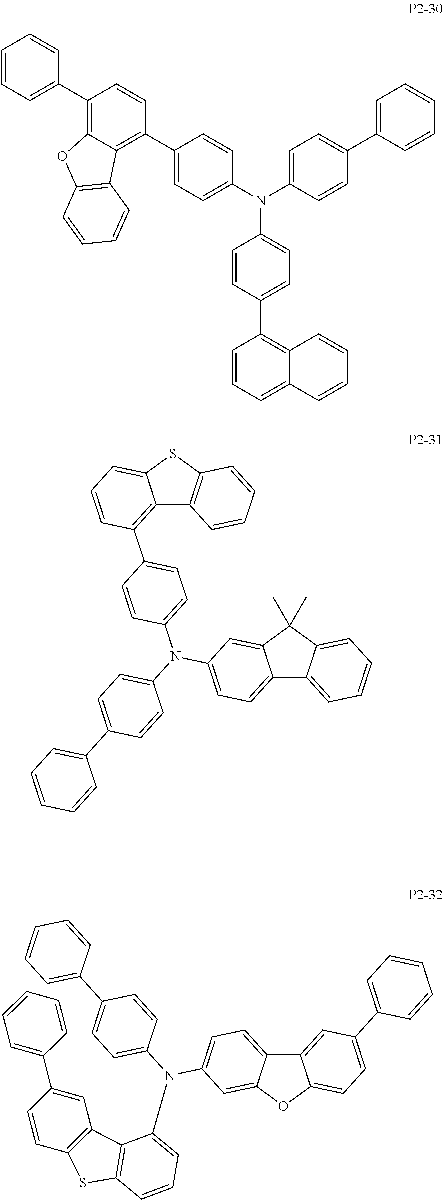 [SMILES: c1ccc(-c2ccc(N(c3ccc(-c4cccc5ccccc45)cc3)c3ccc(-c4ccc(-c5ccccc5)c5oc6ccccc6c45)cc3)cc2)cc1 ; CC1(C)c2ccccc2-c2ccc(N(c3ccc(-c4ccccc4)cc3)c3ccc(-c4cccc5sc6ccccc6c45)cc3)cc21 ; c1ccc(-c2ccc(N(c3ccc4c(c3)oc3ccc(-c5ccccc5)cc34)c3cccc4sc5ccc(-c6ccccc6)cc5c34)cc2)cc1]

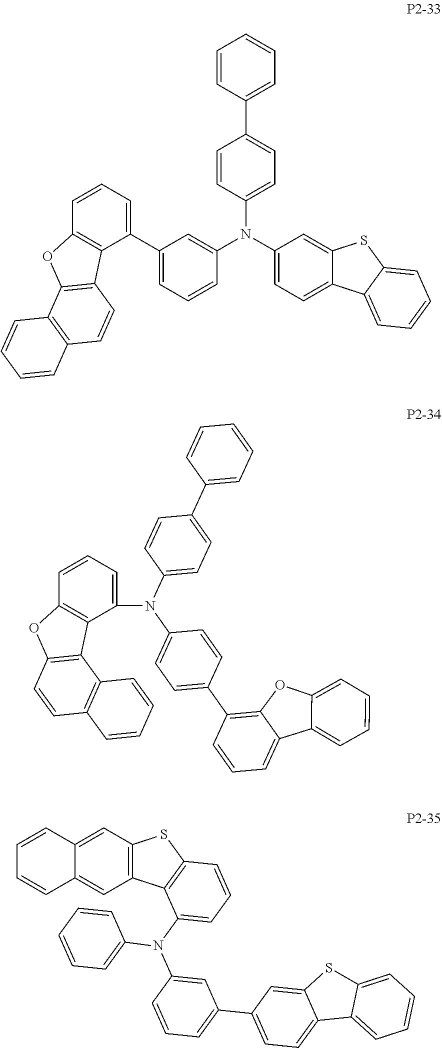 [SMILES: c1ccc(-c2ccc(N(c3cccc(-c4cccc5oc6c7ccccc7ccc6c45)c3)c3ccc4c(c3)sc3ccccc34)cc2)cc1 ; c1ccc(-c2ccc(N(c3ccc(-c4cccc5c4oc4ccccc45)cc3)c3cccc4oc5ccc6ccccc6c5c34)cc2)cc1 ; c1ccc(N(c2cccc(-c3ccc4c(c3)sc3ccccc34)c2)c2cccc3sc4cc5ccccc5cc4c23)cc1]

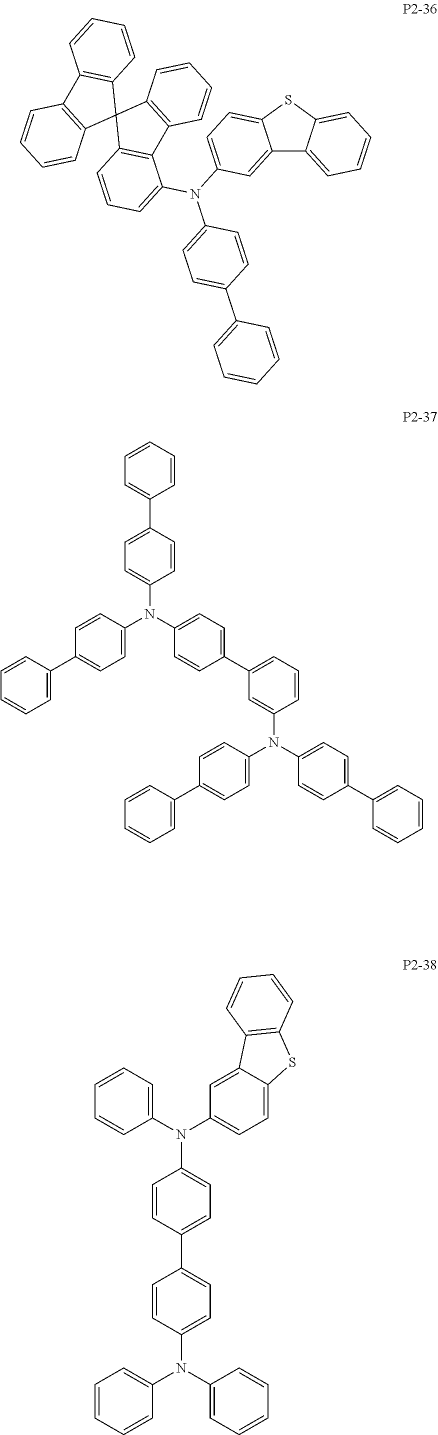 [SMILES: c1ccc(-c2ccc(N(c3ccc4sc5ccccc5c4c3)c3cccc4c3-c3ccccc3C43c4ccccc4-c4ccccc43)cc2)cc1 ; c1ccc(-c2ccc(N(c3ccc(-c4ccccc4)cc3)c3ccc(-c4cccc(N(c5ccc(-c6ccccc6)cc5)c5ccc(-c6ccccc6)cc5)c4)cc3)cc2)cc1 ; c1ccc(N(c2ccccc2)c2ccc(-c3ccc(N(c4ccccc4)c4ccc5sc6ccccc6c5c4)cc3)cc2)cc1]

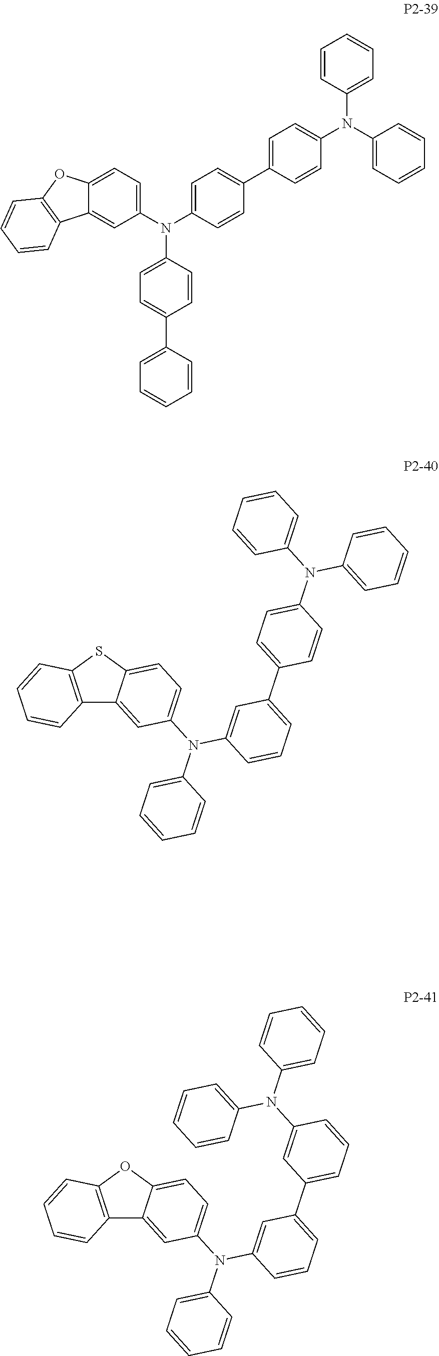 [SMILES: c1ccc(-c2ccc(N(c3ccc(-c4ccc(N(c5ccccc5)c5ccccc5)cc4)cc3)c3ccc4oc5ccccc5c4c3)cc2)cc1 ; c1ccc(N(c2ccccc2)c2ccc(-c3cccc(N(c4ccccc4)c4ccc5sc6ccccc6c5c4)c3)cc2)cc1 ; c1ccc(N(c2ccccc2)c2cccc(-c3cccc(N(c4ccccc4)c4ccc5oc6ccccc6c5c4)c3)c2)cc1]

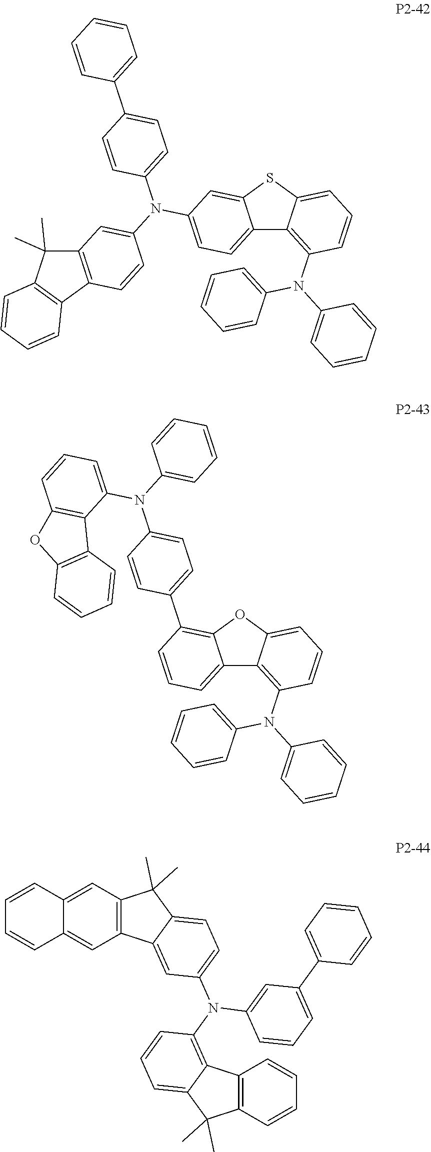 [SMILES: CC1(C)c2ccccc2-c2ccc(N(c3ccc(-c4ccccc4)cc3)c3ccc4c(c3)sc3cccc(N(c5ccccc5)c5ccccc5)c34)cc21 ; c1ccc(N(c2ccc(-c3cccc4c3oc3cccc(N(c5ccccc5)c5ccccc5)c34)cc2)c2cccc3oc4ccccc4c23)cc1 ; CC1(C)c2ccc(N(c3cccc(-c4ccccc4)c3)c3cccc4c3-c3ccccc3C4(C)C)cc2-c2cc3ccccc3cc21]

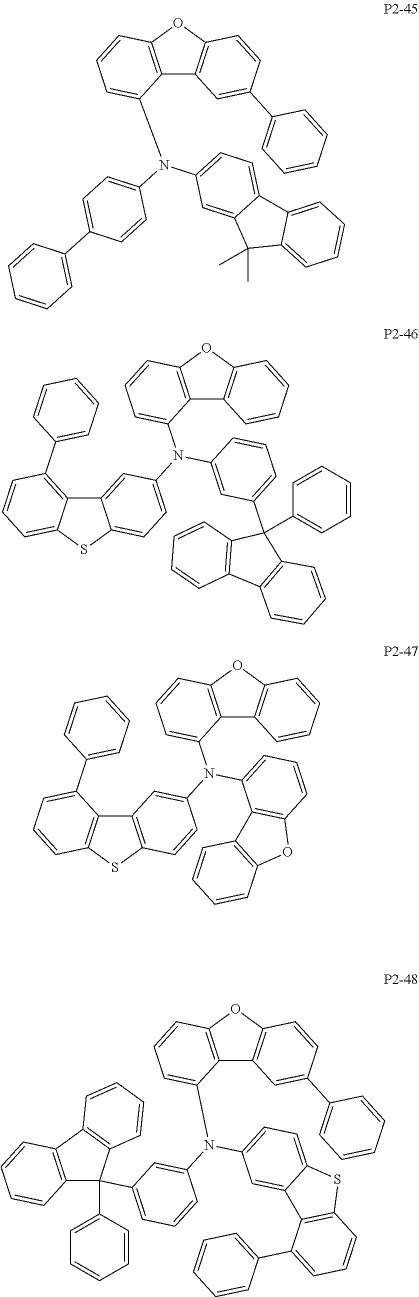 [SMILES: CC1(C)c2ccccc2-c2ccc(N(c3ccc(-c4ccccc4)cc3)c3cccc4oc5ccc(-c6ccccc6)cc5c34)cc21 ; c1ccc(-c2cccc3sc4ccc(N(c5cccc(C6(c7ccccc7)c7ccccc7-c7ccccc76)c5)c5cccc6oc7ccccc7c56)cc4c23)cc1 ; c1ccc(-c2cccc3sc4ccc(N(c5cccc6oc7ccccc7c56)c5cccc6oc7ccccc7c56)cc4c23)cc1 ; c1ccc(-c2ccc3oc4cccc(N(c5cccc(C6(c7ccccc7)c7ccccc7-c7ccccc76)c5)c5ccc6sc7cccc(-c8ccccc8)c7c6c5)c4c3c2)cc1]

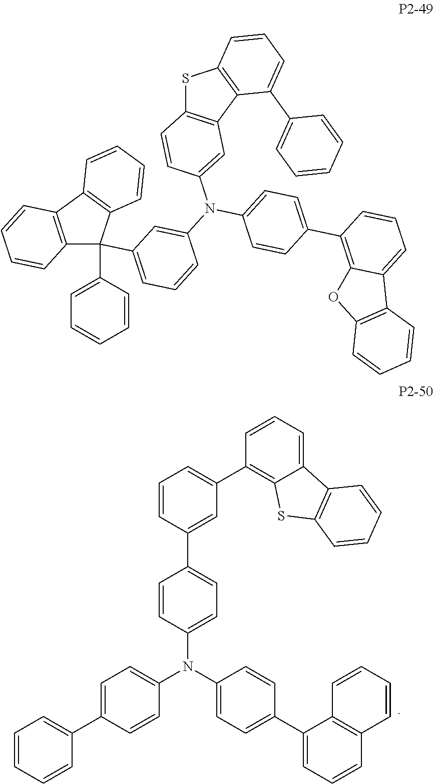 [SMILES: c1ccc(-c2cccc3sc4ccc(N(c5ccc(-c6cccc7c6oc6ccccc67)cc5)c5cccc(C6(c7ccccc7)c7ccccc7-c7ccccc76)c5)cc4c23)cc1 ; c1ccc(-c2ccc(N(c3ccc(-c4cccc(-c5cccc6c5sc5ccccc56)c4)cc3)c3ccc(-c4cccc5ccccc45)cc3)cc2)cc1]

9: The organic electronic device of claim 1, wherein the thickness of the first light-emitting auxiliary layer ranges from 25 to 900 Å, and the thickness of the second light-emitting auxiliary layer ranges from 10 to 300 Å.

10: The organic electronic device of claim 1, wherein the recombination energy of the first light-emitting auxiliary layer ranges from 0.110 to 0.140.

11: The organic electronic device of claim 1, wherein T₁ energy level of the second light-emitting auxiliary layer ranges from 2.3 to 3.0.

12: The organic electronic device of claim 1, wherein the organic layer comprises two or more stacks, and the two or more stacks each comprise a hole-transporting layer, a light-emitting layer and an electron-transporting layer formed sequentially on the first electrode.

13: The organic electronic device of claim 12, wherein the organic layer further comprises a charge generation layer between the two or more stacks.

14: The organic electronic device of claim 1, wherein the organic electronic device further comprises a layer for improving luminous efficiency, and the layer for improving luminous efficiency is formed on one side of either the first electrode or the second, and the one side not facing the organic layer.

15: An electronic apparatus comprising a display device and a control unit configured to drive the display device, wherein the display device comprises the organic electronic device of claim 1.

16: The electronic device of claim 15, wherein the organic electronic device is selected from the group consisting of an organic electroluminescent device, an organic solar cell, an organic photo conductor, an organic transistor, a device for monochromatic illumination and a quantum dot display device.
